(19) United States
(12) Patent Application Publication
(10) Pub. No.: US 2025/0311213 A1
(43) Pub. Date: Oct. 2, 2025

(54) MEMORY DEVICE INCLUDING DUMMY MEMORY BLOCK

(71) Applicant: Samsung Electronics Co., Ltd., Suwon-si (KR)

(72) Inventor: Bongkil Jung, Suwon-si (KR)

(21) Appl. No.: 19/061,727

(22) Filed: Feb. 24, 2025

(30) Foreign Application Priority Data
Mar. 29, 2024 (KR) 10-2024-0043670

(51) Int. Cl. H10B 43/10; G11C 16/04; G11C 16/08; G11C 16/10; H10B 43/27

(52) U.S. Cl. CPC H10B 43/10; G11C 16/0483; G11C 16/08; G11C 16/107; H10B 43/27

(57) ABSTRACT

A memory device includes a memory cell structure including a plurality of memory blocks, wherein the plurality of memory blocks include at least one dummy memory block and a plurality of main memory blocks, each of the plurality of main memory blocks includes a first type of string group, and the at least one dummy memory block includes the first type of string group and a second type of string group, the first type of string group includes a plurality of first vertical channels which are connected to a first string selection line and are connected to bit lines, and the second type of string group includes a plurality of second vertical channels which are connected to a second string selection line and are not connected to bit lines.

### CROSS-REFERENCE TO RELATED APPLICATION

This application is based on and claims priority under 35 U.S.C. § 119 to Korean Patent Application No. 10-2024-0043670, filed on Mar. 29, 2024, in the Korean Intellectual Property Office, the disclosure of which is incorporated by reference herein in its entirety.

### BACKGROUND

The inventive concept relates to a semiconductor memory, and more particularly, to a memory device including a dummy memory block.

Semiconductor memories are divided into volatile memory devices such as SRAM and DRAM, in which stored data is lost when the power supply is interrupted, and nonvolatile memory devices such as flash memory devices, PRAM, MRAM, RRAM, and FRAM, which retain stored data even when the power supply is interrupted.

With the recent multifunctionalization of information and communication devices, large capacity and high integration of memory devices are required. For high integration, vertical memory devices including memory cells vertically arranged in three dimensions have been proposed. As the scale of memory devices decreases and structures thereof change due to the high integration of memory devices, various previously unknown problems have been discovered. Various newly discovered problems may damage strings included in memory devices, and may damage data stored in the memory devices.

### SUMMARY

The inventive concept provides a memory device with a reduced size and including a dummy memory block.

According to an aspect of the inventive concept, there is provided a memory device including a memory cell structure including a plurality of memory blocks, wherein the plurality of memory blocks include a first dummy memory block and a plurality of main memory blocks, each of the plurality of main memory blocks includes a first type of string group, the first dummy memory block includes the first type of string group and a second type of string group, the first type of string group includes a plurality of first vertical channels which are connected to a first string selection line and are connected to bit lines, and the second type of string group includes a plurality of second vertical channels which are connected to a second string selection line and are not connected to bit lines (e.g., have no signal path to bit lines and/or are unable to be connected to bit lines).

According to another aspect of the inventive concept, there is provided a memory device including a memory cell structure including a plurality of memory blocks, wherein the plurality of memory blocks include a first dummy memory block, a plurality of main memory blocks, and a second dummy memory block, the first dummy memory block is disposed on a first side of the plurality of main memory blocks, and the second dummy memory block is disposed on a second side of the plurality of main memory blocks facing the first side in a first direction, the first dummy memory block is a single memory block including a first type of string group and a second type of string group, the second dummy memory block is a single memory block including the first type of string group and the second type of string group, each of the plurality of main memory blocks includes the first type of string group, the first type of string group includes a plurality of vertical channels which are connected to a first string selection line and are connected to bit lines, and the second type of string group includes a plurality of second vertical channels which are connected to a second string selection line and are not connected to bit lines (e.g., have no signal path to bit lines and/or are unable to be connected to bit lines).

According to another aspect of the inventive concept, there is provided a memory device including a memory cell structure including a plurality of memory blocks, wherein the plurality of memory blocks include a first dummy memory block and a plurality of main memory blocks, each of the plurality of main memory blocks includes a plurality of first vertical channels connected to bit lines, and the first dummy memory block includes a plurality of first vertical channels which are connected to bit lines, and a plurality of second vertical channels which are not connected to the bit lines (e.g., have no signal path to bit lines and/or are unable to be connected to bit lines), and data is stored in memory cells included in each of the plurality of first vertical channels of the first dummy memory block.

### BRIEF DESCRIPTION OF THE DRAWINGS

Embodiments will be more clearly understood from the following detailed description taken in conjunction with the accompanying drawings in which:

FIG. 1 is a block diagram illustrating a memory device according to an embodiment;

FIG. 2 is a detailed block diagram illustrating a memory cell array of FIG. 1;

FIG. 3 is a diagram for describing a string group of FIG. 2;

FIG. 4A is an equivalent circuit diagram of a main memory block of FIG. 2, according to an embodiment;

FIG. 4B is an equivalent circuit diagram of a dummy memory block of FIG. 2, according to an embodiment;

FIG. 5A is a plan view illustrating the memory device of FIG. 1, according to an embodiment;

FIG. 5B is a cross-sectional view taken along line A-A′ of FIG. 5A;

FIG. 5C is a cross-sectional view taken along line B-B′ of FIG. 5A;

FIG. 5D is a cross-sectional view taken along line D-D′ of FIG. 5A;

FIG. 6 is a detailed block diagram illustrating a memory cell array of FIG. 1, according to an embodiment;

FIG. 7 is a diagram for describing string groups of FIG. 6;

FIG. 8A is a plan view illustrating the memory device of FIG. 1, according to an embodiment;

FIG. 8B is a cross-sectional view taken along line E-E′ of FIG. 8A;

FIGS. 9A to 9D are cross-sectional views taken along line E-E′ of FIG. 8A, according to some embodiments;

FIG. 10 is a detailed block diagram illustrating a memory cell array of FIG. 1, according to an embodiment;

FIG. 11 is a flowchart illustrating an operating method of a memory device, according to an embodiment;

FIG. 12A is a timing diagram of voltages applied by a memory device to lines during a pre-program operation and an erase operation, according to an embodiment;

FIG. 12B is a timing diagram of voltages applied by a memory device to lines during a pre-program operation and an erase operation, according to an embodiment;

FIG. 12C is a timing diagram of voltages applied by a memory device to lines during a pre-program operation and an erase operation, according to an embodiment;

FIG. 13A is a circuit diagram illustrating a first dummy memory block among a plurality of memory blocks included in a memory cell array of FIG. 1;

FIG. 13B is a vertical cross-sectional view illustrating a first cell string among cell strings of FIG. 13A;

FIG. 13C is a timing diagram illustrating a pre-program operation of the memory device of FIG. 1;

FIG. 13D is a timing diagram illustrating a pre-program operation of the memory device of FIG. 1;

FIG. 14A is a timing diagram illustrating a pre-program operation of the memory device of FIG. 1;

FIG. 14B is a timing diagram illustrating a pre-program operation of the memory device of FIG. 1;

FIG. 14C is a timing diagram illustrating a pre-program operation of the memory device of FIG. 1;

FIG. 14D is a timing diagram illustrating a pre-program operation of the memory device of FIG. 1;

FIG. 15A is a circuit diagram illustrating a second dummy memory block among a plurality of memory blocks included in the memory cell array of FIG. 1;

FIG. 15B is a vertical cross-sectional view illustrating a first cell string among cell strings of FIG. 15A;

FIG. 15C is a flowchart illustrating an operating method of a memory device, according to an embodiment;

FIG. 15D is a timing diagram illustrating a first pre-program operation of the memory device of FIG. 1;

FIG. 15E is a timing diagram illustrating a second pre-program operation of the memory device of FIG. 1;

FIG. 16 is a block diagram illustrating a solid state drive (SSD) system to which a storage device according to an embodiment is applied; and

FIG. 17 is a cross-sectional view of a memory device having a B-VNAND structure, according to an embodiment.

### DETAILED DESCRIPTION OF THE EMBODIMENTS

Hereinafter, the embodiments will be described clearly and in detail so that one of ordinary skill in the art may easily implement the inventive concept.

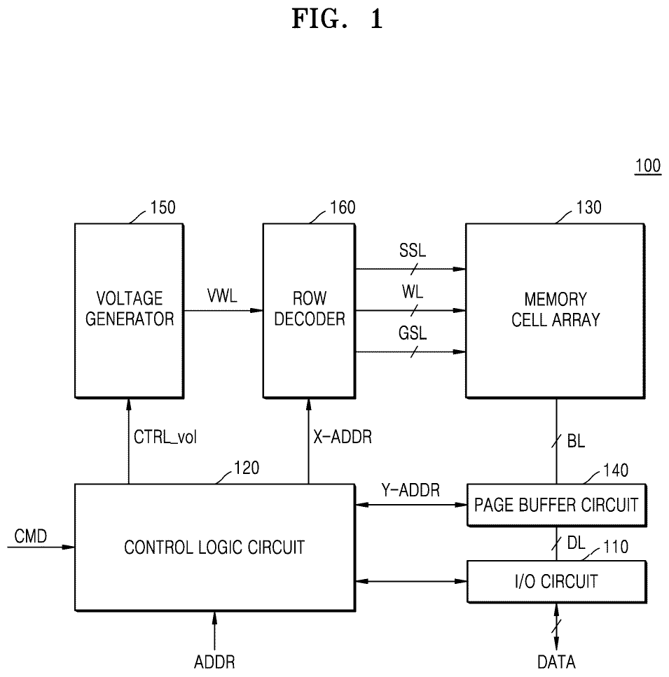

FIG. 1 is a block diagram illustrating a memory device 100 according to an embodiment.

Referring to FIG. 1, the memory device 100 may include an input/output circuit 110, a control logic circuit 120, a memory cell array 130, a page buffer circuit 140, a voltage generator 150, and a row decoder 160. Although not illustrated in FIG. 1, the memory device 100 may further include a column logic, a pre-decoder, a temperature sensor, a command decoder, an address decoder, etc.

The control logic circuit 120 may generally control various operations of the memory device 100. The control logic circuit 120 may output various control signals in response to a command CMD and/or an address ADDR from the input/output circuit 110. For example, the control logic circuit 120 may output a voltage control signal CTRL_vol, a row address X-ADDR, and a column address Y-ADDR.

The memory cell array 130 may include a plurality of memory blocks, and each of the plurality of memory blocks may include a plurality of memory cells. The memory cell array 130 may be connected to the page buffer circuit 140 through bit lines BL, and may be connected to the row decoder 160 through word lines WL, string selection lines SSL, and ground selection lines GSL.

In an embodiment, the memory cell array 130 may include a three-dimensional (3D) memory cell array, and the 3D memory cell array may include a plurality of cell strings. Each cell string may include memory cells respectively connected to the word lines WL vertically stacked on a substrate. U.S. Pat. Nos. 7,679,133, 8,553,466, 8,654,587, 8,559,235, and U.S. Patent Application Publication No. 2011/0233648 are incorporated by reference herein. In an embodiment, the memory cell array 130 may include a two-dimensional (2D) memory cell array, and the 2D memory cell array may include a plurality of cell strings arranged along row and column directions.

In an embodiment, a plurality of memory blocks may include a plurality of main memory blocks and at least one dummy memory block. The main memory block may indicate a block including only memory cells capable of storing data, and the dummy memory block may indicate a single memory block (e.g., a unit of nonvolatile memory erasure) including memory cells incapable of storing data.

In an embodiment, the main memory block may include memory cells that store data. All of the cell strings included in the main memory block may be connected to the bit line BL. All of the memory cells included in the main memory block may be connected to the bit line BL.

In an embodiment, the dummy memory block may include both memory cells that store data and memory cells that do not store data within a single memory block (e.g., a unit of nonvolatile memory erasure). A first part of the cell strings included in the dummy memory block may be connected to the bit line BL. A second part of the cell strings included in the dummy memory block may not be connected to the bit line BL. A first part of the memory cells included in the dummy memory block may be connected to the bit line BL. A second part of the memory cells included in the dummy memory block may not be connected to the bit line BL. For example, the first part of the memory cells in the dummy memory block may be capable of storing data by virtue of being connected to the bit line BL, whereas the second part of the memory cells in the dummy memory block may not be configured to store data.

For example, the presence of memory cells in the dummy memory block that have no signal path (i.e., are unable to be connected) to any bit line BL and/or are incapable of storing data may solve a process issue by providing physical distance. In another example, as semiconductor processing technology develops, the need for distance to mitigate such process issues may decrease, so fewer dummy memory cells may be required. Accordingly, in some embodiments, a dummy memory block may include a combination of memory cells capable of storing data (e.g., connected to bit line BL) and those not configured to store data (e.g., having no signal path to any bit line BL).

In another embodiment, the dummy memory block may include only memory cells that do not store data. All of the cell strings included in the dummy memory block may not be connected to the bit line BL. All of the memory cells included in the dummy memory block may not be connected to the bit line BL.

The page buffer circuit 140 may include a plurality of page buffers. The page buffer circuit 140 may be connected to the memory cell array 130 through the bit lines BL. The plurality of page buffers of the page buffer circuit 140 may be connected to the memory cells through a plurality of bit lines BL, respectively. The page buffer circuit 140 may select at least one bit line BL from among the bit lines BL in response to the column address Y-ADDR. The page buffer circuit 140 may operate as a write driver or a sense amplifier according to an operation mode. For example, during a program operation, the page buffer circuit 140 may apply a bit line voltage corresponding to data to be programmed through the selected bit line BL. During a read operation, the page buffer circuit 140 may detect a current or voltage of the selected bit line BL to detect data stored in the memory cell.

The voltage generator 150 may generate various types of voltages for performing program, read, and erase operations based on a voltage control signal CTRL_vol. For example, the voltage generator 150 may generate a program voltage, a pre-program voltage, a read voltage, a program verify voltage, an erase voltage, etc. as a word line voltage VWL.

The row decoder 160 may select one of a plurality of word lines WL in response to the row address X-ADDR and may select one of a plurality of string selection lines SSL. For example, during a program operation, the row decoder 160 may apply a program voltage and a program verify voltage to the selected word line WL, and may apply a read voltage to the selected word line WL during a read operation.

Cell strings may be damaged due to repeated erase operations. In particular, repeated erase operations on memory cells on which a program is not performed may damage the memory cells. To prevent such damage to cell strings due to erase operations, in an embodiment, the memory device 100 may perform a pre-program operation. For example, the memory device 100 may perform a pre-program operation on memory cells before performing an erase operation.

In an embodiment, the row decoder 160 may perform a pre-program operation and an erase operation. The row decoder 160 may perform a pre-program operation of applying a program voltage or a pre-program voltage. The row decoder 160 may perform an erase operation of applying an erase voltage.

In an embodiment, the memory device 100 may perform a pre-program operation and an erase operation on a dummy memory block. For example, the row decoder 160 may perform a pre-program operation on the dummy memory block. The row decoder 160 may perform an erase operation on the dummy memory block.

For example, the row decoder 160 may apply a program voltage or a pre-program voltage to the word line WL to perform such a pre-program operation. A program voltage may increase the threshold voltage of a memory cell to be programmed. For example, the row decoder 160 may apply the pre-program voltage VPGM to the word line WL connected to the second type T2 of each of the string groups in the dummy memory block on which the pre-program operation is to be performed. The memory device 100 may apply the pre-program voltage VPGM to the word line WL connected to a second channel structure CS2.

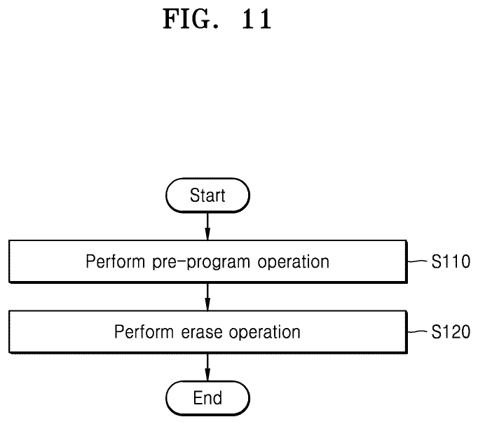

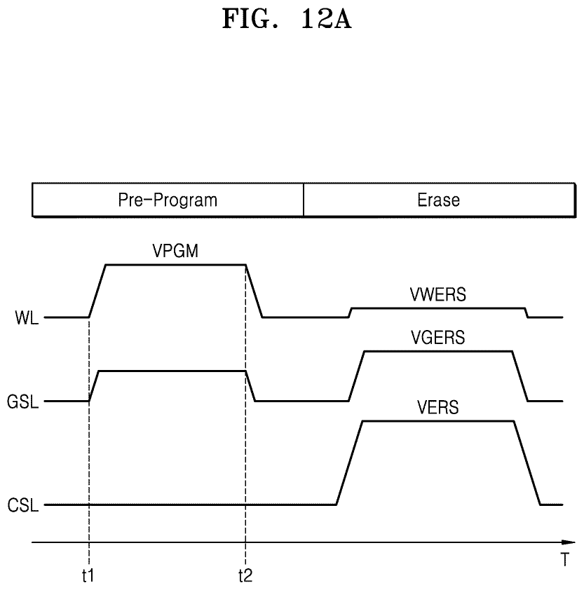

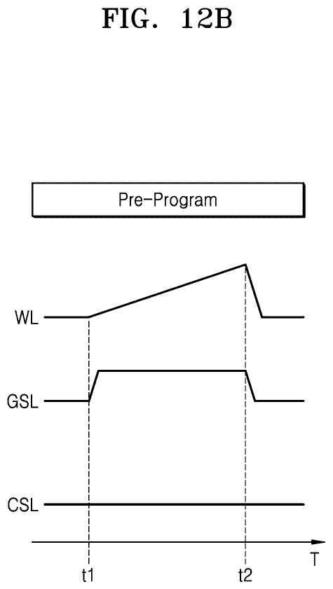

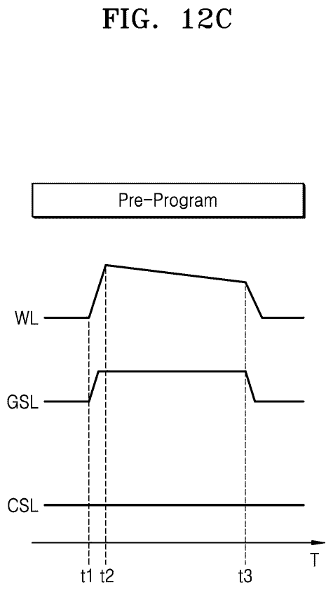

The memory device 100 may apply a pass voltage VPASS to the ground selection line GSL connected to the second type T2 of each of the string groups. The pass voltage VPASS may be a voltage for turning on a ground selection transistor. The memory device 100 may apply a ground voltage VSS or a ground voltage GND to a common source line CSL connected to the second type T2 of each of the string groups. A detailed description of the pre-program operation is given with reference to FIGS. 11 and 12.

As described above, the memory device 100 according to an embodiment may include a plurality of main memory blocks and at least one dummy memory block. For example, the memory cell array 130 (or cell area) (or memory cell structure) may include the plurality of main memory blocks and the at least one dummy memory block. Cell strings included in at least one string group included in the dummy memory block may be electrically connected to a bit line. Accordingly, data may be stored in some memory cells of the dummy memory block. For example, the memory device 100 may replace a part of the dummy memory block with a spare block and use the spare block. As a result, the disclosed memory device 100 may provide an improvement, such as reducing the size of a chip or increasing a storage usage space, compared with other memory devices with fewer operative memory cells.

The memory device 100 according to an embodiment may perform the pre-program operation on cell strings which are not connected to the bit line (e.g., have no signal path to the bit line and/or are unable to be connected to the bit line) and are included in the dummy memory block. In an example, in order to perform the pre-program operation and/or to apply a ground voltage to cell strings in the dummy memory block that are not connected to the bit line (e.g., have no signal path to the bit line and/or are unable to be connected to the bit line), the memory device 100 may apply a pass voltage to a ground selection line connected to such cell strings which are not connected to the bit line and are included in the dummy memory block, and apply a ground voltage to a common source line connected to cell strings which are not connected to the bit line and are included in the dummy memory block. Accordingly, damage to cell strings due to repeated erase operations may be prevented.

Hereinafter, for convenience of description, terms such as “memory cell array”, “memory cell structure”, and “cell area” are used interchangeably. These terms may have the same meaning or different meanings according to the context of embodiments, and the meaning of each term will be understood according to the context of embodiments to be described.

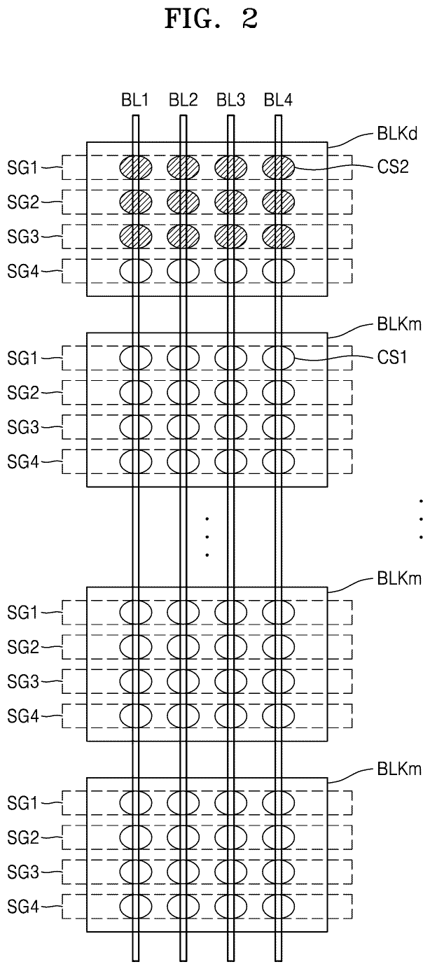

FIG. 2 is a detailed block diagram illustrating the memory cell array 130 of FIG. 1.

Referring to FIGS. 1 and 2, the memory cell array 130 may include a plurality of memory blocks. The memory cell array 130 may include a dummy memory block BLKd and a main memory block BLKm. For example, the memory cell array 130 may include at least one dummy memory block BLKd and a plurality of main memory blocks BLKm.

The dummy memory block BLKd may include a plurality of channel structures CS (or channel holes) (or cell strings). For example, channel structures may be channel pillars, and may also be referred to as vertical channels. The dummy memory block BLKd may include a plurality of string groups SG. The string group SG may indicate string cells or channel structures connected to the same string selection line SSL.

For example, the dummy memory block BLKd may include first to fourth string groups SG1 to SG4. The plurality of channel structures CS included in the dummy memory block BLKd may be divided into a plurality of string groups. For example, the plurality of channel structures CS included in the dummy memory block BLKd may be divided into first to fourth string groups SG1 to SG4. For example, the four string groups SG1 to SG4 are illustrated in an embodiment of FIG. 2, but the scope of the inventive concept is not limited thereto, and the number of string groups may be increased or decreased according to an implementation method.

In an example, the string groups (e.g., first to fourth string groups SG1 to SG4) within each memory block may be spaced apart by a constant distance or pitch. The spacing between adjacent memory blocks (such as between adjacent main memory block BLKm or between the dummy memory block BLKd and an adjacent main memory block BLKm) may exceed the pitch between string groups within a single memory block (such as the pitch of first to fourth string groups SG1 to SG4). Alternatively or additionally, the spacing between immediately adjacent string groups of dummy memory block BLKd and a neighboring main block BLKm may exceed the pitch between string groups within a single memory block. For example, the spacing between the string group SG4 shown at the bottom of dummy memory block BLKd and the immediately adjacent string group SG1 shown at the top of main memory block BLKm may exceed the pitch of first to fourth string groups SG1 to SG4 within the dummy memory block BLKd.

The first string group SG1 of the dummy memory block BLKd may include cell strings or the channel structures CS connected to a first string selection line SSL1. A second string group SG2 of the dummy memory block BLKd may include the channel structures CS connected to a second string selection line SSL2. A third string group SG3 of the dummy memory block BLKd may include the channel structures CS connected to a third string selection line SSL3. The fourth string group SG4 of the dummy memory block BLKd may include the channel structures CS connected to a fourth string selection line SSL4.

The main memory block BLKm may include the plurality of channel structures CS. The main memory block BLKm may include a plurality of string groups. The main memory block BLKm may include the first to fourth string groups SG1 to SG4. The plurality of channel structures CS included in the main memory block BLKm may be divided into a plurality of string groups. For example, the plurality of channel structures CS included in the main memory block BLKm may be divided into the first to fourth string groups SG1 to SG4. For example, the four string groups SG1 to SG4 are illustrated in an embodiment of FIG. 2, but the scope of the inventive concept is not limited thereto, and the number of string groups may be increased or decreased according to an implementation method.

The first string group SG1 of the main memory block BLKm may include cell strings or the channel structures CS connected to the first string selection line SSL1. The second string group SG2 of the main memory block BLKm may include the channel structures CS connected to the second string selection line SSL2. The third string group SG3 of the main memory block BLKm may include the channel structures CS connected to the third string selection line SSL3. The fourth string group SG4 of the main memory block BLKm may include the channel structures CS connected to the fourth string selection line SSL4.

The channel structure CS may include a first channel structure (e.g., channel pillar or vertical channel) CS1 and a second channel structure (e.g., channel pillar or vertical channel) CS2. The first channel structure CS1 may indicate the channel structure CS connected to the bit line BL. The second channel structure CS2 may indicate the channel structure CS that is not connected to the bit line BL (e.g., having no signal path to bit line BL and/or unable to be connected to bit line BL). For example, the second channel structure CS2 may be a dummy structure.

The first channel structure CS1 may be connected to the bit line BL. For example, the first channel structures CS1 may be connected to first to fourth bit lines BL1 to BL4. The four bit lines BL1 to BL4 are illustrated in an embodiment of FIG. 2, but the scope of the inventive concept is not limited thereto, and the number of bit lines may be increased or decreased according to an implementation method. Some of the first channel structures CS1 may be connected to the first bit line BL1, and others of the first channel structures CS1 may be connected to a second bit line BL2. Some of the first channel structures CS1 may be connected to a third bit line BL3, and others of the first channel structures CS1 may be connected to the fourth bit line BL4. The second channel structure CS2 may not be connected to the bit line BL.

In an embodiment, the main memory block BLKm may include only the first channel structures CS1. For example, the main memory block BLKm may include only the channel structures CS connected to a bit line. For example, the main memory block BLKm may include only memory cells connected to the bit line BL.

In an embodiment, the dummy memory block BLKd may include both the first channel structures CS1 and the second channel structures CS2. The dummy memory block BLKd may include both the channel structures CS connected to the bit line BL and the channel structures CS not connected to the bit line BL. The dummy memory block BLKd may include both memory cells connected to the bit line BL (e.g., having a signal path to bit line BL) and memory cells not connected to the bit line BL (e.g., having no signal path to bit line BL and/or unable to be connected to bit line BL).

Each of the string groups SG1 to SG4 of each of the main memory blocks BLKm may include only the first channel structures CS1. The first string group SG1 of the dummy memory block BLKd may include the second channel structures CS2. Each of the channel structures CS included in the first string group SG1 of the dummy memory block BLKd may not be connected to the bit line BL. The second string group SG2 of the dummy memory block BLKd may include the second channel structures CS2. Each of the channel structures CS included in the second string group SG2 of the dummy memory block BLKd may not be connected to the bit line BL. The third string group SG3 of the dummy memory block BLKd may include two channel structures CS2. Each of the channel structures CS included in the third string group SG3 of the dummy memory block BLKd may not be connected to the bit line BL. The fourth string group SG4 of the dummy memory block BLKd may include the first channel structures CS1. Each of the channel structures CS included in the fourth string group SG4 of the dummy memory block BLKd may be connected to the bit line BL. Accordingly, in this example, the dummy memory block BLKd may contain a combination of string groups (e.g., SG1 to SG3) that are not connected to bit line BL, and those (e.g., SG4) that are connected to bit line BL. By contrast, the main memory blocks BLKm may include only string groups connected to bit line BL.

In particular, as described above, each of the channel structures included in at least one string group among the first to fourth string groups SG1 to SG4 of the dummy memory block BLKd may be connected to the bit line BL. The fourth string group SG4 of the dummy memory block BLKd may store data. Each of the channel structures included in the fourth string group SG4 of the dummy memory block BLKd may store data. Each of the memory cells included in the fourth string group SG4 of the dummy memory block BLKd may store data. The channel structures included in the first to third string groups SG1 to SG3 of the dummy memory block BLKd may not store data. For example, the first channel structure CS1 may store data, and the second channel structure CS2 may not store data.

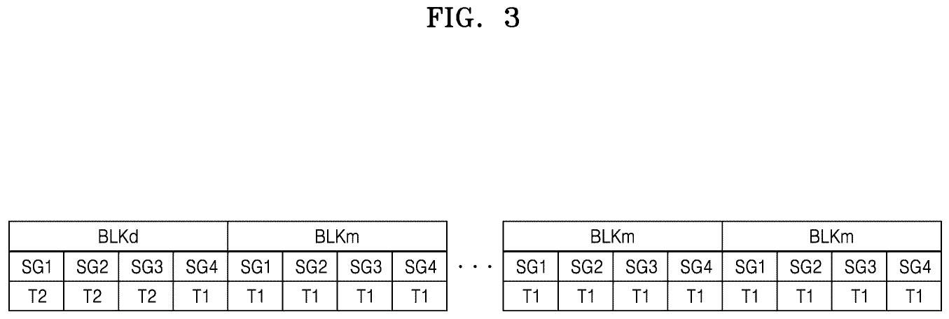

FIG. 3 is a table describing the channel structure types of the string group SG of FIG. 2.

Referring to FIGS. 1, 2, and 3, the string group SG may be one of a first type T1 of the string group SG or a second type T2 of the string group SG. The string group SG may have either the first type T1 or the second type T2. The first type T1 may indicate the string group SG including the first channel structures CS1, and the second type T2 may indicate the string group SG including the second channel structures CS2. The first type T1 of the string group SG may be the string group SG including the channel structures CS connected to a bit line, and the second type T2 of the string group SG may be the string group SG including the channel structures CS not connected to a bit line.

The first string group SG1 of the dummy memory block BLKd may be of the second type T2, the second string group SG2 of the dummy memory block BLKd may be of the second type T2, the third string group SG3 of the dummy memory block BLKd may be of the second type T2, and the fourth string group SG4 of the dummy memory block BLKd may be of the first type T1.

The first string group SG1 of the main memory block BLKm may be the first type T1, the second string group SG2 of the main memory block BLKm may be the first type T1, the third string group SG3 of the main memory block BLKm may be the first type T1, and the fourth string group SG4 of the main memory block BLKm may be the first type T1.

Among the first to fourth string groups SG1 to SG4 of the dummy memory block BLKd, the string group SG (i.e., the fourth string group SG4) adjacent to the main memory block BLKm may be of the first type T1. In the dummy memory block BLKd, the string group SG far from an edge of the memory cell array 130 may be of the first type T1.

Each of all of the first to fourth string groups SG1 to SG4 included in the main memory block BLKm may be of the first type T1. The main memory block BLKm may include only the first type T1 of the string groups SG. The main memory block BLKm may include only the string groups SG including the channel structures CS connected to a bit line.

Each of the first to fourth string groups SG1 to SG4 included in the dummy memory block BLKd may be of either the first type T1 or the second type T2. The dummy memory block BLKm may include at least one first type T1 of the string group SG and the second type T2 of the plurality of string groups SG. The dummy memory block BLKd may include the string group SG including the channel structures CS which are connected to a bit line and the string group SG including the channel structures CS which are not connected to the bit line.

Accordingly, in this example, the string groups included in the dummy memory block BLKd may include a combination of string groups of the first type T1 and string groups of the second type T2, whereas all of the string groups included in the main memory block BLKm may be of the first type T1.

In an embodiment, memory cells included in the second type T2 of the string group SG of the dummy memory block BLKd may be dummy memory cells that do not function as memory cells. Memory cells included in the first type T1 of the string group SG of the dummy memory block BLKd may be the same as or similar to memory cells included in the plurality of main memory blocks BLKm. The memory cells included in the first type T1 of the string group SG of the dummy memory block BLKd may perform the same function as the memory cells included in the plurality of main memory blocks BLKm. The memory cells included in the first type T1 of the string group SG of the dummy memory block BLKd may store data. On the other hand, the memory cells included in the second type T2 of the string group SG of the dummy memory block BLKd may not store data. The memory cells included in the second type T2 of the string group SG of the dummy memory block BLKd may be memory cells to which data is not written.

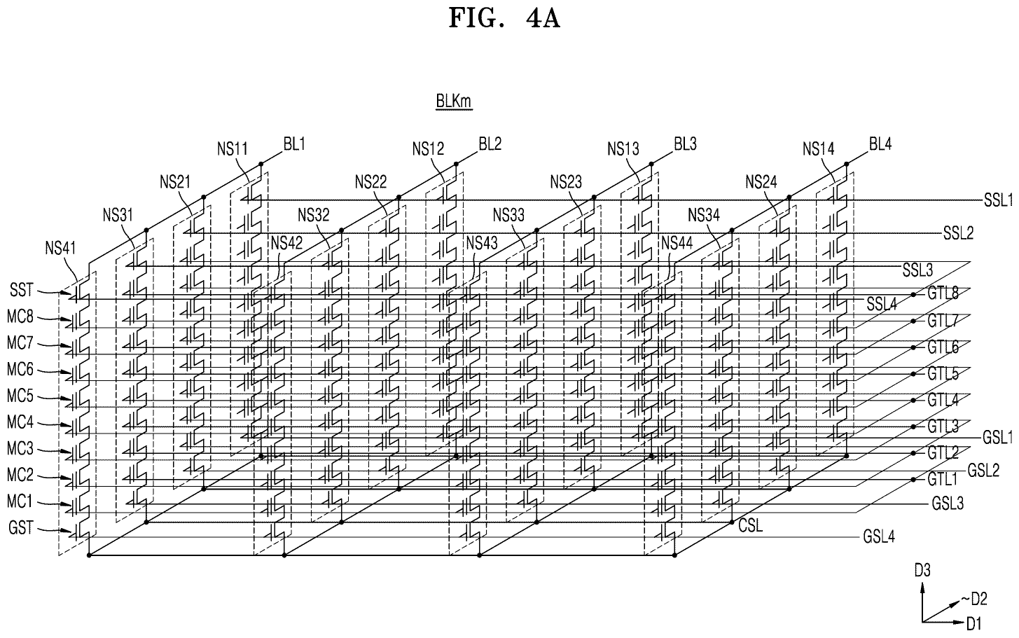

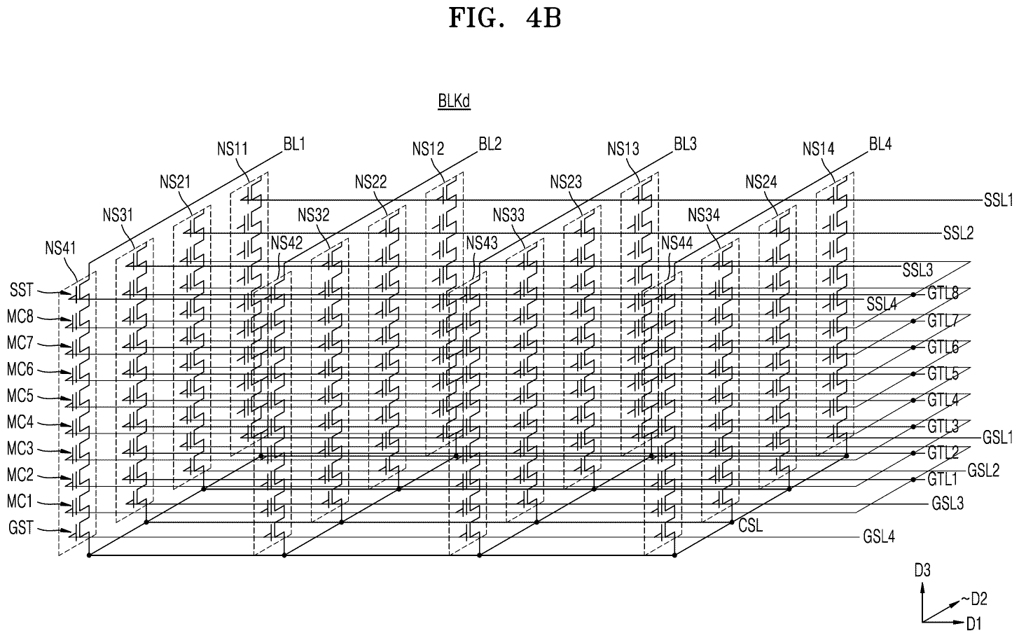

FIG. 4A is an equivalent circuit diagram of the main memory block BLKm of FIG. 2 according to an embodiment.

The main memory block BLKm illustrated in FIG. 4A represents a three-dimensional (3D) memory block formed on a substrate in a 3D structure. For example, a plurality of memory cell strings included in the main memory block BLKm may be formed in a direction perpendicular to the substrate.

Referring to FIG. 4A, the main memory block BLKm may include a plurality of memory cell strings NS11 to NS44 connected between the first to fourth bit lines BL1 to BL4 and a common source line CSL. Each of the plurality of memory cell strings NS11 to NS44 may include a string selection transistor SST, a plurality of memory cells MC1, MC2, . . . , and MC8, and a ground selection transistor GST. FIG. 4A illustrates that each of the plurality of memory cell strings NS11 to NS44 includes eight memory cells MC1, MC2, . . . , and MC8, but the inventive concept is not necessarily limited thereto, and may include any number of memory cells.

The string selection transistor SST may be connected to corresponding first to fourth string selection lines SSL1, SSL2, SSL3, and SSL4. The plurality of memory cells MC1, MC2, . . . , and MC8 may be connected to corresponding gate lines GTL1, GTL2, . . . , and GTL8, respectively. The gate lines GTL1, GTL2, . . . , and GTL8 may correspond to word lines, and some of the gate lines GTL1, GTL2, . . . , and GTL8 may correspond to dummy word lines. The ground selection transistor GST may be connected to corresponding ground selection lines GSL1, GSL2, GSL3, and GSL4. The string selection transistor SST may be connected to the corresponding first to fourth bit lines BL1 to BL4, and the ground selection transistor GST may be connected to the common source line CSL.

Word lines (e.g., WL1) of the same height may be commonly connected, and the ground selection lines GSL1, GSL2, GSL3, and GSL4 and the first to fourth string selection lines SSL1, SSL2, SSL3, and SSL4 may be separated. FIG. 4A illustrates that the main memory block BLKm is connected to the eight gate lines GTL1, GTL2, . . . , GTL8 and the four bit lines BL1, BL2, BL3, and BL4, but the inventive concept is not necessarily limited thereto, and may include any number of gate lines and/or bit lines.

The first string group SG1 of the main memory block BLKm may include the cell strings NS11, NS12, NS13, and NS14, the second string group SG2 of the main memory block BLKm may include the cell strings NS21, NS22, NS23, and NS24, the third string group SG3 of the main memory block BLKm may include the cell strings NS31, NS32, NS33, and NS34, and the fourth string group SG4 of the main memory block BLKm may include the cell strings NS41, NS42, NS43, and NS44.

The cell string may be an equivalent circuit diagram of the channel structure CS. The cell string may correspond to the channel structure CS. Hereinafter, for convenience of description, the terms such as “channel structure,” “cell string,” “channel pillar,” and “vertical channel” are used interchangeably. These terms may have the same meaning or different meanings according to the context of embodiments, and the meaning of each term will be understood according to the context of embodiments to be described.

FIG. 4B is an equivalent circuit diagram of the dummy memory block BLKd of FIG. 2 according to an embodiment.

The dummy memory block BLKd illustrated in FIG. 4B represents a 3D memory block formed on a substrate in a 3D structure. For example, a plurality of memory cell strings (also referred to as cell strings) included in the memory block BLKd may be formed in a direction perpendicular to the substrate.

Referring to FIG. 4B, the dummy memory block BLKd may include the plurality of memory cell strings NS11 to NS44. The dummy memory block BLKd may include the memory cell strings NS11 to NS33 connected to the common source line GSL. The dummy memory block BLKd may include the memory cell strings NS41 to NS44 connected between the common source line GSL and the first to fourth bit lines BL1 to BL4. Each of the plurality of memory cell strings NS11 to NS44 may include the string selection transistor SST, the plurality of memory cells MC1, MC2, . . . , and MC8, and the ground selection transistor GST. FIG. 4B illustrates that each of the plurality of memory cell strings NS11 to NS44 includes the eight memory cells MC1, MC2, . . . , and MC8, but the inventive concept is not necessarily limited thereto, and may include any number of memory cells.

The string selection transistor SST may be connected to corresponding first to fourth string selection lines SSL1, SSL2, SSL3, and SSL4. The plurality of memory cells MC1, MC2, . . . , and MC8 may be connected to the corresponding gate lines GTL1, GTL2, . . . , and GTL8, respectively. The gate lines GTL1, GTL2, . . . , and GTL8 may correspond to word lines, and some of the gate lines GTL1, GTL2, . . . , and GTL8 may correspond to dummy word lines. The ground selection transistor GST may be connected to the corresponding ground selection lines GSL1, GSL2, GSL3, and GSL4. The string selection transistor SST connected to the fourth string selection line SSL4 may be connected to the corresponding first to fourth bit lines BL1 to BL4. The string selection transistor SST connected to the first to fourth string selection lines SSL1 to SSL4 may not be connected to the corresponding first to fourth bit lines BL1 to BL4. The ground selection transistor GST may be connected to the common source line CSL.

Word lines (e.g., WL1) of the same height may be commonly connected, and the ground selection lines GSL1, GSL2, GSL3, and GSL4 and the first to fourth string selection lines SSL1, SSL2, SSL3, and SSL4 may be separated. FIG. 4B illustrates that the dummy memory block BLKd is connected to the eight gate lines GTL1, GTL2, . . . , GTL8 and the four bit lines BL1, BL2, BL3, and BL4, but the inventive concept is not necessarily limited thereto, and may include any number of gate lines and/or bit lines.

The first string group SG1 of the dummy memory block BLKd may include the cell strings NS11, NS12, NS13, and NS14, the second string group SG2 of the dummy memory block BLKd may include the cell strings NS21, NS22, NS23, and NS24, the third string group SG3 of the dummy memory block BLKd may include the cell strings NS31, NS32, NS33, and NS34, and the fourth string group SG4 of the dummy memory block BLKd may include the cell strings NS41, NS42, NS43, and NS44.

As described above, the cell strings NS11, NS12, NS13, and NS14 of the first string group SG1 of the dummy memory block BLKd may not be connected to the first to fourth bit lines BL1 to BL4. The cell strings NS21, NS22, NS23, and NS24 of the second string group SG2 of the dummy memory block BLKd may not be connected to the first to fourth bit lines BL1 to BL4. The cell strings NS31, NS32, NS33, and NS34 of the third string group SG3 of the dummy memory block BLKd may not be connected to the first to fourth bit lines BL1 to BL4. The cell strings NS41, NS42, NS43, and NS44 of the fourth string group SG4 of the dummy memory block BLKd may be connected to the first to fourth bit lines BL1 to BL4. In an example, the memory device 100 may store data in the cell strings NS41, NS42, NS43, and NS44 of the fourth string group SG4 of the dummy memory block BLKd.

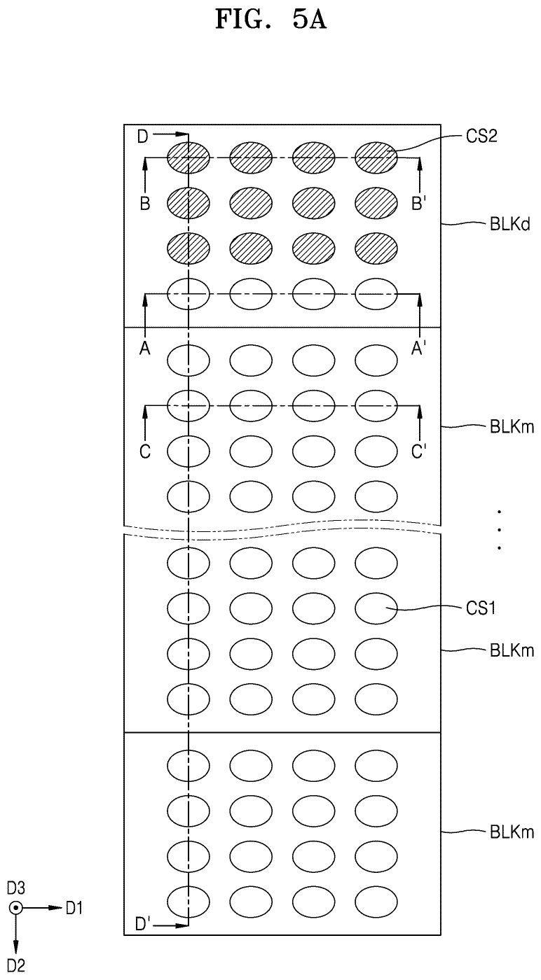

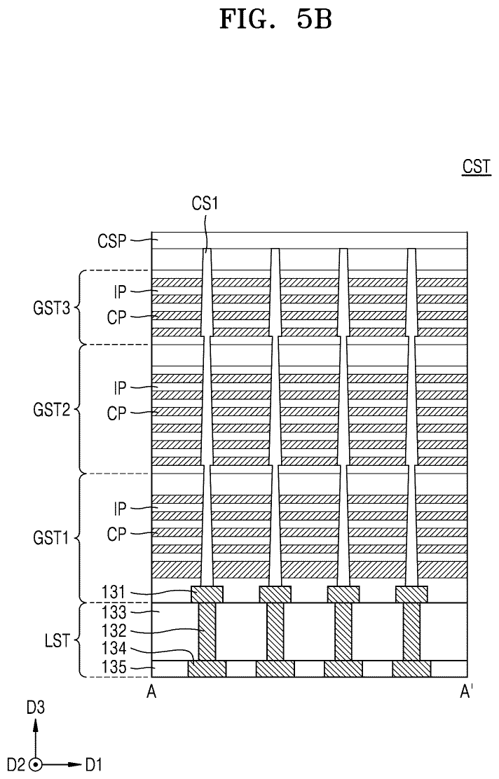

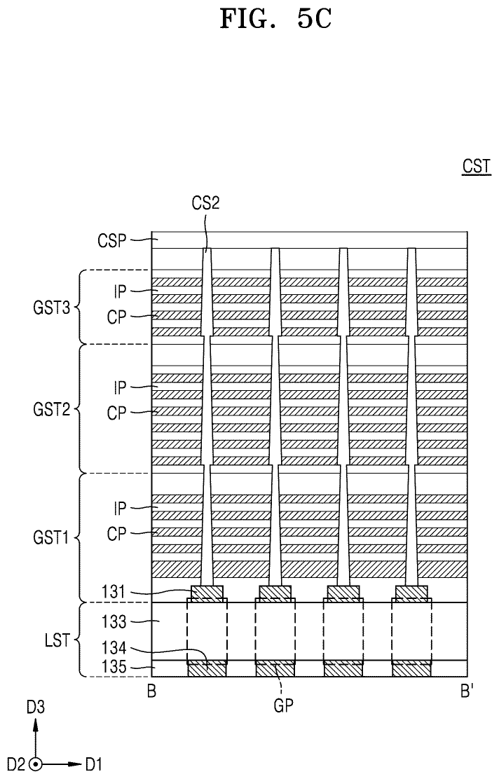

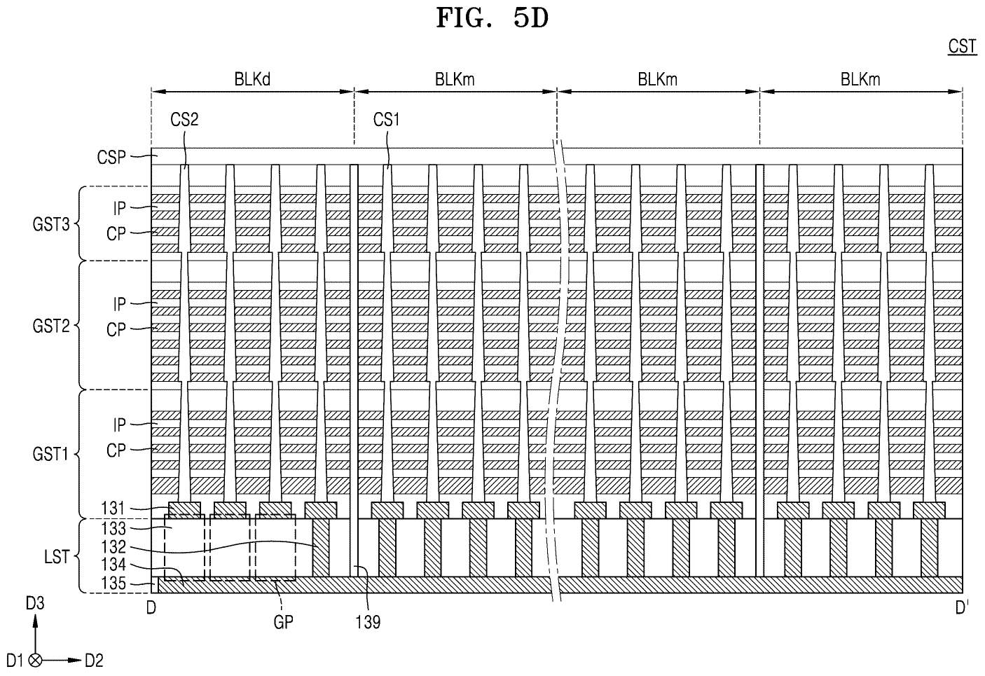

FIG. 5A is a plan view illustrating the memory device 100 of FIG. 1 according to an embodiment. FIG. 5B is a cross-sectional view taken along line A-A′ of FIG. 5A. FIG. 5C is a cross-sectional view taken along line B-B′ of FIG. 5A. FIG. 5D is a cross-sectional view taken along line D-D′ of FIG. 5A.

Referring to FIGS. 2, 5A, 5B, 5C, and 5D, the dummy memory block BLKd may be disposed on one side of the main memory blocks BLKm. The dummy memory block BLKd and the plurality of main memory blocks BLKm may be disposed in a second direction D2. The string groups SG1, SG2, SG3, and SG4 may be disposed to be spaced apart from each other in the second direction D2. The first type T1 of a string group of the dummy memory block BLKd may be disposed adjacent to the plurality of main memory blocks BLKm. The first type T1 of the string group of the dummy memory block BLKd may be disposed far from an edge area of the memory cell array 130. The first to fourth bit lines BL1 to BL4 may be disposed to be spaced apart from each other in a first direction D1. The first to fourth bit lines BL1 to BL4 may extend in the second direction D2.

The memory device 100 may include a plurality of memory blocks. The plurality of memory blocks may include the plurality of main memory blocks BLKm and the at least one dummy memory block BLKd. In an embodiment, the dummy memory block BLKd may be disposed on at least one side of the plurality of main memory blocks BLKm.

In an embodiment, the dummy memory block BLKd may be disposed on both sides of the plurality of main memory blocks BLKm. The dummy memory block BLKd may be formed to have the same structure as or similar structure to the plurality of main memory blocks BLKm. However, the dummy memory block BLKd may include a plurality of dummy memory cells that do not function as memory cells (e.g., are not configured to store data, and/or are not configured to store any data that is accessible to a device external to the memory device 100).

In some examples, the plurality of dummy memory cells may belong to dummy cell strings, e.g. cell strings that are not connected to a bit line. Such dummy cell strings may be connected to the string select lines and CSL, for example, through appropriate string selection and/or ground selection transistors. For example, the dummy cell strings may include a corresponding string selection transistor and ground selection transistor, and may be connected thereto.

The memory device 100 may include a memory cell structure (e.g., a memory cell system) CST. The memory cell structure CST may include a lower wiring structure LST, a first gate stack structure GST1, a second gate stack structure GST2, a third gate stack structure GST3, the first channel structures CS1, the second channel structures CS2, a common source plate CSP, etc.

For example, the memory cell structure CST may correspond to the memory cell array 130 of FIG. 1. The memory cell structure CST may correspond to a cell area. The memory cell structure CST may include a plurality of memory blocks. The memory cell structure CST may include a plurality of memory blocks defined between a stack of insulating layers 139 passing through the memory cell structure CST and extending in the third direction D3. The plurality of memory blocks may include the plurality of main memory blocks BLKm and the at least one dummy memory block BLKd. For example, the at least one dummy memory block BLKd may be disposed on one side of the plurality of main memory blocks BLKm. In one embodiment, the first width of the stack of insulating layer 139 between the main memory blocks BLKm and of the dummy memory block BLKd may be greater than the second width of the stack of insulating layer 139 between the plurality of main memory blocks BLKm.

The lower wiring structure (e.g., lower wiring system) LST may include a first interlayer insulating layer 135, bit lines 134, a second interlayer insulating layer 133, and first contacts 132. The first interlayer insulating layer 135 may include an insulating material. In some embodiments, the first interlayer insulating layer 135 may be a multilayer including a plurality of insulating layers.

The bit lines 134 may be disposed in the first interlayer insulating layer 135. The bit lines 134 may extend in the second direction D2. The bit lines 134 may be arranged in the first direction D1. The bit lines 134 may include a conductive material.

The second interlayer insulating layer 133 may be disposed on the first interlayer insulating layer 135. The second interlayer insulating layer 133 may include an insulating material. In some embodiments, the second interlayer insulating layer 133 may be a multilayer including a plurality of insulating layers.

The first contacts 132 may be disposed on the bit line 134. The first contacts 132 may be disposed in the second interlayer insulating layer 133. The first contact 132 may electrically connect the bit line 134 to the first channel structure CS1. The first contacts 132 may include a conductive material.

The number of the second and first interlayer insulating layers 133 and 135 may not be limited to those illustrated. In some embodiments, the number of the second and first interlayer insulating layers 133 and 135 may be two or less, or four or more.

The first gate stack structure GST1 may be disposed on the second interlayer insulating layer 133. The second gate stack structure GST2 may be disposed on the first gate stack structure GST1. The third gate stack structure GST3 may be disposed on the second gate stack structure GST2. The number of the first to third gate stack structures GST1, GST2, and GST3 may not be limited to those illustrated. In some embodiments, the number of the first to third gate stack structures GST1, GST2, and GST3 may be two or less, or four or more.

Each of the first to third gate stack structures GST1, GST2, and GST3 may include insulating patterns IP and conductive patterns CP, which are alternately stacked on each other in a third direction D3. The third direction D3 may intersect the first direction D1 and the second direction D2. For example, the third direction D3 may be a vertical direction orthogonal to the first direction D1 and the second direction D2.

The insulating patterns IP may each include an insulating material. For example, the insulating patterns IP may each include an oxide or a low dielectric material, but are not limited thereto. The conductive patterns CP may each include a conductive material. For example, the conductive patterns CP may each include at least one of a doped semiconductor, a metal, a conductive metal nitride, or a transition metal, but are not limited thereto.

The first channel structures CS1 may extend in the third direction D3 and pass through the first gate stack structure GST1, the second gate stack structure GST2, and the third gate stack structure GST3. The first channel structure CS1 may be disposed on the second interlayer insulating layer 133 in the cell area.

The second channel structures CS2 may extend in the third direction D3 and pass through the first gate stack structure GST1, the second gate stack structure GST2, and the third gate stack structure GST3. The second channel structure CS2 may be disposed on the second interlayer insulating layer 133 in the cell area. The common source plate CSP may be disposed on the third gate stack structure GST3.

The second channel structure CS2 may be covered by the second interlayer insulating layer 133, and this portion may be referred to as a gap portion GP. The second channel structure CS2 may be covered by the gap portion GP so as not to be electrically connected to the bit line BL. No contact may be disposed between the bit line BL and the second channel structure CS2.

The cross-sectional view taken along line C-C′ of FIG. 5A may be the same as the cross-sectional view taken along line A-A′ of FIG. 5A. FIG. 5B (i.e., the cross-sectional view taken along line A-A′ of FIG. 5A) may be a cross-sectional view of the first type T1 of the string group SG. FIG. 5C (i.e., the cross-sectional view taken along line B-B′ of FIG. 5A) may be a cross-sectional view of the second type T2 of the string group SG.

In an embodiment, the second channel structures CS2 may be shifted to one side of the memory cell array. Among the string groups of the dummy memory block BLKd, a string group close to the edge area of the memory cell array 130 may be of the second type T2. Among the string groups of the dummy memory block BLKd, a string group far from the edge area of the memory cell array 130 may be of the first type T1. Alternatively, among the string groups of the dummy memory block BLKd, a string group close to the center of the memory cell array 130 may be of the first type T1. Among the string groups of the dummy memory block BLKd, a string group far from the center of the memory cell array 130 may be of the second type T2. For example, the first to third string groups SG1 to SG3 of the dummy memory block BLKd may be of the second type T2, and the fourth string group SG4 of the dummy memory block BLKd may be of the first type T1.

In an embodiment, the memory device 100 may include the memory cell structure CST including the plurality of memory blocks. The plurality of memory blocks may include the at least one dummy memory block BLKd and the plurality of main memory blocks BLKm. Each of the plurality of main memory blocks BLKm may include the first type T1 of a string group, and the at least one dummy memory block BLKd may include the first type T1 of a string group and the second type T2 of a string group. The first type T1 of the string group may include a plurality of first channel structures CS1 which are connected to the same string selection line SSL and are connected to the bit lines BL. The second type T2 of the string group may include a plurality of second channel structures CS2 which are connected to the same string selection line SSL and are not connected to the bit lines BL.

In an embodiment, the first type T1 of the string group of the dummy memory block BLKd of the memory device 100 may store data in the same manner as the string group of the main memory block BLKm. The memory device 100 may store data in the first channel structures CS1 of the dummy memory block BLKd. The memory device 100 may store data in memory cells included in the first type T1 of the string group of the dummy memory block BLKd.

As described above, the first channel structure CS1 included in the first type T1 of the string group SG may be connected to the bit line BL by the first contact 132. On the other hand, the first contact 132 may not be formed in the second channel structure CS2 included in the second type T2 of the string group SG. Accordingly, the second channel structure CS2 may not be electrically connected to the bit line BL. The dummy memory block BLKd may include both the first channel structure CS1 and the second channel structure CS2. The memory device 100 may store data in the first channel structure CS1 of the dummy memory block BLKd. For example, the memory device 100 may store data in at least one string group SG of the dummy memory block BLKd. Accordingly, the size of the disclosed memory device 100 may be reduced while maintaining its storage capacity, thereby improving memory device 100. Alternatively, the storage space of the memory device 100 may be increased.

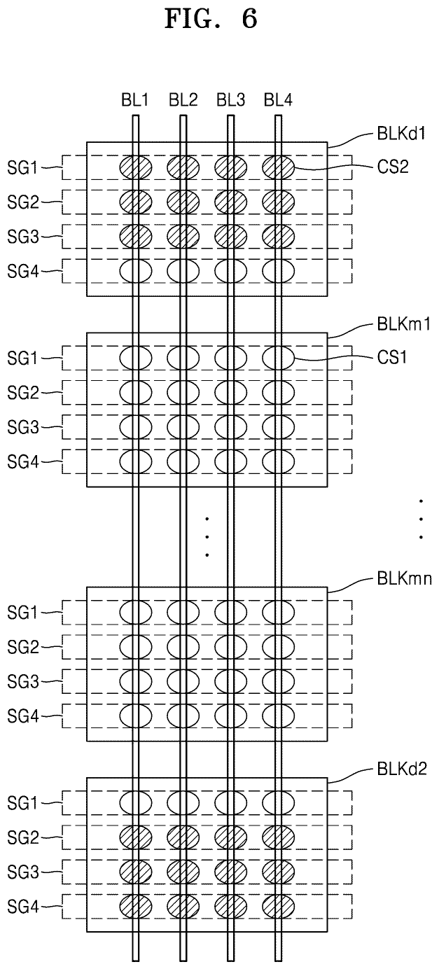

FIG. 6 is a detailed block diagram illustrating the memory cell array 130 of FIG. 1 according to an embodiment.

For convenience of description, detailed descriptions of the components described above are omitted. Referring to FIGS. 1, 2, and 6, the memory cell array 130 may include a plurality of memory blocks. In an embodiment, the memory cell array 130 may include a first dummy memory block BLKd1, first to nth main memory blocks BLKm1 to BLKmn, and a second dummy memory block BLKd2.

The first dummy memory block BLKd1 may include the first to fourth string groups SG1 to SG4. The first string group SG1 of the first dummy memory block BLKd1 may include the second channel structures CS2 which are connected to the first string selection line SSL1 and are not connected to the first to fourth bit lines BL1 to BL4. The second string group SG2 of the first dummy memory block BLKd1 may include the second channel structures CS2 which are connected to the second string selection line SSL2 and are not connected to the first to fourth bit lines BL1 to BL4. The third string group SG3 of the first dummy memory block BLKd1 may include the second channel structures CS2 which are connected to the third string selection line SSL3 and are not connected to the first to fourth bit lines BL1 to BL4. The fourth string group SG4 of the first dummy memory block BLKd1 may include the first channel structures CS1 which are connected to the fourth string selection line SSL4 and are connected to the first to fourth bit lines BL1 to BL4.

The first main memory block BLKm1 may include the first to fourth string groups SG1 to SG4. The first string group SG1 of the first main memory block BLKm1 may include the first channel structures CS1 which are connected to the first string selection line SSL1 and are connected to the first to fourth bit lines BL1 to BL4. The second string group SG2 of the first main memory block BLKm1 may include the first channel structures CS1 which are connected to the second string selection line SSL2 and are connected to the first to fourth bit lines BL1 to BL4. The third string group SG3 of the first main memory block BLKm1 may include the first channel structures CS1 which are connected to the third string selection line SSL3 and are connected to the first to fourth bit lines BL1 to BL4. The fourth string group SG4 of the first main memory block BLKm1 may include the first channel structures CS1 which are connected to the fourth string selection line SSL4 and are connected to the first to fourth bit lines BL1 to BL4.

The nth main memory block BLKmn may include the first to fourth string groups SG1 to SG4. The first string group SG1 of the nth main memory block BLKmn may include the first channel structures CS1 which are connected to the first string selection line SSL1 and are connected to the first to fourth bit lines BL1 to BL4. The second string group SG2 of the nth main memory block BLKmn may include the first channel structures CS1 which are connected to the second string selection line SSL2 and are connected to the bit lines BL1, BL2, BL3, and BL4. The third string group SG3 of the nth main memory block BLKmn may include the first channel structures CS1 which are connected to the third string selection line SSL3 and are connected to the first to fourth bit lines BL1 to BL4. The fourth string group SG4 of the nth main memory block BLKmn may include the first channel structures CS1 which are connected to the fourth string selection line SSL4 and are connected to the first to fourth bit lines BL1 to BL4.

The second dummy memory block BLKd2 may include the first to fourth string groups SG1 to SG4. The first string group SG1 of the second dummy memory block BLKd2 may include the first channel structures CS1 which are connected to the first string selection line SSL1 and are connected to the first to fourth bit lines BL1 to BL4. The second string group SG2 of the second dummy memory block BLKd2 may include the second channel structures CS2 which are connected to the second string selection line SSL2 and are not connected to the first to fourth bit lines BL1 to BL4. The third string group SG3 of the second dummy memory block BLKd2 may include the second channel structures CS2 which are connected to the third string selection line SSL3 and are not connected to the first to fourth bit lines BL1 to BL4. The fourth string group SG4 of the second dummy memory block BLKd2 may include the second channel structures CS2 which are connected to the fourth string selection line SSL4 and are not connected to the first to fourth bit lines BL1 to BL4.

In an example, the string groups within each memory block may be spaced apart by a constant distance or pitch. The spacing between adjacent memory blocks may exceed the pitch between string groups within a single memory block. Alternatively or additionally, the spacing between immediately adjacent string groups of a dummy memory block (e.g., BLKd1 or BLKd2) and a neighboring main memory block (e.g., BLKm1 or BLKmn) may exceed the pitch between string groups within a single memory block. For example, the spacing between the string group SG4 of dummy memory block BLKd1 and immediately adjacent string group SG1 of main memory block BLKm1 may exceed the pitch of string groups SG1 to SG4. The spacing between the string group SG1 of dummy memory block BLKd2 and immediately adjacent string group SG4 of main memory block BLKmn may also exceed the pitch of string groups SG1 to SG4.

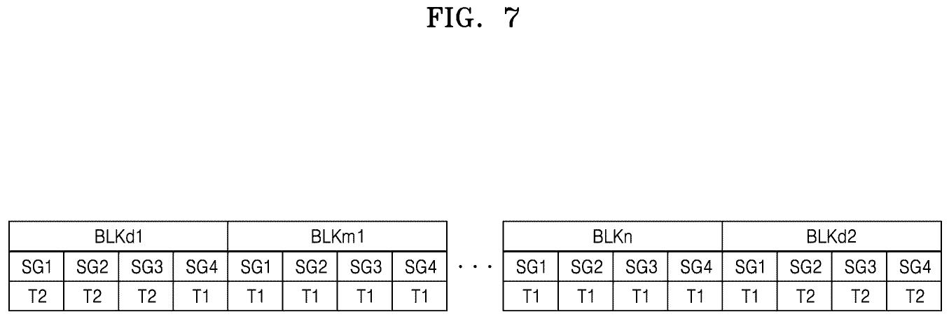

FIG. 7 is a table describing the channel structure types of the first to fourth string groups SG1 to SG4 of FIG. 6.

Referring to FIGS. 1, 6, and 7, the first string group SG1 of the first dummy memory block BLKd1 may be of the second type T2, the second string group SG2 of the first dummy memory block BLKd1 may be of the second type T2, the third string group SG3 of the first dummy memory block BLKd1 may be of the second type T2, and the fourth string group SG4 of the first dummy memory block BLKd1 may be of the first type T1.

The first string group SG1 of the first main memory block BLKm1 may be of the first type T1, the second string group SG2 of the first main memory block BLKm1 may be of the first type T1, the third string group SG3 of the first main memory block BLKm1 may be of the first type T1, and the fourth string group SG4 of the first main memory block BLKm1 may be of the first type T1.

The first string group SG1 of the nth main memory block BLKmn may be of the first type T1, the second string group SG2 of the nth main memory block BLKmn may be of the first type T1, the third string group SG3 of the nth main memory block BLKmn may be of the first type T1, and the fourth string group SG4 of the nth main memory block BLKmn may be of the first type T1.

The first string group SG1 of the second dummy memory block BLKd2 may be of the first type T1, the second string group SG2 of the second dummy memory block BLKd2 may be of the second type T2, the third string group SG3 of the second dummy memory block BLKd2 may be of the second type T2, and the fourth string group SG4 of the second dummy memory block BLKd2 may be of the second type T2.

As described above, the first and second dummy memory blocks BLKd1 and BLKd2 may each include both the first type T1 of the string group and the second type T2 of the string group. For example, the first and second dummy memory blocks BLKd1 and BLKd2 may each include both the first channel structures CS1 and the second channel structures CS2. Each of the first to nth main memory blocks BLKm1 to BLKmn may include only the first type T1 of string groups. Each of the first to nth main memory blocks BLKm1 to BLKmn may include only the first channel structures CS1.

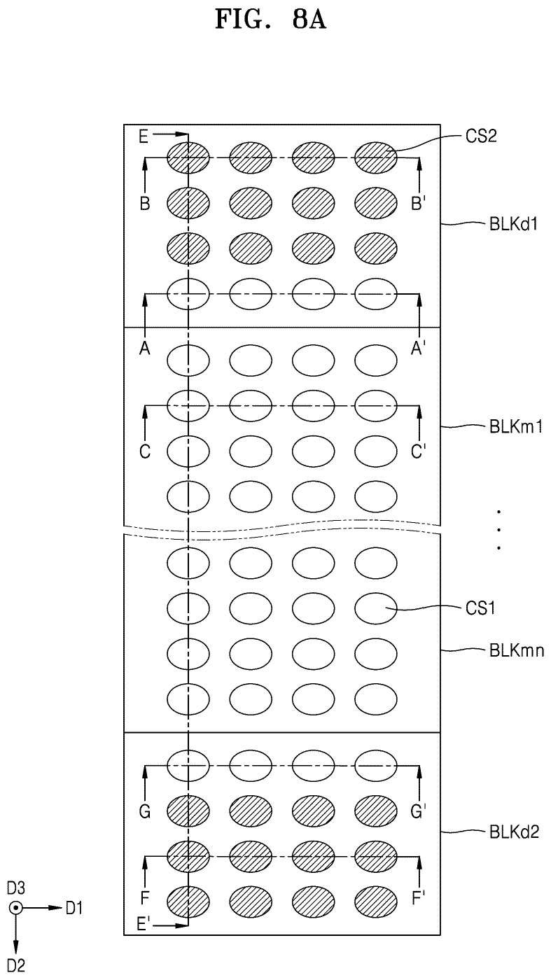

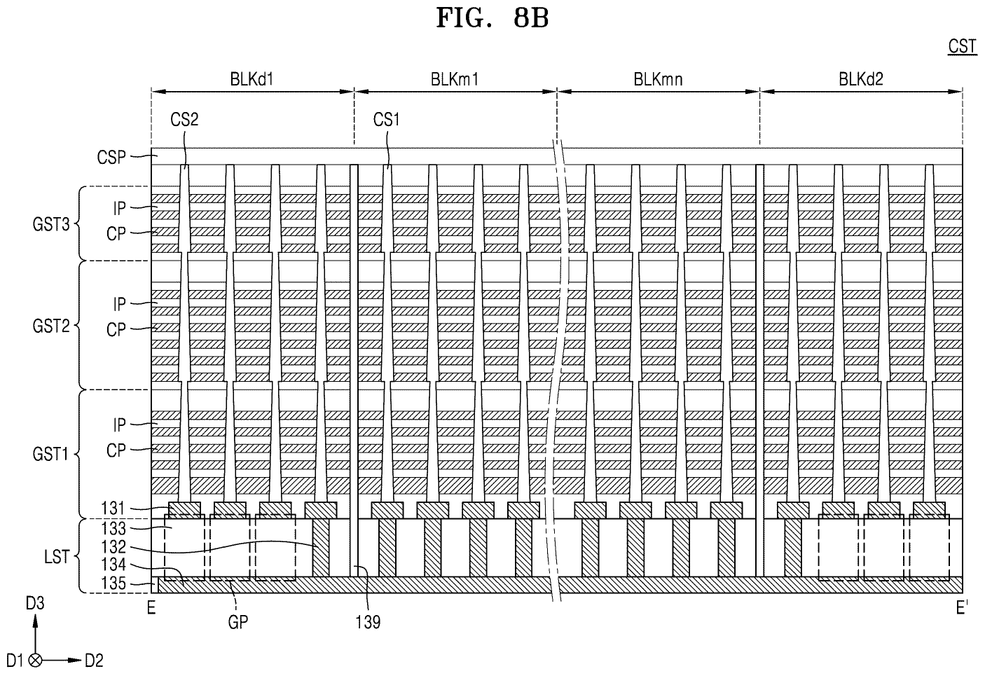

FIG. 8A is a plan view illustrating the memory device 100 of FIG. 1 according to an embodiment. FIG. 8B is a cross-sectional view taken along line E-E′ of FIG. 8A.

For convenience of description, detailed descriptions of the components described above are omitted. Referring to FIGS. 6, 8A, and 8B, the first and second dummy memory blocks BLKd1 and BLKd2 may be disposed on both sides of the main memory blocks BLKm. In an embodiment, the first dummy memory block BLKd1 may be disposed on a first side of the first to nth main memory blocks BLKm1 to BLKmn, and the second dummy memory block BLKd2 may be disposed on a second side facing the first side of the first to nth main memory blocks BLKm1 to BLKmn in the second direction D2.

For example, the first dummy memory block BLKd1, the first to nth main memory blocks BLKm1 to BLKmn, and the second dummy memory block BLKd2 may be disposed in the second direction D2. The nth main memory block BLKmn may be disposed on the second dummy memory block BLKd2, an n−1 main memory block (not shown) may be disposed on the nth main memory block BLKmn, the first main memory block BLKm1 may be disposed on a second main memory block (not shown), and the first dummy memory block BLKd1 may be disposed on the first main memory block BLKm1.

The first to fourth string groups SG1 to SG4 may be disposed to be spaced apart from each other in the second direction D2. The first to fourth bit lines BL1 to BL4 may be disposed to be spaced apart from each other in the first direction D1. The first to fourth bit lines BL1 to BL4 may extend in the second direction D2.

The memory device 100 may include a plurality of memory blocks. The plurality of memory blocks may include a plurality of main memory blocks BLKm and the first and second dummy memory blocks BLKd1 and BLKd2. In an embodiment, the dummy memory block BLKd may be disposed on both sides of the plurality of main memory blocks BLKm. The dummy memory block BLKd may be formed to have the same structure as or similar structure to the plurality of main memory blocks BLKm. However, the dummy memory block BLKd may include a plurality of dummy memory cells that do not function as memory cells (e.g., are not configured to store data).

For example, data may be stored in memory cells included in the first type T1 of a string group (i.e., the fourth string group SG4) of the first dummy memory block BLKd1. Data may be stored in memory cells included in the first type T1 of a string group (i.e., the first string group SG1) of the second dummy memory block BLKd2.

The memory device 100 may include the memory cell structure CST. The memory cell structure CST may include the lower wiring structure LST, the first gate stack structure GST1, the second gate stack structure GST2, the third gate stack structure GST3, the first channel structures CS1, the second channel structures CS2, the common source plate CSP, etc.

The lower wiring structure LST may include the first interlayer insulating layer 135, the bit lines 134, the second interlayer insulating layer 133, and the first contacts 132. The first interlayer insulating layer 135 may include an insulating material. In some embodiments, the first interlayer insulating layer 135 may be a multilayer including a plurality of insulating layers.

The bit lines 134 may be disposed in the first interlayer insulating layer 135. The bit lines 134 may extend in the second direction D2. The bit lines 134 may be arranged in the first direction D1. The bit lines 134 may each include a conductive material.

The second interlayer insulating layer 133 may be disposed on the first interlayer insulating layer 135. The second interlayer insulating layer 133 may include an insulating material. In some embodiments, the second interlayer insulating layer 133 may be a multilayer including a plurality of insulating layers.

The first contacts 132 may be disposed on the bit line 134. The first contacts 132 may be disposed in the second interlayer insulating layer 133. The first contact 132 may electrically connect the bit line 134 to the first channel structure CS1. The first contacts 132 may each include a conductive material.

The number of the second and first interlayer insulating layers 133 and 135 may not be limited to those illustrated. In some embodiments, the number of the second and first interlayer insulating layers 133 and 135 may be two or less, or four or more.

The first gate stack structure GST1 may be disposed on the second interlayer insulating layer 133. The second gate stack structure GST2 may be disposed on the first gate stack structure GST1. The third gate stack structure GST3 may be disposed on the second gate stack structure GST2. The number of the first to third gate stack structures GST1, GST2, and GST3 may not be limited to those illustrated. In some embodiments, the number of the first to third gate stack structures GST1, GST2, and GST3 may be two or less, or four or more.

Each of the first to third gate stack structures GST1, GST2, and GST3 may include the insulating patterns IP and the conductive patterns CP, which are alternately stacked on each other in the third direction D3.

The insulating patterns IP may each include an insulating material. For example, the insulating patterns IP may each include an oxide or a low dielectric material, but are not limited thereto. The conductive patterns CPs may each include a conductive material. For example, the conductive patterns CP may each include at least one of a doped semiconductor, a metal, a conductive metal nitride, or a transition metal, but are not limited thereto.

The first channel structures CS1 may extend in the third direction D3 and pass through the first gate stack structure GST1, the second gate stack structure GST2, and the third gate stack structure GST3. The first channel structure CS1 may be disposed on the second interlayer insulating layer 133 in a cell area.

The second channel structures CS2 may extend in the third direction D3 and pass through the first gate stack structure GST1, the second gate stack structure GST2, and the third gate stack structure GST3. The second channel structure CS2 may be disposed on the second interlayer insulating layer 133 in the cell area. The common source plate CSP may be disposed on the third gate stack structure GST3.

The second channel structure CS2 may be covered by the second interlayer insulating layer 133, and this portion may be referred to as the gap portion GP. The second channel structure CS2 may be covered by the gap portion GP so as not to be electrically connected to the bit line BL.

The cross-sectional view taken along line A-A′ of FIG. 8A may be the same as the cross-sectional view (i.e., FIG. 5B) taken along line A-A′ of FIG. 5A. The cross-sectional view taken along line C-C′ of FIG. 8A may also be the same as the cross-sectional view taken along line A-A′ of FIG. 5A. The cross-sectional view taken along line B-B′ of FIG. 8A may be the same as the cross-sectional view (i.e., FIG. 5C) taken along line B-B′ of FIG. 5A. The cross-sectional view taken along line F-F′ of FIG. 8A may also be the same as the cross-sectional view (i.e., FIG. 5C) taken along line B-B′ of FIG. 5A. The cross-sectional view taken along line G-G′ of FIG. 8A may be the same as the cross-sectional view (i.e., FIG. 5B) taken along line A-A′ of FIG. 5A.

In an embodiment, the first and second dummy memory blocks BLKd1 and BLKd2 may be disposed at the outermost portion of the memory cell array 130. The first and second dummy memory blocks BLKd1 and BLKd2 may be disposed in an edge area of the memory cell array 130. The memory blocks may be sequentially disposed in the second direction D2. The first dummy memory block BLKd1, the first to nth main memory blocks BLKm1 to BLKmn, and the second dummy memory block BLKd2 may be sequentially disposed in the second direction D2.

In an embodiment, the first type T1 of a string group (i.e., the fourth string group SG4) of the first dummy memory block BLKd1 may be disposed adjacent to the first to nth main memory blocks BLKm1 to BLKmn. The first type T1 of a string group (i.e., the first string group SG1) of the second dummy memory block BLKd2 may be disposed adjacent to the first to nth main memory blocks BLKm1 to BLKmn.

In an embodiment, types of the string groups of the first and second dummy memory blocks BLKd1 and BLKd2 may have a mirror structure with respect to the center of the memory cell array 130. For example, channel structures of the first and second dummy memory blocks BLKd1 and BLKd2 may be formed symmetrically with respect to the center of the memory cell array 130. For example, only the fourth string group SG4 of the first dummy memory block BLKd1 may be of the first type T1, and only the first string group SG1 of the second dummy memory block BLKd2 may be of the first type T1. The second channel structures CS2 may be disposed in an outer portion (or edge area) of the memory cell array 130, and thus, the reliability of memory cells may be improved.

As described above, the first channel structure CS1 included in the first type T1 of the string group SG may be connected to the bit line BL by the first contact 132. On the other hand, the first contact 132 may not be formed in the second channel structure CS2 included in the second type T2 of the string group SG. Accordingly, the second channel structure CS2 may not be electrically connected to the bit line BL.

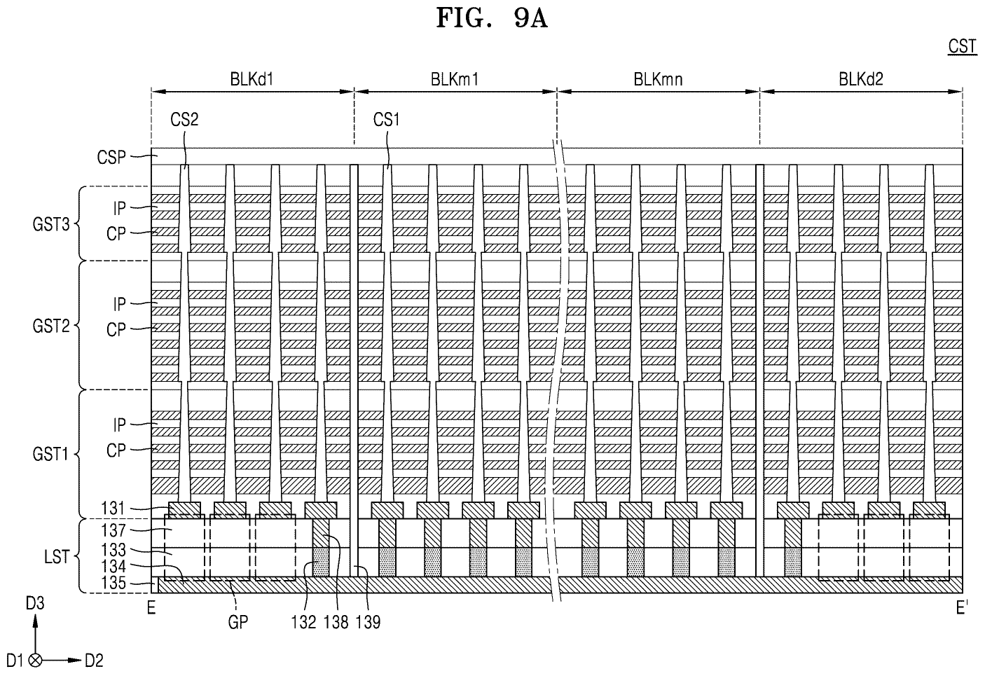

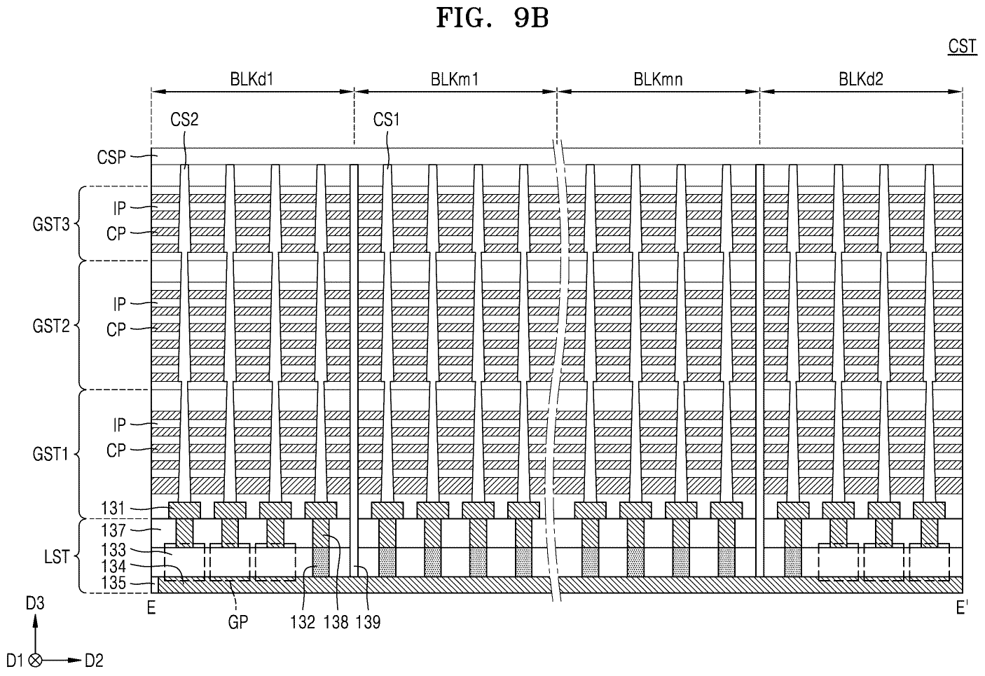

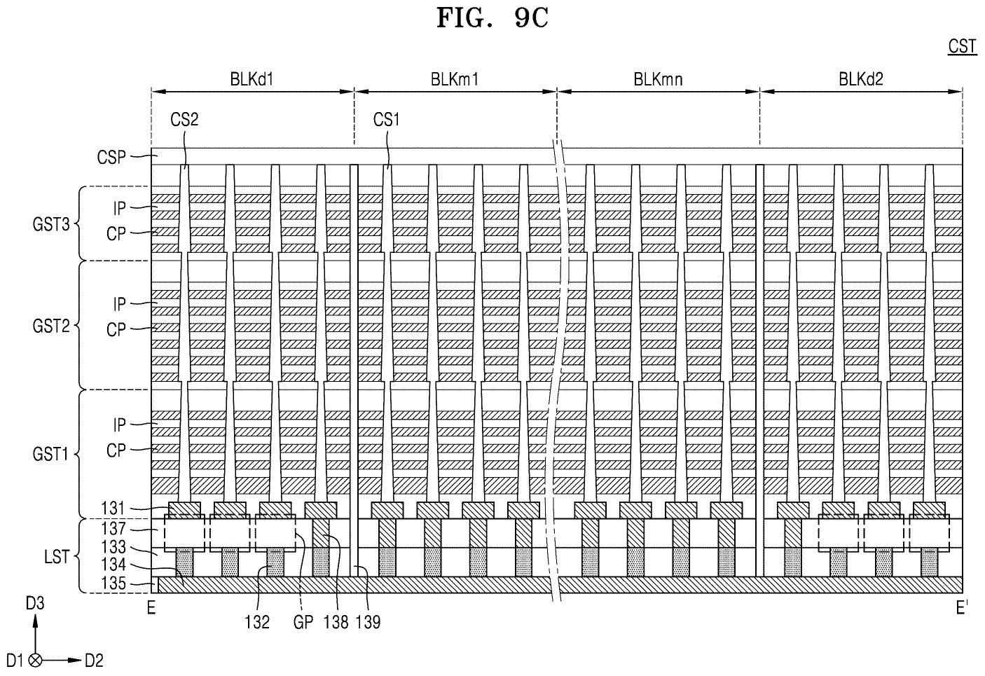

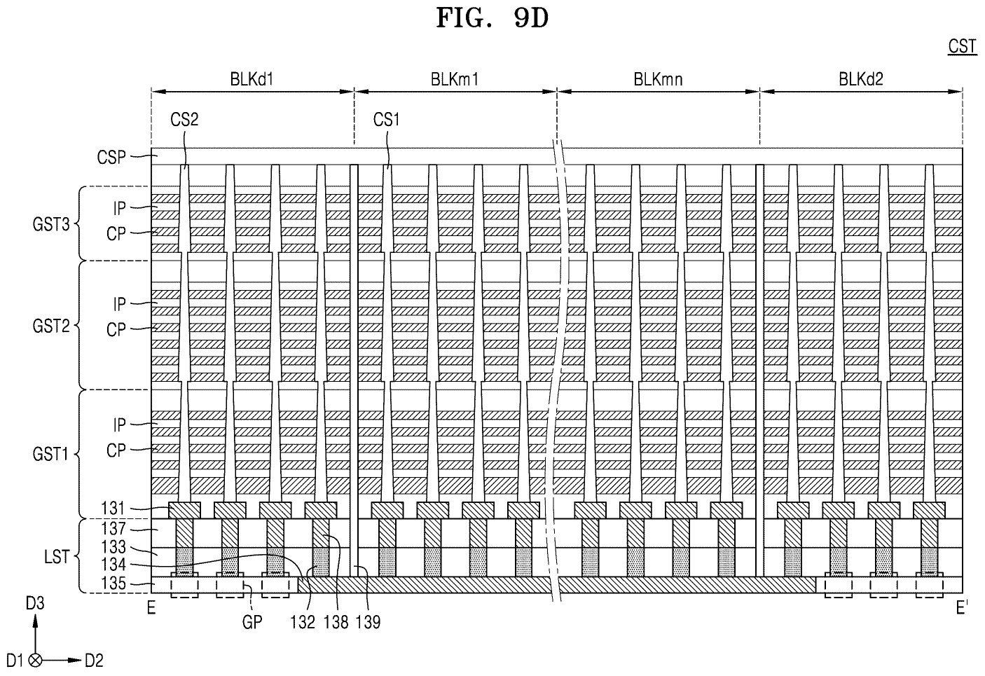

FIGS. 9A to 9D are cross-sectional views taken along line E-E′ of FIG. 8A according to some embodiments.

The lower wiring structure LST may include the first interlayer insulating layer 135, the bit lines 134, the second interlayer insulating layer 133, a third interlayer insulating layer 137, the first contacts 132, and second contacts 138.

The first interlayer insulating layer 135 may include an insulating material. In some embodiments, the first interlayer insulating layer 135 may be a multilayer including a plurality of insulating layers. The bit lines 134 may be disposed in the first interlayer insulating layer 135. The bit lines 134 may extend in the second direction D2. The bit lines 134 may be arranged in the first direction D1. The bit lines 134 may include a conductive material.

The second interlayer insulating layer 133 may be disposed on the first interlayer insulating layer 135. The second interlayer insulating layer 133 may include an insulating material. In some embodiments, the second interlayer insulating layer 133 may be a multilayer including a plurality of insulating layers.

The first contacts 132 may be disposed on the bit line 134. The first contacts 132 may be disposed in the second interlayer insulating layer 133. The first contact 132 may electrically connect the bit line 134 and the second contact 138. The first contacts 132 may each include a conductive material.

The third interlayer insulating layer 137 may be disposed on the second interlayer insulating layer 133. The third interlayer insulating layer 137 may include an insulating material. In some embodiments, the third interlayer insulating layer 137 may be a multilayer including a plurality of insulating layers.

The second contacts 138 may be disposed on the first contacts 132. The second contacts 138 may be disposed in the third interlayer insulating layer 137. The second contacts 138 may electrically connect the first contacts 132 to the first channel structure CS1. The second contacts 138 may each include a conductive material.

The first gate stack structure GST1 may be disposed on the third interlayer insulating layer 137. The second gate stack structure GST2 may be disposed on the first gate stack structure GST1. The third gate stack structure GST3 may be disposed on the second gate stack structure GST2.

Referring to FIG. 9A, the first contact 132 and the second contact 138 may not be formed in the second channel structure CS2. Accordingly, the second channel structure CS2 may not be electrically connected to the bit line BL. The second channel structure CS2 may be covered by the second interlayer insulating layer 133 and the third interlayer insulating layer 137, and this portion may be referred to as the gap portion GP. The second channel structure CS2 may be covered by the gap portion GP so as not to be electrically connected to the bit line BL.

For example, the memory device 100 may include the memory cell structure CST, and the memory cell structure CST may include the lower wiring structure LST, the gate stack structure GST, the first channel structure CS1, the first contact 132, the second contact 138, and the second channel structure CS2. The lower wiring structure LST may include the first interlayer insulating layer 135 on which the bit line 134 is disposed, the second interlayer insulating layer 133, and the third interlayer insulating layer 137. The gate stack structure GST may be disposed on the lower wiring structure LST and include the conductive patterns CP and the insulating patterns IP alternately stacked on each other. The first channel structure CS1 may pass through the gate stack structure GST. The second channel structure CS2 may pass through the gate stack structure GST. The first contact 132 may electrically connect the bit line 134 to the second contact 138. The first contact 132 may be disposed in the second interlayer insulating layer 133. The second contact 138 may electrically connect the first contact 132 to the first channel structure CS1. The second contact 138 may be disposed in the third interlayer insulating layer 137. No contact may be disposed between the bit line 134 and the second channel structure CS2.

Referring to FIG. 9B, the first contact 132 may not be formed in the second channel structure CS2. Accordingly, the second channel structure CS2 may not be electrically connected to the bit line BL. The second channel structure CS2 may be covered by the second interlayer insulating layer 133, and this portion may be referred to as the gap portion GP. The second channel structure CS2 may be covered by the gap portion GP so as not to be electrically connected to the bit line BL.

For example, the memory device 100 may include the memory cell structure CST, and the memory cell structure CST may include the lower wiring structure LST, the gate stack structure GST, the first channel structure CS1, the first contact 132, the second contact 138, and the second channel structure CS2. The lower wiring structure LST may include the first interlayer insulating layer 135 on which the bit line 134 is disposed, the second interlayer insulating layer 133, and the third interlayer insulating layer 137. The gate stack structure GST may be disposed on the lower wiring structure LST and include the conductive patterns CP and the insulating patterns IP alternately stacked on each other. The first channel structure CS1 may pass through the gate stack structure GST. The second channel structure CS2 may pass through the gate stack structure GST. The first contact 132 may electrically connect the bit line 134 to the second contact 138. The first contact 132 may be disposed in the second interlayer insulating layer 133. The second contact 138 may electrically connect the first contact 132 to the first channel structure CS1. The second contact 138 may be disposed in the third interlayer insulating layer 137. The second contact 138 may be connected to the second channel structure CS2. The second contact 138 may be disposed in the third interlayer insulating layer 137. No contact may be disposed between the second contact 138 and the bit line 134 corresponding to the second channel structure CS2.

Referring to FIG. 9C, the second contact 138 may not be formed in the second channel structure CS2. Accordingly, the second channel structure CS2 may not be electrically connected to the bit line BL. The second channel structure CS2 may be covered by the third interlayer insulating layer 137, and this portion may be referred to as the gap portion GP. The second channel structure CS2 may be covered by the gap portion GP so as not to be electrically connected to the bit line BL.

For example, the memory device 100 may include the memory cell structure CST, and the memory cell structure CST may include the lower wiring structure LST, the gate stack structure GST, the first channel structure CS1, the first contact 132, the second contact 138, and the second channel structure CS2. The lower wiring structure LST may include the first interlayer insulating layer 135 on which the bit line 134 is disposed, the second interlayer insulating layer 133, and the third interlayer insulating layer 137. The gate stack structure GST may be disposed on the lower wiring structure LST and include the conductive patterns CP and the insulating patterns IP alternately stacked on each other. The first channel structure CS1 may pass through the gate stack structure GST. The second channel structure CS2 may pass through the gate stack structure GST. The first contact 132 may electrically connect the bit line 134 to the second contact 138. The first contact 132 may be disposed in the second interlayer insulating layer 133. The second contact 138 may electrically connect the first contact 132 to the first channel structure CS1. The second contact 138 may be disposed in the third interlayer insulating layer 137. The first contact 132 may be connected to a bit line corresponding to the second channel structure CS2. The first contact 132 may be disposed in the second interlayer insulating layer 133. No contact may be disposed between the first contact 132 and the second channel structure CS2.

Referring to FIG. 9D, the first contact 132 and the second contact 138 may be formed in the second channel structure CS2. The second channel structure CS2 may be electrically connected to the first contact 132 through the second contact 138. However, the bit line 134 may not extend to the second channel structures CS2 in the first interlayer insulating layer 135. The first contact 132 connected to the second contact 138 connected to the second channel structure CS2 may not be connected to the bit line 134. For example, the first contact 132 on the second channel structure CS2 may not be connected to the bit line 134. The first contact 132 on the second channel structure CS2 may be covered by a part of the first interlayer insulating layer 135, and this portion may be referred to as the gap portion GP. The second channel structure CS2 may be covered by the gap portion GP so as not to be electrically connected to the bit line BL.

In an embodiment, types of string groups of the first and second dummy memory blocks BLKd1 and BLKd2 may have a mirror structure with respect to the center of the memory cell array 130. For example, channel structures of the first and second dummy memory blocks BLKd1 and BLKd2 may be formed symmetrically with respect to the center of the memory cell array 130. For example, only the fourth string group SG4 of the first dummy memory block BLKd1 may be of the first type T1, and only the first string group SG1 of the second dummy memory block BLKd2 may be of the first type T1. The second channel structures CS2 may be disposed in an outer portion (or edge area) of the memory cell array 130, and thus, the reliability of memory cells may be improved.

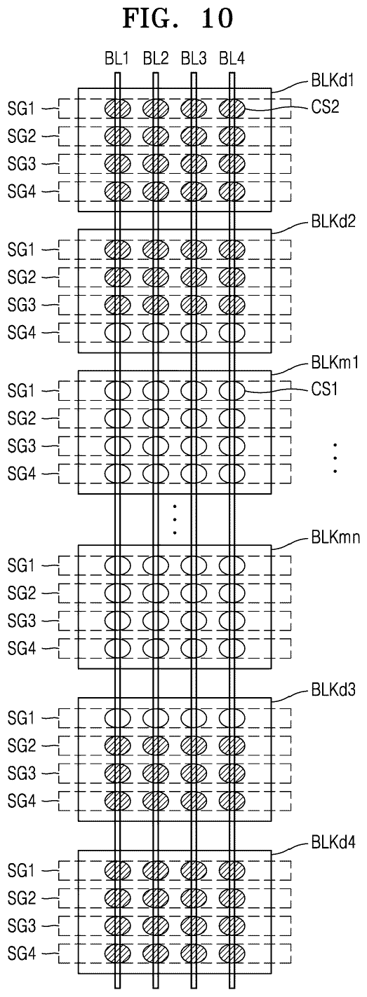

FIG. 10 is a detailed block diagram illustrating the memory cell array 130 of FIG. 1 according to an embodiment.

For convenience of description, detailed descriptions of the components described above are omitted. Referring to FIGS. 1, 2, and 10, the memory cell array 130 may include a plurality of memory blocks. In an embodiment, the memory cell array 130 may include the first dummy memory block BLKd1, the second dummy memory block BLKd2, the first to nth main memory blocks BLKm1 to BLKmn, a third dummy memory block BLKd3, and a fourth dummy memory block BLKd4.

In an embodiment, the main memory block BLKm may include only the first channel structures CS1. The main memory block BLKm may include only the channel structures CS connected to the bit line BL. For example, the main memory block BLKm may include only memory cells connected to the bit line BL.

In an embodiment, the dummy memory block BLKd may include both the first channel structures CS1 and the second channel structures CS2. The dummy memory block BLKd may include both the channel structures CS which are connected to the bit line BL and the channel structures CS which are not connected to the bit line BL. The dummy memory block BLKd may include both memory cells which are connected to the bit line BL and memory cells which are not connected to the bit line BL.

In an embodiment, the dummy memory block BLKd may include only the second channel structures CS2. The dummy memory block BLKd may include only the channel structures CS that are not connected to the bit line BL. For example, the dummy memory block BLKd may include only the memory cells which are not connected to the bit line BL.

The first dummy memory block BLKd1 may include the first to fourth string groups SG1 to SG4. The first string group SG1 of the first dummy memory block BLKd1 may include the second channel structures CS2 which are connected to the first string selection line SSL1 and are not connected to the first to fourth bit lines BL1 to BL4. The second string group SG2 of the first dummy memory block BLKd1 may include the second channel structures CS2 which are connected to the second string selection line SSL2 and are not connected to the first to fourth bit lines BL1 to BL4. The third string group SG3 of the first dummy memory block BLKd1 may include the second channel structures CS2 which are connected to the third string selection line SSL3 and are not connected to the first to fourth bit lines BL1 to BL4. The fourth string group SG4 of the first dummy memory block BLKd1 may include the second channel structures CS2 which are connected to the fourth string selection line SSL4 and are not connected to the first to fourth bit lines BL1 to BL4.

The second dummy memory block BLKd2 may include the first to fourth string groups SG1 to SG4. The first string group SG1 of the second dummy memory block BLKd2 may include the second channel structures CS2 which are connected to the first string selection line SSL1 and are not connected to the first to fourth bit lines BL1 to BL4. The second string group SG2 of the second dummy memory block BLKd2 may include the second channel structures CS2 which are connected to the second string selection line SSL2 and are not connected to the first to fourth bit lines BL1 to BL4. The third string group SG3 of the second dummy memory block BLKd2 may include the second channel structures CS2 which are connected to the third string selection line SSL3 and are not connected to the first to fourth bit lines BL1 to BL4. The fourth string group SG4 of the second dummy memory block BLKd2 may include the first channel structures CS1 which are connected to the fourth string selection line SSL4 and are connected to the first to fourth bit lines BL1 to BL4.

The first main memory block BLKm1 may include the first to fourth string groups SG1 to SG4. The first string group SG1 of the first main memory block BLKm1 may include the first channel structures CS1 which are connected to the first string selection line SSL1 and are connected to the first to fourth bit lines BL1 to BL4. The second string group SG2 of the first main memory block BLKm1 may include the first channel structures CS1 which are connected to the second string selection line SSL2 and are connected to the first to fourth bit lines BL1 to BL4. The third string group SG3 of the first main memory block BLKm1 may include the first channel structures CS1 which are connected to the third string selection line SSL3 and are connected to the first to fourth bit lines BL1 to BL4. The fourth string group SG4 of the first main memory block BLKm1 may include the first channel structures CS1 which are connected to the fourth string selection line SSL4 and are connected to the first to fourth bit lines BL1 to BL4.

The nth main memory block BLKmn may include the first to fourth string groups SG1 to SG4. The first string group SG1 of the nth main memory block BLKmn may include the first channel structures CS1 which are connected to the first string selection line SSL1 and are connected to the first to fourth bit lines BL1 to BL4. The second string group SG2 of the nth main memory block BLKmn may include the first channel structures CS1 which are connected to the second string selection line SSL2 and are connected to the first to fourth bit lines BL1 to BL4. The third string group SG3 of the nth main memory block BLKmn may include first channel structures CS1 connected to the third string selection line SSL3 and connected to the bit lines BL1, BL2, BL3, and BL4. The fourth string group SG4 of the nth main memory block BLKmn may include the first channel structures CS1 which are connected to the fourth string selection line SSL4 and are connected to the first to fourth bit lines BL1 to BL4.

The third dummy memory block BLKd3 may include the first to fourth string groups SG1 to SG4. The first string group SG1 of the third dummy memory block BLKd3 may include the first channel structures CS1 which are connected to the first string selection line SSL1 and are connected to the first to fourth bit lines BL1 to BL4. The second string group SG2 of the third dummy memory block BLKd3 may include the second channel structures CS2 which are connected to the second string selection line SSL2 and are not connected to the first to fourth bit lines BL1 to BL4. The third string group SG3 of the third dummy memory block BLKd3 may include the second channel structures CS2 which are connected to the third string selection line SSL3 and are not connected to the first to fourth bit lines BL1 to BL4. The fourth string group SG4 of the third dummy memory block BLKd3 may include the second channel structures CS2 which are connected to the fourth string selection line SSL4 and are not connected to the first to fourth bit lines BL1 to BL4.

The fourth dummy memory block BLKd4 may include the first to fourth string groups SG1 to SG4. The first string group SG1 of the fourth dummy memory block BLKd4 may include the second channel structures CS2 which are connected to the first string selection line SSL1 and are not connected to the first to fourth bit lines BL1 to BL4. The second string group SG2 of the fourth dummy memory block BLKd4 may include the second channel structures CS2 which are connected to the second string selection line SSL2 and are not connected to the first to fourth bit lines BL1 to BL4. The third string group SG3 of the fourth dummy memory block BLKd4 may include the second channel structures CS2 which are connected to the third string selection line SSL3 and are not connected to the first to fourth bit lines BL1 to BL4. The fourth string group SG4 of the fourth dummy memory block BLKd4 may include the second channel structures CS2 which are connected to the fourth string selection line SSL4 and are not connected to the first to fourth bit lines BL1 to BL4.

In other words, the first string group SG1 of the first dummy memory block BLKd1 may be of the second type T2, the second string group SG2 of the first dummy memory block BLKd1 may be of the second type T2, the third string group SG3 of the first dummy memory block BLKd1 may be of the second type T2, and the fourth string group SG4 of the first dummy memory block BLKd1 may be of the second type T2.

The first string group SG1 of the second dummy memory block BLKd2 may be of the second type T2, the second string group SG2 of the second dummy memory block BLKd2 may be of the second type T2, the third string group SG3 of the second dummy memory block BLKd2 may be of the second type T2, and the fourth string group SG4 of the second dummy memory block BLKd2 may be of the first type T1.

The first string group SG1 of the first main memory block BLKm1 may be of the first type T1, the second string group SG2 of the first main memory block BLKm1 may be of the first type T1, the third string group SG3 of the first main memory block BLKm1 may be of the first type T1, and the fourth string group SG4 of the first main memory block BLKm1 may be of the first type T1.

The first string group SG1 of the nth main memory block BLKmn may be of the first type T1, the second string group SG2 of the nth main memory block BLKmn may be of the first type T1, the third string group SG3 of the nth main memory block BLKmn may be of the first type T1, and the fourth string group SG4 of the nth main memory block BLKmn may be of the first type T1.

The first string group SG1 of the third dummy memory block BLKd3 may be of the first type T1, the second string group SG2 of the third dummy memory block BLKd3 may be of the second type T2, the third string group SG3 of the third dummy memory block BLKd3 may be of the second type T2, and the fourth string group SG4 of the third dummy memory block BLKd3 may be of the second type T2.

The first string group SG1 of the fourth dummy memory block BLKd4 may be of the second type T2, the second string group SG2 of the third dummy memory block BLKd3 may be of the second type T2, the third string group SG3 of the third dummy memory block BLKd3 may be of the second type T2, and the fourth string group SG4 of the third dummy memory block BLKd3 may be of the second type T2.

Among the string groups SG1 to SG4 of the first to fourth dummy memory blocks BLKd1 to BLKd4, the string group SG (i.e., the fourth string group SG4 of the second dummy memory block BLKd2, and the first string group SG1 of the third dummy memory block BLKd3) adjacent to the first to nth main memory blocks BLKm1 to BLKmn may be of the first type T1. In the first to fourth dummy memory blocks BLKd1 to BLKd4, a string group far from an edge of the memory cell array 130 may be of the first type T1. In some examples, string groups closer to an edge of the memory cell array 130 may be of the second type T2, so as to provide distance to mitigate process issues.

Each of all of the first to fourth string groups SG1 to SG4 included in the main memory block BLKm may be of the first type T1. The main memory block BLKm may include only the first type T1 of string groups. The main memory block BLKm may include only string groups including the channel structures CS connected to a bit line.

As described above, the first dummy memory block BLKd1 and the fourth dummy memory block BLKd4 may include only the second channel structures CS2. The second dummy memory block BLKd2 and the third dummy memory block BLKd3 may include both the first channel structures SC1 and the second channel structures CS2. Each of the first to nth main memory blocks BLKm1 to BLKmn may include only the first channel structures SC1.

FIG. 11 is a flowchart illustrating an operating method of the memory device 100 according to an embodiment.

Referring to FIGS. 1 and 11, in order to perform a pre-program operation, the memory device 100 may apply the pre-program voltage VPGM to the word line WL connected to the second type T2 of a string group of the dummy memory block BLKd, apply the pass voltage VPASS to the ground selection line GSL connected to the second type T2 of the string group of the dummy memory block BLKd, and apply the ground voltage VSS to the common source line CSL connected to the second type T2 of the string group of the dummy memory block BLKd.

In operation S110, the memory device 100 may perform a pro-program operation. The memory device 100 may perform the pre-program operation on the second type T2 of the string group among string groups of the dummy memory block BLKd. For example, the memory device 100 may perform the pre-program operation on the first to third string groups SG1 to SG3 among the string groups SG1 to SG4 of the dummy memory block BLKd. The memory device 100 may perform the pre-program operation on each of cell structures included in the second type T2 of the string groups. The memory device 100 may perform the pre-program operation on the second channel structures CS2. Accordingly, a threshold voltage distribution of cells included in the second channel structure CS2 may be moved in a direction to increase.

In an embodiment, cell structures included in the first type T1 of the string group included in the dummy memory block BLKd may also be pre-programmed. However, the inventive concept is not limited thereto. In an embodiment, only cell structures included in the second type T2 of the string group included in the dummy memory block BLKd may be pre-programmed, and cell structures included in the first type T1 of the string group included in the dummy memory block BLKd may not be pre-programmed.

In operation S120, the memory device 100 may perform an erase operation. The memory device 100 may perform the erase operation on the second type T2 of each of the string groups on which the pre-program is performed. For example, the memory device 100 may perform the erase operation on the dummy memory block BLKd. The memory device 100 may perform the erase operation on the second channel structures CS2 of the dummy memory block BLKd. Accordingly, data stored in the first type T1 of the string groups included in the dummy memory block BLKd may be erased.

In an embodiment, the memory device 100 may perform operation S120 after performing operation S110. In another embodiment, the memory device 100 may perform operation S110 after performing operation S120. When operation S110 is performed after operation S120, in operation S110, only the second type T2 of the string group of the dummy memory block BLKd may be pre-programmed, and the first type T1 of the string group of the dummy memory block BLKd may not be pre-programmed.

As described above, the memory device 100 may perform the pre-program operation of applying the pre-program voltage VPGM to the dummy memory block BLKd. The memory device 100 may perform the erase operation of applying an erase voltage to the dummy memory block BLKd. The memory device 100 according to the inventive concept may perform the pre-program operation S110 on the second type T2 of the string group before or after the erase operation S120, thereby preventing damage to the cell string from occurring due to repeated erase operations performed on the second type T2 of the string group.

FIG. 12A is a timing diagram of voltages applied by the memory device 100 to lines during a pre-program operation and an erase operation according to an embodiment. FIG. 12B is a timing diagram for describing operations S110 and S120 of FIG. 11.

Referring to FIG. 12A, in the pre-program operation, the memory device (e.g., 100 in FIG. 1) may apply the pre-program voltage VPGM to the word lines WL connected to the second type T2 of each of the string groups of the dummy memory block BLKd on which the pre-program operation is to be performed. For example, the row decoder 160 may apply the pre-program voltage VPGM to a selected word line connected to the second channel structures CS2 of the dummy memory block BLKd. The row decoder 160 may apply a pass voltage VPASS to an unselected word line connected to the second channel structures CS2 of the dummy memory block BLKd.

The memory device 100 may apply the pass voltage VPASS to the ground selection line GSL connected to the second type T2 of each of the string groups of the dummy memory block BLKd. For example, the row decoder 160 may apply the pass voltage VPASS to the ground selection line GSL connected to the second channel structures CS2 of the dummy memory block BLKd.

The memory device 100 may apply the ground voltage VSS to the common source line CSL connected to the second type T2 of each of the string groups. For example, the row decoder 160 may apply the ground voltage VSS to the common source line CSL connected to the second channel structures CS2 of the dummy memory block BLKd. The row decoder 160 may apply the ground voltage VSS to the common source line CSL which is connected to the second channel structures CS2 of the dummy memory block BLKd which is not connected to the bit line BL and. When the memory device 100 performs the pre-program operation, a substrate may maintain the ground voltage VSS.

A period in which the pre-program voltage VPGM is applied to the word lines WL and a period in which the pass voltage VPASS is applied to the ground selection line GSL may overlap each other. For example, the pass voltage VPASS may be applied to the ground selection line GSL at a first time t1 when the pre-program voltage VPGM is applied to the word lines WL. In addition, the ground selection line GSL may be floated at the pass voltage VPASS at a second time t2 when the word lines WL are floated at the pre-program voltage VPGM. In an embodiment, the period in which the pre-program voltage VPGM is applied to the word lines WL and the period in which the pass voltage VPASS is applied to the ground selection line GSL may coincide with each other.

In addition, the period in which the pre-program voltage VPGM is applied to the word lines WL and a period in which the ground voltage VSS is applied to the common source line CSL may overlap each other. For example, the ground voltage VSS may be applied to the common source line CSL at the first time t1 when the pre-program voltage VPGM is applied to the word lines WL. In addition, the common source line CSL may be floated at the ground voltage VSS at the second time t2 when the word lines WL are floated at the pre-program voltage VPGM. In an embodiment, the period in which the pre-program voltage VPGM is applied to the word lines WL and a period in which the ground voltage VSS is applied to the common source line CSL may coincide with each other.

Because the memory cells formed in the second channel structure CS2 are not connected to the bit line BL, the memory cells may not be programmed by applying a voltage to the bit line BL. Accordingly, the memory device 100 according to an embodiment may apply the ground voltage VSS to the common source line CSL, the pass voltage VPASS to the ground selection line GSL, and the pre-program voltage VPGM to the word lines WL, thereby pre-programming the memory cells formed in the second channel structures CS2.

As the pass voltage VPASS is applied to the ground selection line GSL, the ground selection transistor GST may be turned on, and the ground voltage VSS may be applied to a source of a memory cell of a cell string included in the second type T2 of each of the string groups. Even though a bit line voltage is not applied because the bit line BL is not connected to the cell string included in the second type T2 of the string group, the ground voltage VSS may be applied to the common source line CSL, and the pass voltage VPASS may be applied to the ground selection line GSL, and thus, cells included in the second channel structure CS2 may be pre-programmed. In this case, the ground voltage VSS may be applied to the substrate. However, the inventive concept is not limited thereto, and the memory device 100 may apply the pass voltage VPASS to the ground selection line GSL connected to a string corresponding to the second channel structures CS2 of the dummy memory block BLKd, and apply a voltage other than the ground voltage VSS to the common source line CSL.

In the erase operation, the memory device 100 may apply a word line erase voltage VWERS to the word lines WL of the dummy memory block BLKd, apply a ground erase voltage VGERS to the ground selection line GSL of the dummy memory block BLKd, and apply an erase voltage VERS to the common source line CSL of the dummy memory block BLKd. In this case, the word line erase voltage VWERS may be the ground voltage VSS or may have a level close to the ground voltage VSS. The ground erase voltage VGERS may have a value lower than the erase voltage VERS by a certain level. For example, the memory device 100 may apply the ground erase voltage VGERS to the ground selection line GSL based on the level of the erase voltage VERS applied to the common source line CSL. When the memory device 100 performs the erase operation, the erase voltage VERS may also be applied to the substrate.

As described above, the memory device 100 may perform the pre-program operation and the erase operation on the second type T2 of the string groups of the dummy memory block. Accordingly, the memory device 100 with improved reliability is provided.

FIGS. 12B and 12C are timing diagrams of voltages applied by the memory device 100 to lines during a pre-program operation and an erase operation (e.g., operations S110 and S120 of FIG. 11) according to an embodiment.

Referring to FIG. 12B, for example, a voltage applied to the word lines WL at the first time t1 may increase from an off voltage VOFF or the ground voltage VSS to the pre-program voltage VPGM from the first time t1 to the second time t2. The pass voltage VPASS may be applied to the ground selection line GSL at the first time t1. The ground voltage VSS may be applied to the common source line CSL at the first time t1. Also, the word lines WL may be floated at the second time t2. The ground selection line GSL may be floated at the second time t2. The common source line CSL may be floated at the second time t2.

Referring to FIG. 12C, for example, the pre-program voltage VPGM may be applied to the word lines WL at the first time t1. The voltage applied to the word lines WL may increase from the ground voltage VSS or the off voltage VOFF to the pre-program voltage VPGM from the first time t1 to the second time t2. The voltage applied to the word lines WL may decrease from the pre-program voltage VPGM to a second voltage V2 from the second time t2 to a third time t3. The pass voltage VPASS may be applied to the ground selection line GSL at the first time t1. The ground voltage VSS may be applied to the common source line CSL at the first time t1. Also, the word lines WL may be floated at the third time t3. The ground selection line GSL may be floated at the third time t3. The common source line CSL may be floated at the third time t3.

Referring to FIG. 12A, during a pro-program period, the voltage applied to the word lines WL may be maintained as the pre-program voltage VPGM. On the other hand, referring to FIG. 12B, the voltage applied to the word lines WL may increase during the pre-program period. Referring to FIG. 12C, the voltage applied to the word lines WL may decrease during the pre-program period. For example, the pre-program period may refer to a period in which the pre-program voltage VPGM is applied to the word lines WL to perform the pre-program operation.

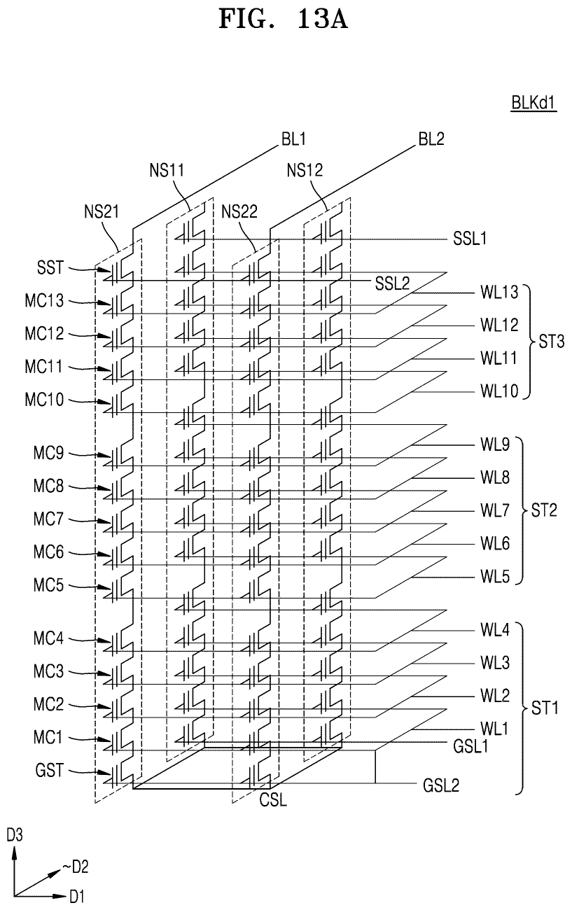

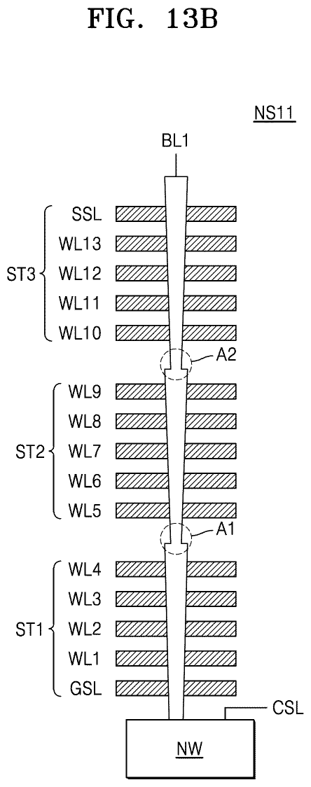

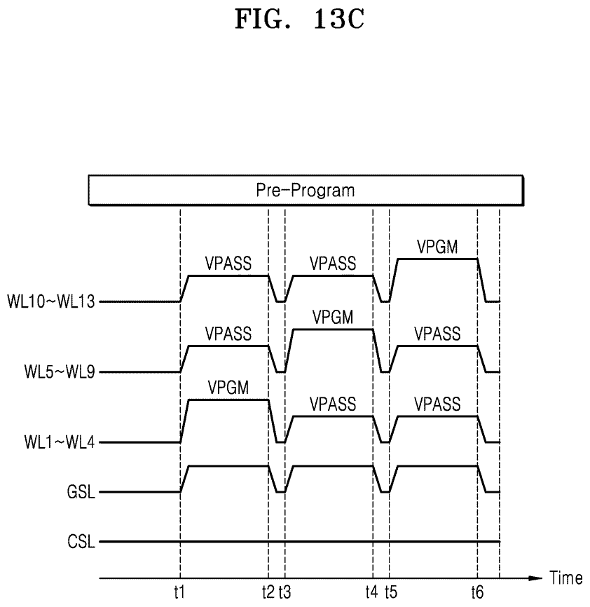

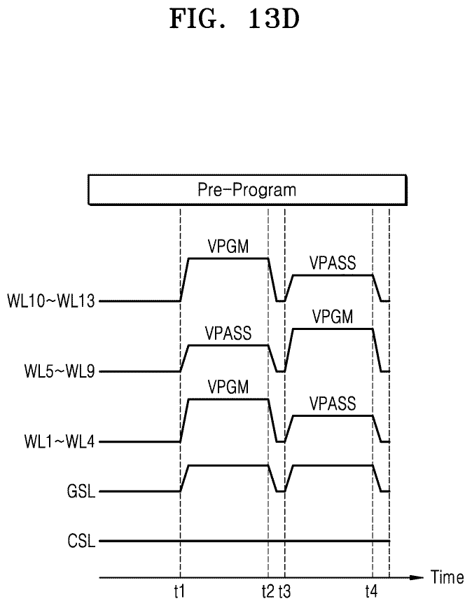

FIG. 13A is a circuit diagram illustrating the first dummy memory block BLKd1 among a plurality of memory blocks included in the memory cell array 130 of FIG. 1. FIG. 13B is a vertical cross-sectional view illustrating the first cell string NS11 among cell strings of FIG. 13A.

For simplicity and convenience of description of the drawing, the first dummy memory block BLKd1 and the first cell string NS11 are described with reference to FIGS. 13A and 13B, but the scope of the inventive concept is not limited thereto, and other dummy memory blocks or other cell strings may also have a structure similar to that of the first dummy memory block BLKd1 and the first cell string NS11 described with reference to FIGS. 13A and 13B.

Referring to FIGS. 13A and 13B, the first dummy memory block BLKd1 may be formed on a substrate (not shown). The first dummy memory block BLKd1 may include the plurality of cell strings NS11, NS12, NS21, and NS22 vertically stacked on the substrate. Each of the plurality of cell strings NS11, NS12, NS21, and NS22 may be arranged in the first direction D1 and the second direction D2.

Cell strings in the same column among the plurality of cell strings NS11, NS12, NS21, and NS22 may be connected to the same bit line. For example, the cell strings NS11 and NS21 may be connected to the first bit line BL1, and the cell strings NS12 and NS22 may be connected to the second bit line BL2. Each of the plurality of cell strings NS11, NS12, NS21, and NS22 may include a plurality of cell transistors. Each of the plurality of cell transistors may be a charge trap flash (CTF) memory cell, but the scope of the inventive concept is not limited thereto. The plurality of cell transistors may be stacked in the third direction D3 perpendicular to a plane (e.g., a semiconductor substrate (not shown) formed by the first direction D1 and the second direction D2.

Hereinafter, for convenience of description, a structure and configuration of a cell string are described with respect to the first cell string NS11, each of the other cell strings NS12, NS21, and NS22 may have a structure similar to that of the first cell string NS11, and a detailed description thereof is omitted.

The plurality of cell transistors may be connected in series between the first bit line BL1 and the common source line CSL. For example, the plurality of cell transistors may include the string selection transistor SST, first to thirteenth memory cells MC1 to MC13, and the ground selection transistor GST. The string selection transistor SST may be provided or connected between the thirteenth memory cell MC13 and the first bit line BL1. The ground selection transistor GST may be provided or connected between the first memory cell MC1 and the common source line CSL.

The first to thirteenth memory cells MC1 to MC13 may be connected in series between the string selection line SSL1 and SSL2 and the ground selection line GSL. Memory cells located at the same height among the first to thirteenth memory cells MC1 to MC13 of each of the plurality of cell strings NS11, NS12, NS21, and NS22 may share the same word line with each other. For example, the first memory cells MC1 of each of the plurality of cell strings NS11, NS12, NS21, and NS22 may be at the same height from the substrate (not shown), and may share the first word line WL1. The second memory cells MC2 of each of the plurality of cell strings NS11, NS12, NS21, and NS22 may be at the same height from the substrate (not shown), and may share the second word line WL2. Likewise, each of the third to thirteenth memory cells MC3 to MC13 of each of the plurality of cell strings NS11, NS12, NS21, and NS22 may be at the same height from the substrate (not shown), and may share the third to thirteenth word lines WL3 to WL13, respectively.

String selection transistors in the same row and at the same height among the string selection transistors SST of each of the plurality of cell strings NS11, NS12, NS21, and NS22 may be connected to the same string selection line. For example, the string selection transistors SST of the cell strings NS11 and NS12 may be connected to the string selection line SSL1, and the string selection transistors SST of the cell strings NS21 and NS22 may be connected to the string selection line SSL2.

Ground selection transistors in the same row and at the same height among the ground selection transistors GST of each of the plurality of cell strings NS11, NS12, NS21, and NS22 may be connected to the same ground selection line. For example, the ground selection transistors GST of the cell strings NS11 and NS12 may be connected to the ground selection line GSL1, and the ground selection transistors GST of the cell strings NS21 and NS22 may be connected to the ground selection line GSL2.

In an embodiment, the first dummy memory block BLKd1 illustrated in FIG. 13A is an example, the number of cell strings may increase or decrease, and the number of rows and columns constituting the cell string may increase or decrease according to the number of cell strings. Also, the first dummy memory block BLKd1 may further include dummy memory cells. The number of cell transistors of the first dummy memory block BLKd1 may increase or decrease, and the height of the first dummy memory block BLKd1 may increase or decrease according to the number of cell transistors. In addition, the number of lines connected to the cell transistors may increase or decrease according to the number of cell transistors.

In an embodiment, the first dummy memory block BLKd1 may have a multi-stacked structure. For example, as shown in FIGS. 13A and 13B, the first dummy memory block BLKd1 may include a first structure ST1, a second structure ST2, and a third structure ST3. The first structure ST1 may include the ground selection transistor GST and the memory cells MC1, MC2, MC3, and MC4 among the cell transistors of the plurality of cell strings NS11, NS12, NS21, and NS22. The second structure ST2 may include the memory cells MC5, MC6, MC7, MC8, and MC9 among the cell transistors of the plurality of cell strings NS11, NS12, NS21, and NS22. The third structure ST3 may include the memory cells MC10, MC11, MC12, MC13, and the string selection transistor SST among the cell transistors of the plurality of cell strings NS11, NS12, NS21, and NS22.

The first structure ST1 may be formed on the substrate, and the second structure ST2 may be formed on an upper portion of the first structure ST1. The third structure ST3 may be formed on an upper portion of the second structure ST2. For example, as illustrated in FIG. 13B, the first structure ST1 may be formed on an N-well substrate NW. In an embodiment, peripheral circuits (e.g., the row decoder 160, the voltage generator 150, the input/output circuit 110, and the control logic circuit 120 of FIG. 1) may be formed on a lower portion of the N-well substrate NW. For example, the memory device 100 may have a cell-on-peripheral (CoP) structure or a CMOS under array (CUA) structure. In this case, the substrate bonded to a string may be of an N-type. However, the scope of the inventive concept is not limited thereto, and the substrate bonded to the string may be a P-type.

The second structure ST2 may be formed on an upper portion of the first structure ST1. The third structure ST3 may be formed on the upper portion of the second structure ST2. In this case, as shown in FIG. 13B, a channel diameter may be changed in an area A1 to which the first structure ST1 and the second structure ST2 are electrically connected and in an area A2 to which the second structure ST2 and the third structure ST3 are electrically connected. For example, a channel of the first structure ST1 may be formed to pass through the ground selection line GSL and the first to fourth word lines WL1, WL2, WL3, and WL4 vertically stacked on the substrate. A channel of the second structure ST2 may be formed to pass through the fifth to ninth word lines WL5, WL6, WL7, WL8, and WL9 stacked on the first structure ST1. A channel of the third structure ST3 may be formed to pass through the tenth to thirteenth word lines WL10, WL11, WL12, and WL13 and the string selection line SSL stacked on the second structure ST2.

The channel of the first structure ST1 and the channel of the second structure ST2 may be electrically connected to each other in the area A1. The channel of the second structure ST2 and the channel of the third structure ST3 may be electrically connected to each other in the area A2. For example, as shown in FIG. 13B, in the area A1 in which the first structure ST1 and the second structure ST2 are electrically connected to each other, the channel diameter of the second structure ST2 may be less than the channel diameter of the first structure ST1. In the area A2 in which the second structure ST2 and the third structure ST3 are electrically connected to each other, the channel diameter of the third structure ST3 may be less than the channel diameter of the second structure ST2.

FIG. 13C is a timing diagram illustrating a pre-program operation of the memory device 100 of FIG. 1.

For convenience of description, it is described that the pre-program operation according to the timing diagram of FIG. 13C is performed by the memory device 100. However, the scope of the inventive concept is not limited thereto.

Hereinafter, for convenience of description, it is described that the pre-program operation is performed on the first dummy memory block BLKd1. However, the scope of the inventive concept is not limited thereto, for example the pre-program operation may be performed on the entire first dummy memory block BLKd1 or may be performed on strings (e.g., NS11 and NS12) in the same row among the first memory blocks BLK1.

Referring to FIGS. 13A, 13B, and 13C, the memory device 100 may sequentially perform the pre-program operation on a plurality of structures of the first dummy memory block BLKd1. In an embodiment, the memory device 100 may perform the pre-program operation on the first structure ST1, then perform the pre-program operation on the second structure ST2, and then perform the pre-program operation on the third structure ST3.

In the pre-program operation, the memory device 100 may apply the pre-program voltage VPGM to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, a substrate may maintain the ground voltage VSS.

For example, at the first time t1, the pre-program voltage VPGM may be applied to the first to fourth word lines WL1 to WL4. At the first time t1, the pass voltage VPASS may be applied to the fifth to thirteenth word lines WL5 to WL13. The pass voltage VPASS may be applied to the ground selection line GSL at the first time t1. The ground voltage VSS may be applied to the common source line CSL at the first time t1. Also, the first to thirteenth word lines WL1 to W13 may be floated at the second time t2. At the second time t2, the ground selection line GSL may be floated. At the second time t2, the common source line CSL may be floated.

After the pre-program operation on the first structure ST1, the memory device 100 may apply the pre-program voltage VPGM to the fifth to ninth word lines WL5 to WL9 connected to the second structure ST2. The memory device 100 may apply the pass voltage VPASS to the first to fourth word lines WL1 to WL4 connected to the first structure ST1. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the third time t3, the pass voltage VPASS may be applied to the first to fourth word lines WL1 to WL4. At the third time t3, the pre-program voltage VPGM may be applied to the fifth to ninth word lines WL5 to WL9. At the third time t3, the pass voltage VPASS may be applied to the tenth to thirteenth word lines WL10 to WL13. The pass voltage VPASS may be applied to the ground selection line GSL at the third time t3. The ground voltage VSS may be applied to the common source line CSL at the third time t3. Also, the first to thirteenth word lines WL1 to W13 may be floated at a fourth time t4. At the fourth time t4, the ground selection line GSL may be floated. At the fourth time t4, the common source line CSL may be floated.

After the pre-program operation on the second structure ST2, the memory device 100 may apply the pre-program voltage VPGM to the tenth to thirteenth word lines WL10 to WL13 connected to the third structure ST3. The memory device 100 may apply the pass voltage VPASS to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at a fifth time t5, the pass voltage VPASS may be applied to the first to fourth word lines WL1 to WL4. At the fifth time t5, the pass voltage VPASS may be applied to the fifth to ninth word lines WL5 to WL9. At the fifth time t5, the pre-program voltage VPGM may be applied to the tenth to thirteenth word lines WL10 to WL13. The pass voltage VPASS may be applied to the ground selection line GSL at the fifth time t5. The ground voltage VSS may be applied to the common source line CSL at the fifth time t5. Also, at a sixth time t6, the first to thirteenth word lines WL1 to W13 may be floated. At the sixth time t6, the ground selection line GSL may be floated. At the sixth time t6, the common source line CSL may be floated.

FIG. 13D is a timing diagram illustrating a pre-program operation of the memory device 100 of FIG. 1.

Referring to FIGS. 13A, 13B, and 13D, the memory device 100 may simultaneously perform the pre-program operation on a plurality of structures of the first dummy memory block BLKd1. In an embodiment, the memory device 100 may perform the pre-program operation on the first and third structures ST1 and ST3 which are odd structures, and then perform the pre-program operation on the second structure ST2 which is an even structure.

The memory device 100 may perform the pre-program operation on the odd structures ST1 and ST3. The memory device 100 may apply the pre-program voltage VPGM to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pre-program voltage VPGM to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, a substrate may maintain the ground voltage VSS.

For example, at the first time t1, the pre-program voltage VPGM may be applied to the first to fourth word lines WL1 to WL4. At the first time t1, the pass voltage VPASS may be applied to the fifth to thirteenth word lines WL5 to WL13. The pre-program voltage VPGM may be applied to the ground selection line GSL at the first time t1. The ground voltage VSS may be applied to the common source line CSL at the first time t1. Also, the first to thirteenth word lines WL1 to W13 may be floated at the second time t2. At the second time t2, the ground selection line GSL may be floated. The common source line CSL may be floated at the second time t2.

After the pre-program operation on the odd structures ST1 and ST3, the memory device 100 may perform the pre-program operation on the even structure ST2. The memory device 100 may apply the pre-program voltage VPGM to the fifth to ninth word lines WL5 to WL9 connected to the second structure ST2. The memory device 100 may apply the pass voltage VPASS to the first to fourth word lines WL1 to WL4 connected to the first structure ST1. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the third time t3, the pass voltage VPASS may be applied to the first to fourth word lines WL1 to WL4. At the third time t3, the pre-program voltage VPGM may be applied to the fifth to ninth word lines WL5 to WL9. At the third time t3, the pass voltage VPASS may be applied to the tenth to thirteenth word lines WL10 to WL13. The pass voltage VPASS may be applied to the ground selection line GSL at the third time t3. The ground voltage VSS may be applied to the common source line CSL at the third time t3. Also, the first to thirteenth word lines WL1 to W13 may be floated at the fourth time t4. At the fourth time t4, the ground selection line GSL may be floated. At the fourth time t4, the common source line CSL may be floated.

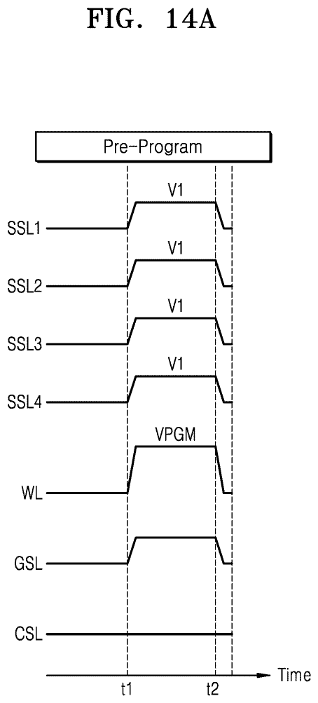

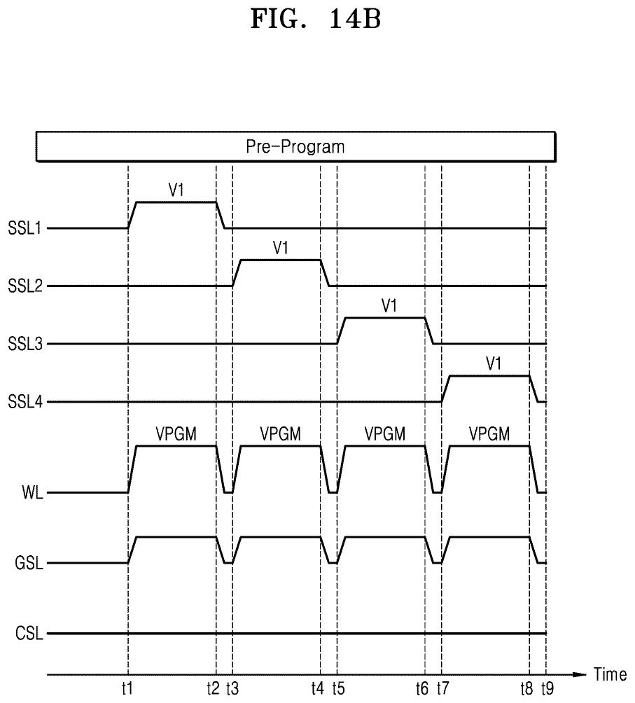

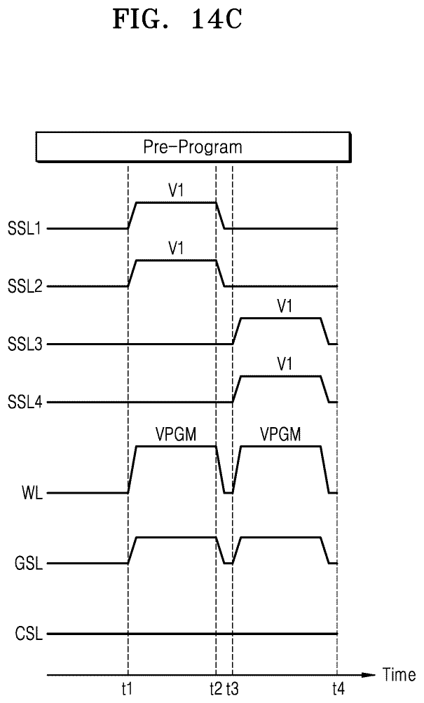

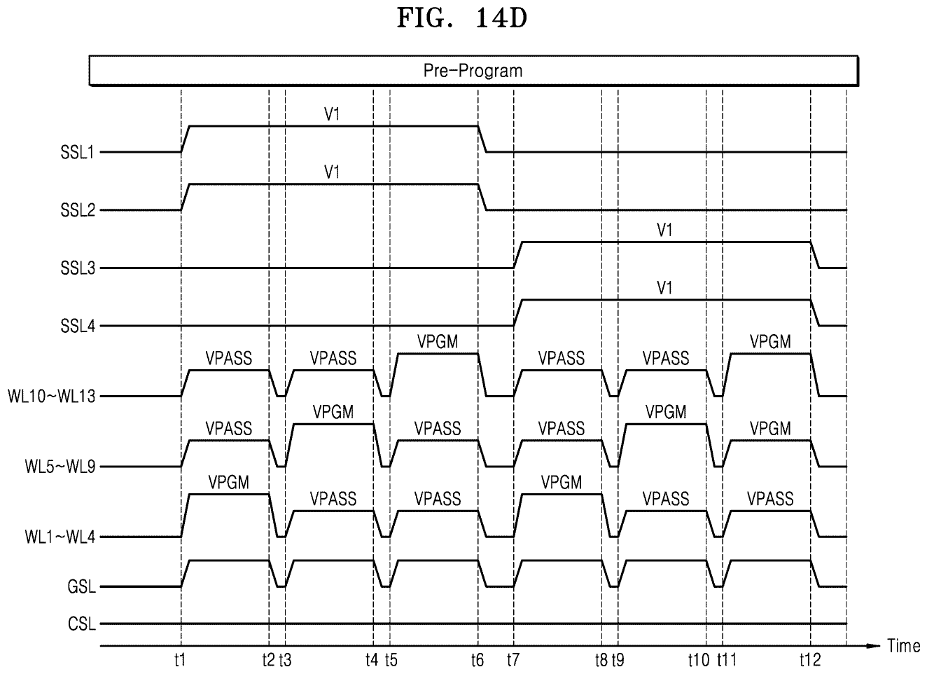

FIG. 14A is a timing diagram illustrating a pre-program operation of the memory device 100 of FIG. 1.

Referring to FIGS. 13A, 13B, and 14A, the memory device 100 may perform the pre-program operation on all cell strings connected to the first to fourth string selection lines SSL1 to SSL4 of the first dummy memory block BLKd1. Hereinafter, it is assumed that the first dummy memory block BLKd1 further includes cell strings connected to the third string selection line SSL3 and cell strings connected to the fourth string selection line SSL4. However, it will be understood that FIG. 13A illustrates only memory cells connected to the first and second string selection lines SSL1 and SSL2, for simplicity and convenience of description of the drawing.

In an embodiment, the memory device 100 may simultaneously perform the pre-program operation on cell strings connected to each of the first to fourth string selection lines SSL1 to SSL4.

The memory device 100 may apply a first voltage V1 to the first string selection line SSL1. For example, the first voltage V1 may be a selection voltage. The memory device 100 may apply the first voltage V1 to the second string selection line SSL2. The memory device 100 may apply the first voltage V1 to the third string selection line SSL3. The memory device 100 may apply the first voltage V1 to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, a substrate may maintain the ground voltage VSS.

For example, at the first time t1, the first voltage V1 may be applied to the first to fourth string selection lines SSL1 to SSL4. At the first time t1, the pre-program voltage VPGM may be applied to the word lines WL respectively connected to the first to fourth string selection lines SSL1 to SSL4. At the first time t1, the pass voltage VPASS may be applied to the ground selection line GSL. The ground voltage VSS may be applied to the common source line CSL at the first time t1. Also, at the second time t2, the first to fourth string selection lines SSL1 to SSL4 may be floated. At the second time t2, the word lines WL may be floated. At the second time t2, the ground selection line GSL may be floated. At the second time t2, the common source line CSL may be floated.

FIG. 14B is a timing diagram illustrating a pre-program operation of the memory device 100 of FIG. 1.

The memory device 100 may perform the pre-program operation on cell strings connected to the first to fourth string selection lines SSL1 to SSL4 of the first dummy memory block BLKd1. The memory device 100 may sequentially perform the pre-program operation on the cell strings connected to each of the first to fourth string selection lines SSL1 to SSL4.

In an embodiment, the memory device 100 may perform the pre-program operation on the cell strings connected to the first string selection line SSL1. Thereafter, the memory device 100 may perform the pre-program operation on the cell strings connected to the second string selection line SSL2. Thereafter, the memory device 100 may perform the pre-program operation on the cell strings connected to the third string selection line SSL3. Thereafter, the memory device 100 may perform the pre-program operation on the cell strings connected to the fourth string selection line SSL4.

The memory device 100 may perform the pre-program operation on the cell strings connected to the first string selection line SSL1. The memory device 100 may apply the first voltage V1 to the first string selection line SSL1. The memory device 100 may apply the ground voltage VSS to the second string selection line SSL2. The memory device 100 may apply the ground voltage VSS to the third string selection line SSL3. The memory device 100 may apply the ground voltage VSS to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the first time t1, the first voltage V1 may be applied to the first string selection line SSL1. At the first time t1, the ground voltage VSS may be applied to the second to fourth string selection lines SSL2 to SSL4. At the first time t1, the pre-program voltage VPGM may be applied to the word lines WL. At the first time t1, the pass voltage VPASS may be applied to the ground selection line GSL. The ground voltage VSS may be applied to the common source line CSL at the first time t1. Also, at the second time t2, the first to fourth string selection lines SSL1 to SSL4 may be floated. At the second time t2, word lines WL may be floated. At the second time t2, the ground selection line GSL may be floated. The common source line CSL may be floated at the second time t2.

After the memory device 100 performs the pre-program operation on the cell strings connected to the first string selection line SSL1, the memory device 100 may perform the pre-program operation on the cell strings connected to the second string selection line SSL2.

The memory device 100 may apply the ground voltage VSS to the first string selection line SSL1. The memory device 100 may apply the first voltage V1 to the second string selection line SSL2. The memory device 100 may apply the ground voltage VSS to the third string selection line SSL3. The memory device 100 may apply the ground voltage VSS to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the third time t3, the ground voltage VSS may be applied to the first string selection line SSL1. At the third time t3, the first voltage V1 may be applied to the second string selection line SSL2. The ground voltage VSS may be applied to the third and fourth string selection lines SSL3 and SSL4. At the third time t3, the pre-program voltage VPGM may be applied to the word lines WL. At the third time t3, the pass voltage VPASS may be applied to the ground selection line GSL. The ground voltage VSS may be applied to the common source line CSL at the third time t3. Also, at the fourth time t4, the first to fourth string selection lines SSL1 to SSL4 may be floated. At the fourth time t4, the word lines WL may be floated. At the fourth time t4, the ground selection line GSL may be floated. The common source line CSL may be floated at the fourth time t4.

After the memory device 100 performs the pre-program operation on the cell strings connected to the second string selection line SSL2, the memory device 100 may perform the pre-program operation on the cell strings connected to the third string selection line SSL3.

The memory device 100 may apply the ground voltage VSS to the first string selection line SSL1. The memory device 100 may apply the ground voltage VSS to the second string selection line SSL2. The memory device 100 may apply the first voltage V1 to the third string selection line SSL3. The memory device 100 may apply the ground voltage VSS to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the fifth time t5, the ground voltage VSS may be applied to the first string selection line SSL1. At the fifth time t5, the ground voltage VSS may be applied to the second string selection line SSL2. At the fifth time t5, the first voltage V1 may be applied to the third string selection line SSL3. At the fifth time t5, the ground voltage VSS may be applied to the fourth string selection line SSL4. At the fifth time t5, the pre-program voltage VPGM may be applied to the word lines WL. At the fifth time t5, the pass voltage VPASS may be applied to the ground selection line GSL. The ground voltage VSS may be applied to the common source line CSL at the fifth time t5. Also, at the sixth time t6, the first to fourth string selection lines SSL1 to SSL4 may be floated. At the sixth time t6, the word lines WL may be floated. At a sixth time t6, the ground selection line GSL may be floated. At the sixth time t6, the common source line CSL may be floated.

After the memory device 100 performs the pre-program operation on the cell strings connected to the third string selection line SSL3, the memory device 100 may perform the pre-program operation on the cell strings connected to the fourth string selection line SSL4.

The memory device 100 may apply the ground voltage VSS to the first string selection line SSL1. The memory device 100 may apply the ground voltage VSS to the second string selection line SSL2. The memory device 100 may apply the ground voltage VSS to the third string selection line SSL3. The memory device 100 may apply the first voltage V1 to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at a seventh time t7, the ground voltage VSS may be applied to the first string selection line SSL1. At a seventh time t7, the ground voltage VSS may be applied to the second string selection line SSL2. At the seventh time t7, the ground voltage VSS may be applied to the third string selection line SSL3. At the seventh time t7, the first voltage V1 may be applied to the fourth string selection line SSL4. At the seventh time t7, the pre-program voltage VPGM may be applied to the word lines WL. At the seventh time t7, the pass voltage VPASS may be applied to the ground selection line GSL. The ground voltage VSS may be applied to the common source line CSL at the seventh time t7. Also, at an eighth time t8, the first to fourth string selection lines SSL1 to SSL4 may be floated. At the eighth time t8, the word lines WL may be floated. At the eighth time t8, the ground selection line GSL may be floated. At the eighth time t8, the common source line CSL may be floated.

FIG. 14C is a timing diagram illustrating a pre-program operation of the memory device 100 of FIG. 1.

The memory device 100 may perform a pre-program operation on cell strings connected to the first to fourth string selection lines SSL1 to SSL4 of the first dummy memory block BLKd1. In an embodiment, the memory device 100 may simultaneously perform the pre-program operation on the cell strings connected to each of two or more string selection lines among the first to fourth string selection lines SSL1 to SSL4.

For example, the memory device 100 may perform the pre-program operation on the cell strings connected to the first and second string selection lines SSL1 and SSL2, and then perform the pre-program operation on the cell strings connected to the third and fourth string selection lines SSL3 and SSL4.

The memory device 100 may simultaneously perform the pre-program operation on the cell strings connected to the first and second string selection lines SSL1 and SSL2. The memory device 100 may apply the first voltage V1 to the first string selection line SSL1. The memory device 100 may apply the first voltage V1 to the second string selection line SSL2. The memory device 100 may apply the ground voltage VSS to the third string selection line SSL3. The memory device 100 may apply the ground voltage VSS to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, a substrate may maintain the ground voltage VSS.

For example, at the first time t1, the first voltage V1 may be applied to the first and second string selection lines SSL1 and SSL2. At the first time t1, the ground voltage VSS may be applied to the third and fourth string selection lines SSL3 and SSL4. At the first time t1, the pre-program voltage VPGM may be applied to the word lines WL. At the first time t1, the pass voltage VPASS may be applied to the ground selection line GSL. The ground voltage VSS may be applied to the common source line CSL at the first time t1. Also, at the second time t2, the first to fourth string selection lines SSL1 to SSL4 may be floated. At the second time t2, the word lines WL connected to the first to fourth string selection lines SSL1 to SSL4 may be floated. At the second time t2, the ground selection line GSL may be floated. At the second time t2, the common source line CSL may be floated.

The memory device 100 may perform the pre-program operation on the cell strings connected to the first and second string selection lines SSL1 and SSL2, and then may perform the pre-program operation on the cell strings connected to the third and fourth string selection lines SSL3 and SSL4. The memory device 100 may apply the ground voltage VSS to the first string selection line SSL1. The memory device 100 may apply the ground voltage VSS to the second string selection line SSL2. The memory device 100 may apply the first voltage V1 to the third string selection line SSL3. The memory device 100 may apply the first voltage V1 to the fourth string selection line SSL4. The memory device 100 may apply the pre-program voltage VPGM to the word lines WL. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the third time t3, the ground voltage VSS may be applied to the first and second string selection lines SSL1 and SSL2. At the third time t3, the first voltage V1 may be applied to the third and fourth string selection lines SSL3 and SSL4. At the third time t3, the pre-program voltage VPGM may be applied to the word lines WL. At the third time t3, the pass voltage VPASS may be applied to the ground selection line GSL. The ground voltage VSS may be applied to the common source line CSL at the third time t3. Also, at the fourth time t4, the first to fourth string selection lines SSL1 to SSL4 may be floated. At the fourth time t4, the word lines WL may be floated. At the fourth time t4, the ground selection line GSL may be floated. At the fourth time t4, the common source line CSL may be floated.

FIG. 14D is a timing diagram illustrating a pre-program operation of the memory device 100 of FIG. 1.

The memory device 100 may perform the pre-program operation on cell strings connected to the first to fourth string selection lines SSL1 to SSL4 of the first dummy memory block BLKd1. In an embodiment, the memory device 100 may simultaneously perform the pre-program operation on the cell strings connected to each of two or more string selection lines among the first to fourth string selection lines SSL1 to SSL4.

For example, the memory device 100 may perform the pre-program operation on the cell strings connected to the first and second string selection lines SSL1 and SSL2, and then perform the pre-program operation on the cell strings connected to the third and fourth string selection lines SSL3 and SSL4.

The memory device 100 may sequentially perform the pre-program operation on a plurality of structures of the cell strings connected to the first and second string selection lines SSL1 and SSL2. In an embodiment, the memory device 100 may perform the pre-program operation on the first structure ST1, then perform the pre-program operation on the second structure ST2, and then perform the pre-program operation on the third structure ST3.

The memory device 100 may perform the pre-program operation on the cell strings connected to the first and second string selection lines SSL1 and SSL2. The memory device 100 may apply the first voltage V1 to the first string selection line SSL1. The memory device 100 may apply the first voltage V1 to the second string selection line SSL2. The memory device 100 may apply the ground voltage VSS to the third string selection line SSL3. The memory device 100 may apply the ground voltage VSS to the fourth string selection line SSL4.

For example, at the first time t1, the first voltage V1 may be applied to the first and second string selection lines SSL1 and SSL2. At the first time t1, the ground voltage VSS may be applied to the third and fourth string selection lines SSL3 and SSL4. Also, at the sixth time t6, the first to fourth string selection lines SSL1 to SSL4 may be floated.

The memory device 100 may perform the pre-program operation on the first structure ST1. The memory device 100 may apply the pre-program voltage VPGM to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the first time t1, the pre-program voltage VPGM may be applied to the first to fourth word lines WL1 to WL4. At the first time t1, the pass voltage VPASS may be applied to the fifth to thirteenth word lines WL5 to WL13. The pass voltage VPASS may be applied to the ground selection line GSL at the first time t1. The ground voltage VSS may be applied to the common source line CSL at a first time t1. Also, the first to thirteenth word lines WL1 to W13 may be floated at the second time t2. At the second time t2, the ground selection line GSL may be floated. At the second time t2, the common source line CSL may be floated.

After the pre-program operation on the first structure ST1, the memory device 100 may perform the pre-program operation on the second structure ST2. The memory device 100 may apply the pre-program voltage VPGM to the fifth to ninth word lines WL5 to WL9 connected to the second structure ST2. The memory device 100 may apply the pass voltage VPASS to the first to fourth word lines WL1 to WL4 connected to the first structure ST1. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the third time t3, the pass voltage VPASS may be applied to the first to fourth word lines WL1 to WL4. At the third time t3, the pre-program voltage VPGM may be applied to the fifth to ninth word lines WL5 to WL9. At the third time t3, the pass voltage VPASS may be applied to the tenth to thirteenth word lines WL10 to WL13. The pass voltage VPASS may be applied to the ground selection line GSL at the third time t3. The ground voltage VSS may be applied to the common source line CSL at the third time t3. Also, the first to thirteenth word lines WL1 to W13 may be floated at the fourth time t4. At the fourth time t4, the ground selection line GSL may be floated. At the fourth time t4, the common source line CSL may be floated.

After the pre-program operation on the second structure ST2, the memory device 100 may perform the pre-program operation on the third structure ST3. The pre-program voltage VPGM may be applied to the tenth to thirteenth word lines WL10 to WL13 connected to the third structure ST3. The memory device 100 may apply the pass voltage VPASS to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the fifth time t5, the pass voltage VPASS may be applied to the first to fourth word lines WL1 to WL4. At the fifth time t5, the pass voltage VPASS may be applied to the fifth to ninth word lines WL5 to WL9. At the fifth time t5, the pre-program voltage VPGM may be applied to the tenth to thirteenth word lines WL10 to WL13. The pass voltage VPASS may be applied to the ground selection line GSL at the fifth time t5. The ground voltage VSS may be applied to the common source line CSL at the fifth time t5. Also, at the sixth time t6, the first to thirteenth word lines WL1 to W13 may be floated. At the sixth time t6, the ground selection line GSL may be floated. The common source line CSL may be floated at the sixth time t6.

The memory device 100 may sequentially perform the pre-program operation on the plurality of structures of the cell strings connected to the first and second string selection lines SSL1 and SSL2. Thereafter, the memory device 100 may sequentially perform the pre-program operation on the plurality of structures of the cell strings connected to the third and fourth string selection lines SSL3 and SSL4.

The memory device 100 may apply the ground voltage VSS to the first string selection line SSL1. The memory device 100 may apply the ground voltage VSS to the second string selection line SSL2. The memory device 100 may apply the first voltage V1 to the third string selection line SSL3. The memory device 100 may apply the first voltage V1 to the fourth string selection line SSL4.

For example, at the seventh time t7, the ground voltage VSS may be applied to the first and second string selection lines SSL1 and SSL2. At the seventh time t7, the first voltage V1 may be applied to the third and fourth string selection lines SSL3 and SSL4. Also, at a twelfth time t12, the first to fourth string selection lines SSL1 to SSL4 may be floated.

The memory device 100 may perform the pre-program operation on the first structure ST1. The memory device 100 may apply the pre-program voltage VPGM to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the seventh time t7, the pre-program voltage VPGM may be applied to the first to fourth word lines WL1 to WL4. At the seventh time t7, the pass voltage VPASS may be applied to the fifth to thirteenth word lines WL5 to WL13. The pass voltage VPASS may be applied to the ground selection line GSL at the seventh time t7. The ground voltage VSS may be applied to the common source line CSL at the seventh time t7. Also, the first to thirteenth word lines WL1 to W13 may be floated at the eighth time t8. At the eighth time t8, the ground selection line GSL may be floated. At the eighth time t8, the common source line CSL may be floated.

After the pre-program operation on the first structure ST1, the memory device 100 may perform the pre-program operation on the second structure ST2. The memory device 100 may apply a pre-program voltage VPGM to the fifth to ninth word lines WL5 to WL9 connected to the second structure ST2. The memory device 100 may apply the pass voltage VPASS to the first to fourth word lines WL1 to WL4 connected to the first structure ST1. The memory device 100 may apply the pass voltage VPASS to the tenth to thirteenth word lines WL10 to WL13 connected to the third structure ST3. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at a ninth time t9, the pass voltage VPASS may be applied to the first to fourth word lines WL1 to WL4. At the ninth time t9, the pre-program voltage VPGM may be applied to the fifth to ninth word lines WL5 to WL9. At the ninth time t9, the pass voltage VPASS may be applied to the tenth to thirteenth word lines WL10 to WL13. The pass voltage VPASS may be applied to the ground selection line GSL at the ninth time t9. The ground voltage VSS may be applied to the common source line CSL at the ninth time t9. Also, at a tenth time t10, the first to thirteenth word lines WL1 to W13 may be floated. At the tenth time t10, the ground selection line GSL may be floated. At the tenth time t10, the common source line CSL may be floated.

After the pre-program operation on the second structure ST2, the memory device 100 may perform the pre-program operation on the third structure ST3. The pre-program voltage VPGM may be applied to the tenth to thirteenth word lines WL10 to WL13 connected to the third structure ST3. The memory device 100 may apply the pass voltage VPASS to the first to fourth word lines WL1 to WL4 connected to the first structure ST1. The memory device 100 may apply the pass voltage VPASS to the fifth to ninth word lines WL5 to WL9 connected to the second structure ST2. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at an eleventh time t11, the pass voltage VPASS may be applied to the first to fourth word lines WL1 to WL4. At the eleventh time t11, the pass voltage VPASS may be applied to the fifth to ninth word lines WL5 to WL9. At the eleventh time t11, the pre-program voltage VPGM may be applied to the tenth to thirteenth word lines WL10 to WL13. The pass voltage VPASS may be applied to the ground selection line GSL at the eleventh time tI1. The ground voltage VSS may be applied to the common source line CSL at the eleventh time t11. Also, at a twelfth time t12, the first to thirteenth word lines WL1 to W13 may be floated. At the twelfth time t12, the ground selection line GSL may be floated. At the twelfth time t12, the common source line CSL may be floated.

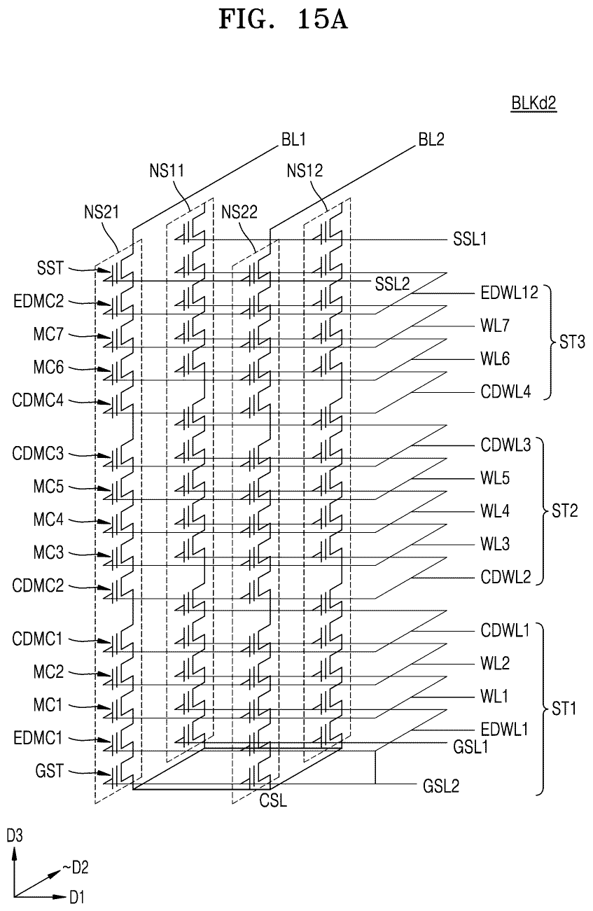

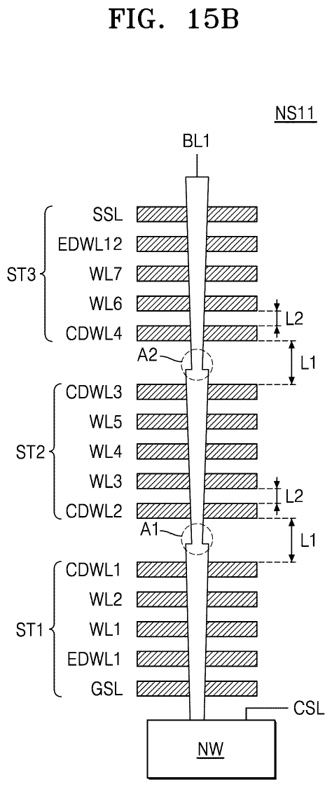

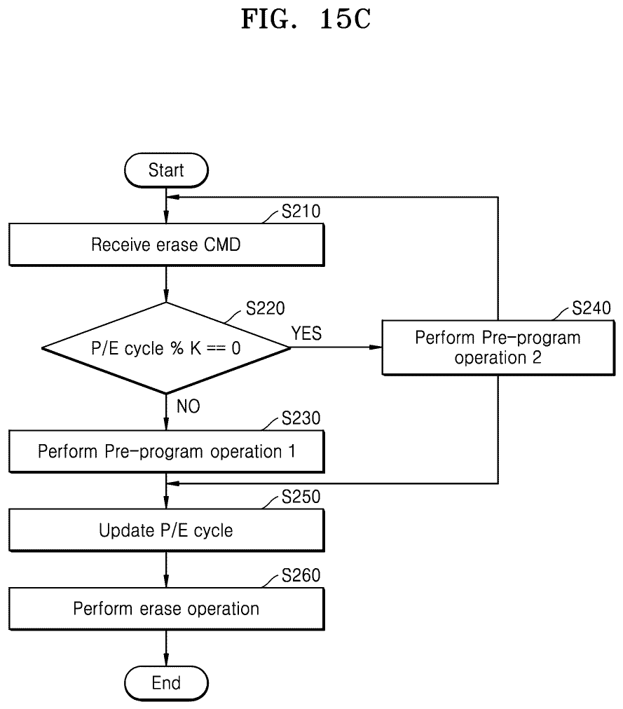

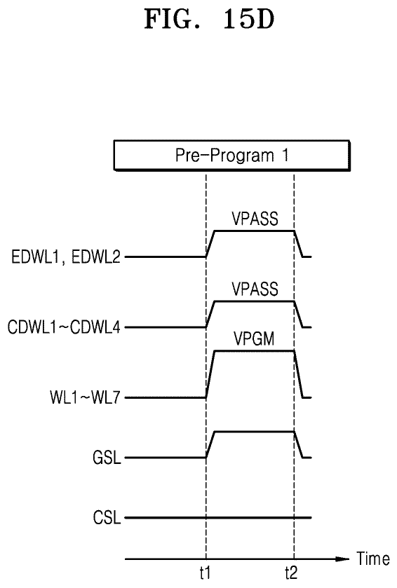

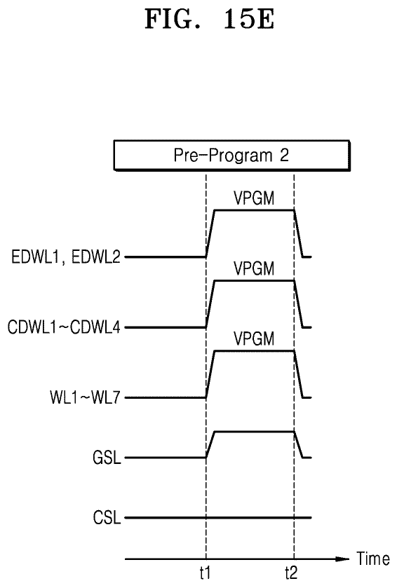

FIG. 15A is a circuit diagram illustrating the second dummy memory block BLKd2 among a plurality of memory blocks included in the memory cell array 130 of FIG. 1. FIG. 15B is a vertical cross-sectional view illustrating the first cell string NS11 among cell strings of FIG. 15A.

For convenience of description, detailed descriptions of the components described above are omitted. The second dummy memory block BLKd2 is described as an example with reference to FIG. 15A, but the scope of the inventive concept is not limited thereto. A plurality of other memory blocks included in the memory cell array 130 may each have a structure similar to that of the second dummy memory block BLKd2.

Referring to FIGS. 15A and 15B, the second dummy memory block BLKd2 may include the plurality of cell strings NS11, NS12, NS21, and NS22. Each of the plurality of cell strings NS11, NS12, NS21, and NS22 may include a plurality of cell transistors. The plurality of cell transistors may be connected in series between the corresponding first or second bit line BL1 or BL2 and the common source line CSL.

The plurality of cell transistors may include the ground selection transistor GST, first and second edge dummy memory cells EDMC1 and EDMC2, first to fourth center dummy memory cells CDMC1, CDMC2, CDMC3, and CDMC4, the first to seventh memory cells MC1, MC2, MC3, MC4, MC5, MC6, and MC7, and the string selection transistor SST. The ground selection transistor GST may be connected to each of the ground selection lines GSL1 and GSL2, the first and second edge dummy memory cells EDMC1 and EDMC2 may be connected to first and second edge dummy word lines EDWL1 and EDWL2, respectively, first to fourth center dummy memory cells CDMC1, CDMC2, CDMC3, and CDMC4 may be connected to first to fourth center dummy word lines CDWL1, CDWL2, CDWL3, and CDWL4, the first to seventh memory cells MC1, MC2, MC3, MC4, MC5, MC6, and CM7 may be connected to the first to seventh word lines WL1, WL2, WL3, WL4, WL5, WL6, and WL7, respectively, and the string selection transistor SST may be connected to each of the first and second string selection lines SSL1 and SSL2.

In an embodiment, the first edge dummy memory cell EDMC1, the first memory cell MC1, the second memory cell MC2, the first center dummy memory cell CDMC1, the second center dummy memory cell CDMC2, the third memory cell MC3, the fourth memory cell MC4, the fifth memory cell MC5, the third center dummy memory cell CDMC3, the fourth center dummy memory cell CDMC4, the sixth memory cell MC6, the seventh memory cell MC7, and the second edge dummy memory cell EDMC2 may be connected in series between the string selection transistor SST and the ground selection transistor GST.

In an embodiment, dummy memory cells including the first and second edge dummy memory cells EDMC1 and EDMC2 and the first to fourth center dummy memory cells CDMC1, CDMC2, CDMC3, and CDMC4 may be memory cells that do not store actual data.

The second dummy memory block BLKd2 may have a multi-stack structure, and the second dummy memory block BLKd2 may include the first structure ST1, the second structure ST2, and the third structure ST3. The first structure ST1 may include the ground selection transistor GST, the first edge dummy memory cell EDMC1, the first and second memory cells MC1 and MC2, and the first center dummy memory cell CDMC1. The second structure ST2 may include the second and third center dummy memory cells CDMC2 and CDMC3, and the third to fifth memory cells MC3 to MC5. The third structure ST3 may include the string selection transistor SST, the second edge dummy memory cell EDMC2, the sixth and seventh memory cells MC6 and MC7, and the fourth center dummy memory cell CDMC2.

In an embodiment, a word line at the uppermost end of the first structure ST1 may be the first center dummy word line CDWL1, and a word line at the lowermost end of the second structure ST2 may be the second center dummy word line CDWL2. A word line at the uppermost end of the second structure ST2 may be the third center dummy word line CDWL3, and a word line at the lowermost end of the third structure ST3 may be the fourth center dummy word line CDWL4.

In other words, the first center dummy word line CDWL1 may be closest to the second structure ST2 among the word lines of the first structure ST1, and the second center dummy word line CDWL2 may be closest to the first structure ST1 among the word lines of the second structure ST2. The third center dummy word line CDWL3 may be closest to the third structure ST3 among the word lines of the second structure ST2, and the fourth center dummy word line CDWL4 may be closest to the second structure ST2 among the word lines of the third structure ST3.

As illustrated in FIG. 15B, a channel diameter corresponding to the first center dummy word line CDWL1 may be wider than a channel diameter corresponding to the second center dummy word line CDWL2. Alternatively, a distance L1 between the first and second center dummy word lines CDWL1 and CDWL2 may be longer than a distance L2 between other word lines. A channel diameter corresponding to the third center dummy word line CDWL3 may be wider than a channel diameter corresponding to the fourth center dummy word line CDWL4. Alternatively, the distance L1 between the third and fourth center dummy word lines CDWL3 and CDWL4 may be longer than the distance L2 between other word lines. Due to these physical or structural characteristics, the first and second center dummy memory cells CDMC1 and CDMC2 connected to the first and second center dummy word lines CDWL1 and CDWL2 may not be used to store actual data.

Hereinafter, for convenience of description, terms such as a normal word line, a center dummy word line, and an edge dummy word line are used. The normal word line may indicate a word line connected to a memory cell used to store actual data among memory cells included in a memory block. The dummy word line may include the center dummy word line and the edge dummy word line. The dummy word line may indicate a word line connected to a memory cell that is not used to store actual data among the memory cells included in the memory block. For example, data may not be stored in memory cells connected to the dummy word line. Alternatively, memory cells connected to the dummy word line may store fewer bits of data than memory cells connected to the normal word line. As described above, the center dummy word line may indicate a word line closest to another structure in each of the stacked structures. The edge dummy word line may indicate a word line connected to a memory cell closest to a string selection transistor or a ground selection transistor.

The second dummy memory block BLKd2 of FIG. 15A may be similar to the first dummy memory block BLKd1 of FIG. 13A in a substantial structure, except that the first and second edge dummy memory cells EDMC1 and EDMC2 and the first to fourth center dummy memory cells CDMC1 to CDMC4 are added, and a detailed description thereof is omitted.

FIG. 15C is a flowchart illustrating an operating method of the memory device 100 according to an embodiment. FIG. 15D is a timing diagram illustrating a first pre-program operation of the memory device 100 of FIG. 1. FIG. 15E is a timing diagram illustrating a second pre-program operation of the memory device 100 of FIG. 1.

Referring to FIGS. 15A to 15E, the memory device 100 may perform a pre-program operation on a dummy memory block. In an embodiment, the pre-program operation may include the first pre-program operation and the second pre-program operation. The first pre-program operation may indicate an operation of applying a pre-program voltage only to memory cells connected to normal word lines. For example, the first pre-program operation may indicate an operation of applying a pass voltage to dummy word lines and applying a pre-program voltage to normal word lines. The second pre-program operation may indicate an operation of applying a pre-program voltage to both memory cells connected to normal word lines and memory cells connected to dummy word lines. For example, the second pre-program operation may indicate an operation of applying a pre-program voltage to dummy word lines and applying a pre-program voltage to normal word lines.

In an embodiment, the memory device 100 may always pre-program memory cells connected to normal word lines before performing an erase operation on the dummy memory block. The memory device 100 may pre-program memory cells connected to dummy word lines only a specific number of times before performing an erase operation on the dummy memory block. The memory device 100 may pre-program memory cells connected to a center dummy word line and edge dummy word lines only a specific number of times.

In an embodiment, the memory device 100 may perform the pre-program operation based on a program/erase cycle. For example, the memory device 100 may perform the second pre-program operation when the program/erase cycle is a specific multiple, and may perform the first pre-program operation when the program/erase cycle is not a specific multiple. For example, when the program/erase cycle is not a specific multiple, the memory device 100 may apply a program voltage to memory cells connected to normal word lines, apply a pass voltage to memory cells connected to the center dummy word line, and apply a pass voltage to memory cells connected to the edge dummy word line. When the program/erase cycle is a specific multiple, the memory device 100 may apply a pre-program voltage to memory cells connected to normal word lines, apply a pre-program voltage to memory cells connected to the center dummy word line, and apply a pre-program voltage to memory cells connected to the edge dummy word line.

In operation S210, the memory device 100 may receive an erase command from an external storage controller. For example, the memory device 100 may receive an erase command with respect to the dummy memory block.

In operation S220, the memory device 100 may determine whether the program/erase cycle is a specific multiple. For example, the memory device 100 may perform a modular operation in the program/erase cycle to determine whether a result value is ‘0’. When the result value is ‘0’, the memory device 100 may determine that the program/erase cycle is a specific multiple. When the result value is not ‘0’, the memory device 100 may determine that the program/erase cycle is not a specific multiple. When the program/erase cycle is not a specific multiple, the memory device 100 may perform operation S230, and when the program/erase cycle is a specific multiple, the memory device 100 may perform operation S240.

In operation S230, the memory device 100 may perform the first pre-program operation. In an embodiment, the memory device 100 may apply a pre-program voltage to only memory cells connected to normal word lines, apply a pass voltage to memory cells connected to the center dummy word lines, and apply a pass voltage to memory cells connected to edge dummy word lines.

In operation S240, the memory device 100 may perform the second pre-program operation. In an embodiment, the memory device 100 may apply a pre-program voltage to memory cells connected to normal word lines, apply a pre-program voltage to memory cells connected to center dummy word lines, and apply a pre-program voltage to memory cells connected to edge dummy word lines.

In operation S250, the memory device 100 may update the program/erase cycle. For example, the memory device 100 may increase the program/erase cycle by ‘1’. In operation S260, the memory device 100 may perform an erase operation. For example, the memory device 100 may perform an erase operation on the dummy memory block on which the pre-program operation is performed.

The first pre-program operation will be described in detail with reference to FIG. 15D. The memory device 100 may perform the first pre-program operation on the second dummy memory block BLKd2. The memory device 100 may apply the pre-program voltage VPGM to the first to seventh word lines WL1 to WL7. The memory device 100 may apply the pass voltage VPASS to the first to fourth center dummy word lines CDWL1 to CDWL4. The memory device 100 may apply the pass voltage VPASS to the first and second edge dummy word lines EDWL1 and EDWL2. The memory device 100 may apply the pass voltage VPASS to the ground selection line GSL. The memory device 100 may apply the ground voltage VSS to the common source line CSL. When the memory device 100 performs the pre-program operation, a substrate may maintain the ground voltage VSS.

For example, at the first time t1, the pre-program voltage VPGM may be applied to the first to seventh word lines WL1 to WL7. At the first time t1, the pass voltage VPASS may be applied to the first to fourth center dummy word lines CDWL1 to CDWL4. At the first time t1, the pass voltage VPASS may be applied to the first and second edge dummy word lines EDWL1 and EDWL2. The pass voltage VPASS may be applied to the ground selection line GSL at the first time t1. The ground voltage VSS may be applied to the common source line CSL at the first time t1. Also, the first to seventh word lines WL1 to W7 may be floated at the second time t2. At the second time t2, the first to fourth center dummy word lines CDWL1 to CDWL4 may be floated. At the second time t2, the first and second edge dummy word lines EDWL1 and EDWL2 may be floated. At the second time t2, the ground selection line GSL may be floated. At the second time t2, the common source line CSL may be floated.

The second pre-program operation will be described in detail with reference to FIG. 15E. The memory device 100 may perform the second pre-program operation on the second dummy memory block BLKd2. The memory device 100 may apply the pre-program voltage VPGM to the first to seventh word lines WL1 to WL7. The memory device 100 may apply the pre-program voltage VPGM to the first to fourth center dummy word lines CDWL1 to CDWL4. The memory device 100 may apply the pre-program voltage VPGM to the first and second edge dummy word lines EDWL1 and EDWL2. The memory device 100 may apply the pass voltage VPASS to the ground selection line GSL. The memory device 100 may apply the ground voltage VSS to the common source line CSL. When the memory device 100 performs the pre-program operation, the substrate may maintain the ground voltage VSS.

For example, at the first time t1, the pre-program voltage VPGM may be applied to the first to seventh word lines WL1 to WL7. At the first time t1, the pre-program voltage VPGM may be applied to the first to fourth center dummy word lines CDWL1 to CDWL4. At the first time t1, the pre-program voltage VPGM may be applied to the first and second edge dummy word lines EDWL1 and EDWL2. The pass voltage VPASS may be applied to the ground selection line GSL at the first time t1. The ground voltage VSS may be applied to the common source line CSL at the first time t1. Also, the first to seventh word lines WL1 to W7 may be floated at the second time t2. At the second time t2, the first to fourth center dummy word lines CDWL1 to CDWL4 may be floated. At the second time t2, the first and second edge dummy word lines EDWL1 and EDWL2 may be floated. At the second time t2, the ground selection line GSL may be floated. At the second time t2, the common source line CSL may be floated.

In an embodiment, the pre-program operation described with reference to FIGS. 12A to 14D may be applied to both the first pre-program operation and the second pre-program operation. For example, in the first pre-program operation, the pre-program operation may be sequentially performed on first to third structures. Alternatively, in the first pre-program operation, cell strings connected to first to fourth string selection lines may sequentially perform the pre-program operation.

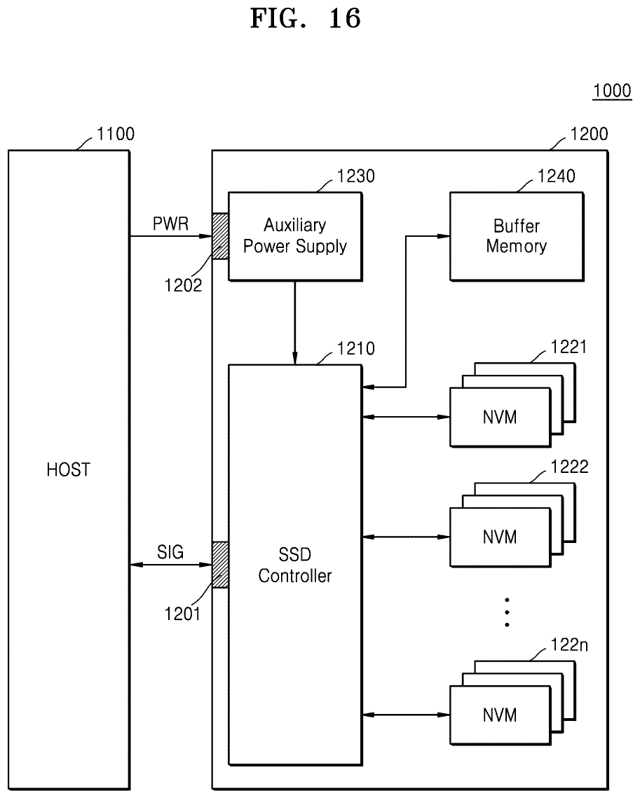

FIG. 16 is a block diagram illustrating a solid state drive (SSD) system 1000 to which a storage device according to an embodiment is applied. Referring to FIG. 16, the SSD system 1000 includes a host 1100 and an SSD 1200.

The SSD 1200 exchanges a signal SIG with the host 1100 through a signal connector 1201 and receives power PWR through a power connector 1202. The SSD 1200 includes an SSD memory controller 1210, a plurality of flash memories 1221 to 122n, an auxiliary power supply 1230, and a buffer memory 1240.

The SSD memory controller 1210 may control the plurality of flash memories 1221 to 122n in response to the signal SIG received from the host 1100. The plurality of flash memories 1221 to 122n may operate by control of the SSD memory controller 1210. The auxiliary power supply 1230 is connected to the host 1100 through a power connector 1202. The auxiliary power supply 1230 may receive the power PWR from the host 1100 and be charged with the power PWR. The auxiliary power supply 1230 may provide power to the SSD 1200 when power supply from the host 1100 is not smooth.

In an embodiment, each of the plurality of flash memories 1221 to 122n may include the dummy memory block BLKd described with reference to FIGS. 1 to 12C. The dummy memory block BLKd of each of the plurality of flash memories 1221 to 122n may include the first type T1 of at least one string group, and each of the plurality of flash memories 1221 to 122n may store data in a part of the dummy memory block BLKd. Each of the plurality of flash memories 1221 to 122n may perform a pre-program operation and an erase operation described with reference to FIGS. 1 to 12 on the dummy memory block BLKd. Accordingly, the size of the plurality of flash memories 1221 to 122n may be reduced or the storage space of the plurality of flash memories 1221 to 122n may be increased. In addition, the reliability of the plurality of flash memories 1221 to 122n may be improved by performing the pre-program operation.

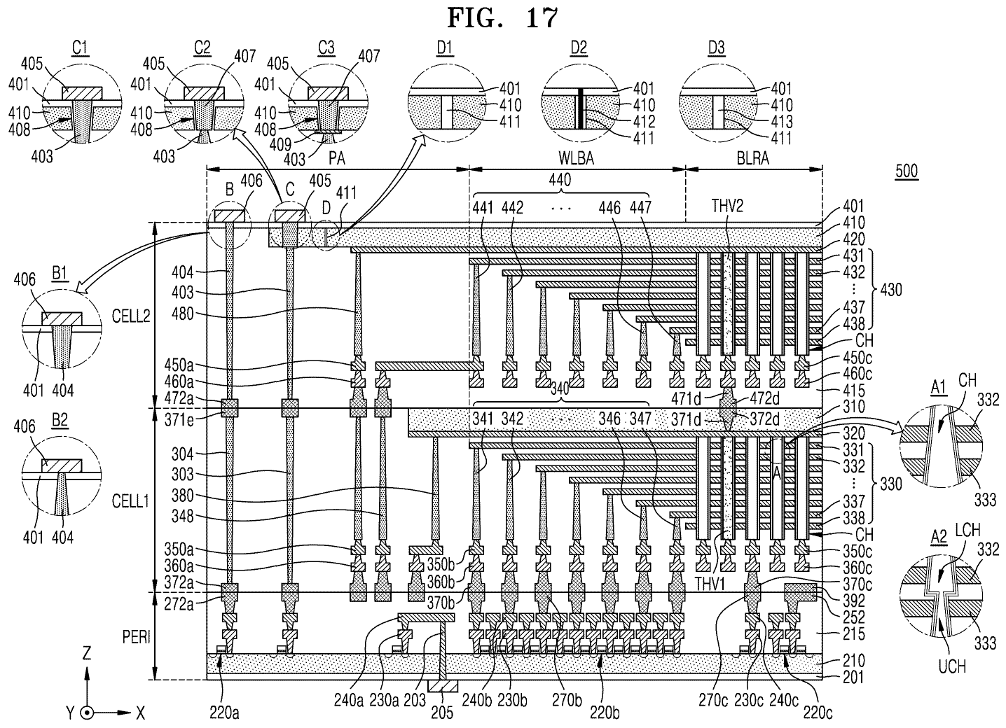

FIG. 17 is a cross-sectional view of a memory device 500 having a B-VNAND structure, according to an embodiment.

Referring to FIG. 17, the memory device 500 may have a chip-to-chip (C2C) structure. Here, the C2C structure may mean that at least one upper chip including a cell area CELL and a lower chip including a peripheral circuit area PERI are manufactured, and then connected to each other by using a bonding method. For example, the bonding method may mean a method of electrically or physically connecting a bonding metal pattern formed on the uppermost metal layer of the upper chip and a bonding metal pattern formed on the uppermost metal layer of the lower chip to each other. For example, when bonding metal patterns include copper (Cu), the bonding method may be a Cu—Cu bonding method. For another example, the bonding metal patterns may include aluminum (Al) or tungsten (W).

The memory device 500 may include at least one upper chip including a cell area. For example, as illustrated in FIG. 17, the memory device 500 may be implemented to include two upper chips. However, this is an example, and the number of upper chips is not limited thereto. When the memory device 500 is implemented to include two upper chips, the memory device 500 may be manufactured by manufacturing a first upper chip including a first cell area CELL1, a second upper chip including a second cell area CELL2, and a lower chip including a peripheral circuit area PERI, and then connecting the first upper chip, the second upper chip, and the lower chip to each other by using the bonding method. The first upper chip may be inverted and connected to the lower chip by using the bonding method, and the second upper chip may also be inverted and connected to the first upper chip by using the bonding method. In the following description, an upper portion and a lower portion of each of the first upper chip and the second upper chip are defined with respect to before the first upper chip and the second upper chip are inverted. For example, in FIG. 17, the upper portion of the lower chip means an upper portion defined with respect to the +Z axis direction, and the upper portion of each of the first upper chip and the second upper chip means an upper portion defined with respect to the −Z axis direction. However, this is an example, and in some examples, only one of the first upper chip and the second upper chip may be inverted and connected by using the bonding method.

Each of the peripheral circuit area PERI, the first cell area CELL1, and the second cell area CELL2 of the memory device 500 may include an external pad bonding area PA, a word line bonding area WLBA, and a bit line bonding area BLBA. The peripheral circuit area PERI may include a first substrate 210 and a plurality of circuit elements 220a, 220b, and 220c formed on the first substrate 210. An interlayer insulating layer 215 including one or more insulating layers may be disposed on the plurality of circuit elements 220a, 220b, and 220c, and a plurality of metal wirings connecting the plurality of circuit elements 220a, 220b, and 220c may be disposed in the interlayer insulating layer 215. For example, the plurality of metal wirings may include first metal wirings 230a, 230b, and 230c respectively connected to the plurality of circuit elements 220a, 220b, and 220c, and second metal wirings 240a, 240b, and 240c respectively formed on the first metal wirings 230a, 230b, and 230c. The plurality of metal wirings may include at least one of various conductive materials. For example, the first metal wirings 230a, 230b, and 230c may include tungsten having relatively high electrical resistivity, and the second metal wirings 240a, 240b, and 240c may include copper having relatively low electrical resistivity.

Only the first metal wirings 230a, 230b, and 230c and the second metal wirings 240a, 240b, and 240c are illustrated and described herein, but the inventive concept is not limited thereto, and one or more additional metal wirings may be further formed on the second metal wirings 240a, 240b, and 240c. In this case, the second metal wirings 240a, 240b, and 240c may include aluminum. Also, at least some of the additional metal wirings formed on the second metal wirings 240a, 240b, and 240c may include copper, etc. having a lower electrical resistivity than that of aluminum of the second metal wirings 240a, 240b, and 240c. The interlayer insulating layer 215 may be disposed on the first substrate 210 and may include an insulating material such as silicon oxide, silicon nitride, etc.

Each of the first cell area CELL1 and the second cell area CELL2 may include at least one memory block. The first cell area CELL1 may include a second substrate 310 and a common source line 320. A plurality of word lines 330, including word lines 331 to 338, may be stacked on the second substrate 310 in a direction (Z-axis direction) perpendicular to an upper surface of the second substrate 310. String selection lines and ground selection lines may be disposed above and below the word lines 330, and the plurality of word lines 330 may be disposed between the string selection lines and the ground selection line. Likewise, the second cell area CELL2 may include a third substrate 410 and a common source line 420, and a plurality of word lines 430, including word lines 431 to 438, may be stacked in a direction (Z-axis direction) perpendicular to an upper surface of the third substrate 410. The second substrate 310 and the third substrate 410 may include various materials, and, for example, each be a silicon substrate, a silicon-germanium substrate, a germanium substrate, or a substrate having a single crystal epitaxial layer grown on a monocrystalline silicon substrate. A plurality of channel structures CH may be formed in each of the first cell area CELL1 and the second cell area CELL2.

In an embodiment, as shown in A1, the channel structure CH may be provided in the bit line bonding area BLBA and extend in a direction perpendicular to the upper surface of the second substrate 310 to pass through the word lines 330, the string selection lines, and the ground selection line. The channel structure CH may include a data storage layer, a channel layer (e.g., a semiconductor layer), a buried insulating layer, etc. The channel layer may be electrically connected to a first metal wiring 350c and a second metal wiring 360c in the bit line bonding area BLBA. For example, the second metal wiring 360c may be a bit line, and connected to the channel structure CH through the first metal wiring 350c. The bit line 360c may extend in a first direction (Y-axis direction) parallel to the upper surface of the second substrate 310.

In an embodiment, as shown in A2, the channel structure CH may include a lower channel LCH and an upper channel UCH connected to each other. For example, the channel structure CH may be formed through a process of the lower channel LCH and a process of the upper channel UCH. The lower channel LCH may extend in a direction perpendicular to the upper surface of the second substrate 310 and pass through the common source line 320 and the lower word lines 331 and 332. The lower channel LCH may include a data storage layer, a channel layer, a buried insulating layer, etc., and be connected to the upper channel UCH. The upper channel UCH may pass through the upper word lines 333 to 338. The upper channel UCH may include a data storage layer, a channel layer, a buried insulating layer, etc., and the channel layer of the upper channel UCH may be electrically connected to the first metal wiring 350c and the second metal wiring 360c. As the length of the channel increases, it may be difficult to form a channel with a constant width due to process reasons. The memory device 500 according to an embodiment may include a channel with the improved width uniformity through the lower channel LCH and the upper channel UCH formed by a sequential process.

As shown in A2, when the channel structure CH is formed to include the lower channel LCH and the upper channel UCH, word lines near a boundary between the lower channel LCH and the upper channel UCH may be dummy word lines. For example, the word line 332 and the upper word line 333 forming the boundary between the lower channel LCH and the upper channel UCH may be dummy word lines. In this case, data may not be stored in memory cells connected to the dummy word line. Alternatively, the number of pages corresponding to the memory cells connected to the dummy word line may be less than the number of pages corresponding to memory cells connected to a normal word line. A level of voltage applied to the dummy word line may be different from a level of voltage applied to the normal word line, and accordingly, the influence of a non-uniform channel width between the lower channel LCH and the upper channel UCH on the operation of the memory device 500 may be reduced.

Meanwhile, it is shown in A2 that the number of the lower word lines 331 and 332 through which the lower channel LCH passes is less than the number of upper word lines 333 to 338 through which the upper channel UCH passes. However, this is an example, and the inventive concept is not limited thereto. For another example, the number of lower word lines passing through the lower channel LCH may be formed to be equal to or greater than the number of upper word lines passing through the upper channel UCH. In addition, the structure and connection relationship of the channel structure CH disposed in the first cell area CELL1 described above may be equally applied to the channel structure CH disposed in the second cell area CELL2.

In the bit line bonding area BLBA, a first through electrode THV1 may be provided in the first cell area CELL1, and a second through electrode THV2 may be disposed in the second cell area CELL2. The first through electrode THV1 may pass through the common source line 320 and the plurality of word lines 330. However, this is an example, and the first through electrode THV1 may further pass through the second substrate 310. The first through electrode THV1 may include a conductive material. Alternatively, the first through electrode THV1 may include a conductive material surrounded by an insulating material. The second through electrode THV2 may also be disposed in the same shape and structure as the first through electrode THV1.

The first through electrode THV1 and the second through electrode THV2 may be electrically connected to each other through a first through metal pattern 372d and a second through metal pattern 472d. The first through metal pattern 372d may be formed at a lower end of the first upper chip including the first cell area CELL1, and the second through metal pattern 472d may be formed at an upper end of the second upper chip including the second cell area CELL2. The first through electrode THV1 may be electrically connected to the first metal wiring 350c and the second metal wiring 360c. A lower via 371d may be formed between the first through electrode THV1 and the first through metal pattern 372d, and an upper via 471d may be formed between the second through electrode THV2 and the second through metal pattern 472d. The first through metal pattern 372d and the second through metal pattern 472d may be connected to each other by using the bonding method.

In addition, in the bit line bonding area BLBA, an upper metal pattern 252 may be formed on the uppermost metal layer of the peripheral circuit area PERI, and an upper metal pattern 392 having the same shape as the upper metal pattern 252 may be formed on the uppermost metal layer of the first cell area CELL1. The upper metal pattern 392 of the first cell area CELL1 and the upper metal pattern 252 of the peripheral circuit area PERI may be electrically connected to each other by using the bonding method. In the bit line bonding area BLBA, the bit line 360c may be electrically connected to a page buffer included in the peripheral circuit area PERI. For example, some of the circuit elements 220c of the peripheral circuit area PERI may provide a page buffer, and the bit line 360c may be electrically connected to the circuit elements 220c providing the page buffer through the upper bonding metal 370c of the first cell area CELL1 and the upper bonding metal 270c of the peripheral circuit area PERI.

In an embodiment, as described with reference to FIGS. 1 to 16, a first channel structure among the channel structures CH of the first cell area CELL1 and the second cell area CELL2 may be electrically connected to the bit line 360c through the first metal wiring 350c. Because the first metal wiring 350c is not formed in a second channel structure among the channel structures CH of the first cell area CELL1 and the second cell area CELL2, the second channel structure may not be connected to the bit line 360c.

In the word line bonding area WLBA, the word lines 330 of the first cell area CELL1 may extend in a second direction (X-axis direction) parallel to the upper surface of the second substrate 310 and may be connected to a plurality of cell contact plugs 340, including contact plugs 341 to 347. A first metal wiring 350b and a second metal wiring 360b may be sequentially connected to upper portions of the cell contact plugs 340 connected to the word lines 330. The cell contact plugs 340 may be connected to the peripheral circuit area PERI in the word line bonding area WLBA through an upper bonding metal 370b of the first cell area CELL1 and an upper bonding metal 270b of the peripheral circuit area PERI.

The cell contact plugs 340 may be electrically connected to a row decoder included in the peripheral circuit area PERI. For example, some of the circuit elements 220b of the peripheral circuit area PERI provide the row decoder, and the cell contact plugs 340 may be electrically connected to the circuit elements 220b providing the row decoder through the upper bonding metal 370b of the first cell area CELL1 and the upper bonding metal 270b of the peripheral circuit area PERI. In an embodiment, operating voltages of the circuit elements 220b providing the row decoder may be different from operating voltages of the circuit elements 220c providing the page buffer. For example, operating voltages of the circuit elements 220c providing the page buffer may be greater than operating voltages of the circuit elements 220b providing the row decoder.

Likewise, in the word line bonding area WLBA, the word lines 430 of the second cell area CELL2 may extend in the second direction (X-axis direction) parallel to the upper surface of the third substrate 410, and may be connected to a plurality of cell contact plugs 440, including contact plugs 441 to 447. The cell contact plugs 440 may be connected to the peripheral circuit area PERI through the upper metal pattern of the second cell area CELL2, the lower metal pattern and the upper metal pattern of the first cell area CELL1, and a cell contact plug 348.

In the word line bonding area WLBA, the upper bonding metal 370b may be formed in the first cell area CELL1, and the upper bonding metal 270b may be formed in the peripheral circuit area PERT. The upper bonding metal 370b of the first cell area CELL1 and the upper bonding metal 270b of the peripheral circuit area PERI may be electrically connected to each other by using the bonding method. The upper bonding metal 370b and the upper bonding metal 270b may include aluminum, copper, tungsten, etc.

In the external pad bonding area PA, a lower metal pattern 371e may be formed on a lower portion of the first cell area CELL1, and an upper metal pattern 472a may be formed on an upper portion of the second cell area CELL2. The lower metal pattern 371e of the first cell area CELL1 and the upper metal pattern 472a of the second cell area CELL2 may be connected to each other in the external pad bonding area PA by using the bonding method. Likewise, an upper metal pattern 372a may be formed in an upper portion of the first cell area CELL1, and an upper metal pattern 272a may be formed in an upper portion of the peripheral circuit area PERT. The upper metal pattern 372a of the first cell area CELL1 and the upper metal pattern 272a of the peripheral circuit area PERI may be connected by using the bonding method.

Common source line contact plugs 380 and 480 may be disposed in the external pad bonding area PA. The common source line contact plugs 380 and 480 may each include a conductive material such as a metal, a metal compound, or doped polysilicon. The common source line contact plug 380 of the first cell area CELL1 may be electrically connected to the common source line 320, and the common source line contact plug 480 of the second cell area CELL2 may be electrically connected to the common source line 420. A first metal wiring 350a and a second metal wiring 360a may be sequentially stacked on the common source line contact plug 380 of the first cell area CELL1, and a first metal wiring 450a and a second metal wiring 460a may be sequentially stacked on the common source line contact plug 480 of the second cell area CELL2.

First to third input/output pads 205, 405, and 406 may be disposed on the external pad bonding area PA. A lower insulating layer 201 may cover the lower surface of the first substrate 210, and the first input/output pad 205 may be formed on the lower insulating layer 201. The first input/output pad 205 may be connected to at least one of the plurality of circuit elements 220a disposed in the peripheral circuit area PERI through a first input/output contact plug 203, and separated from the first substrate 210 by the lower insulating layer 201. In addition, a side insulating layer may be disposed between the first input/output contact plug 203 and the first substrate 210 and may electrically separate the first input/output contact plug 203 from the first substrate 210.

An upper insulating layer 401 covering the upper surface of the third substrate 410 may be formed on the third substrate 410. The second input/output pad 405 and/or the third input/output pad 406 may be disposed on the upper insulating layer 401. The second input/output pad 405 may be connected to at least one of the plurality of circuit elements 220a disposed in the peripheral circuit area PERI through second input/output contact plugs 403 and 303, and the third input/output pad 406 may be connected to at least one of the plurality of circuit elements 220a disposed in the peripheral circuit area PERI through third input/output contact plugs 404 and 304.

The third substrate 410 may not be disposed in an area in which an input/output contact plug is disposed. For example, as shown in B, the third input/output contact plug 404 may be separated from the third substrate 410 in a direction parallel to the upper surface of the third substrate 410, may pass through the interlayer insulating layer 415 of the second cell area CELL2, and be connected to the third input/output pad 406. In this case, the third input/output contact plug 404 may be formed by various processes.

For example, as illustrated in B1, the third input/output contact plug 404 may extend in a third direction (Z-axis direction) and be formed to have a diameter increasing toward the upper insulating layer 401. For example, the diameter of the channel structure CH described in A1 may decrease toward the upper insulating layer 401, whereas the diameter of the third input/output contact plug 404 may increase toward the upper insulating layer 401. For example, the third input/output contact plug 404 may be formed after the second cell area CELL2 and the first cell area CELL1 are bonded to each other.

In addition, for example, as shown in B2, the third input/output contact plug 404 may extend in the third direction (Z-axis direction) and be formed to have a diameter decreasing toward the upper insulating layer 401. For example, the diameter of the third input/output contact plug 404 may decrease toward the upper insulating layer 401, like the channel structure CH. For example, the third input/output contact plug 404 may be formed together with the cell contact plugs 440 before the second cell area CELL2 and the first cell area CELL1 are bonded to each other.

In another embodiment, an input/output contact plug may be disposed to overlap the third substrate 410. For example, as illustrated in C, the second input/output contact plug 403 may pass through the interlayer insulating layer 415 of the second cell area CELL2 in the third direction (Z-axis direction), and be electrically connected to the second input/output pad 405 through the third substrate 410. In this case, a connection structure between the second input/output contact plug 403 and the second input/output pad 405 may be implemented in various ways.

For example, as illustrated in C1, an opening 408 passing through the third substrate 410 may be formed, and the second input/output contact plug 403 may be directly connected to the second input/output pad 405 through the opening 408 formed in the third substrate 410. In this case, as illustrated in C1, the diameter of the second input/output contact plug 403 may increase toward the second input/output pad 405. However, this is an example, and in some examples, the diameter of the second input/output contact plug 403 may decrease toward the second input/output pad 405.

For example, as illustrated in C2, the opening 408 passing through the third substrate 410 may be formed, and a contact 407 may be formed in the opening 408. One end of the contact 407 may be connected to the second input/output pad 405, and the other end thereof may be connected to the second input/output contact plug 403. Accordingly, the second input/output contact plug 403 may be electrically connected to the second input/output pad 405 through the contact 407 in the opening 408. In this case, as shown in C2, the diameter of the contact 407 may increase toward the second input/output pad 405, and the diameter of the second input/output contact plug 403 may decrease toward the second input/output pad 405. For example, the third input/output contact plug 404 may be formed together with the cell contact plugs 440 before the second cell area CELL2 and the first cell area CELL1 are bonded to each other, and the contact 407 may be formed after the second cell area CELL2 and the first cell area CELL1 are bonded to each other.

Also, for example, as shown in C3, a stopper 409 may be further formed on an upper surface of the opening 408 of the third substrate 410 compared to C2. The stopper 409 may be a metal wiring formed on the same layer as the common source line 420. However, this is an example, and in some examples, the stopper 409 may be a metal wiring formed on the same layer as at least one of the word lines 430. The second input/output contact plug 403 may be electrically connected to the second input/output pad 405 through the contact 407 and the stopper 409.

Meanwhile, similar to the second input/output contact plug 403 and the third input/output contact plug 404 of the second cell area CELL2, the second input/output contact plug 303 and the third input/output contact plug 304 of the first cell area CELL1 may each be formed to have a diameter decreasing toward the lower metal pattern 371e or increasing toward the lower metal pattern 371e.

Meanwhile, according to some embodiments, a slit 411 may be formed in the third substrate 410. For example, the slit 411 may be formed at an arbitrary position in the external pad bonding area PA. For example, as shown in D, the slit 411 may be between the second input/output pad 405 and the cell contact plugs 440 in a plan view. However, this is an example, and in a plan view, the slit 411 may be formed so that the second input/output pad 405 may be between the slit 411 and the cell contact plugs 440 in some examples.

For example, as illustrated in D1, the slit 411 may be formed to pass through the third substrate 410. The slit 411 may be used, for example, to prevent the third substrate 410 from being finely divided when the opening 408 is formed. However, this is an example, and in some examples, the slit 411 may be formed to a depth of about 60% to about 70% with respect to a thickness of the third substrate 410.

Also, for example, as illustrated in D2, a conductive material 412 may be formed in the slit 411. The conductive material 412 may be used, for example, to discharge a leakage current generated during driving of circuit elements in the external pad bonding area PA to the outside. In this case, the conductive material 412 may be connected to an external ground line.

Also, for example, as illustrated in D3, an insulating material 413 may be formed in the slit 411. The insulating material 413 may be formed, for example, to electrically separate the second input/output pad 405 and the second input/output contact plug 403 disposed in the external pad bonding area PA from the word line bonding area WLBA. The insulating material 413 may be formed in the slit 411, thereby blocking a voltage provided through the second input/output pad 405 from influencing a metal layer disposed on the third substrate 410 in the word line bonding area WLBA.

According to some embodiments, the first to third input/output pads 205, 405, and 406 may be selectively formed. For example, the memory device 500 may be implemented to include only the first input/output pad 205 disposed on the upper portion of the first substrate 210, only the second input/output pad 405 disposed on the upper portion of the third substrate 410, or only the third input/output pad 406 disposed on the upper portion of the upper insulating layer 401.

According to some embodiments, at least one of the second substrate 310 of the first cell area CELL1 or the third substrate 410 of the second cell area CELL2 may be used as a sacrificial substrate, and completely or partially removed before or after a bonding process. An additional layer may be stacked after at least one of the second substrate 310 or the third substrate 410 is removed. For example, the second substrate 310 of the first cell area CELL1 may be removed before or the peripheral circuit area PERI and the first cell area CELL1 are bonded to each other, and an insulating layer covering an upper surface of the common source line 320 or a conductive layer for connection may be formed. Similarly, the third substrate 410 of the second cell area CELL2 may be removed before or after the first cell area CELL1 and the second cell area CELL2 are bonded to each other, and the upper insulating layer 401 covering an upper surface of the common source line 420 or a conductive layer for connection may be formed.

According to the embodiment, the upper bonding metals 270c of the peripheral circuit area PERI may be disposed on an upper portion of a page buffer circuit area, and disposed in a matrix form according to the first direction (Y-axis direction) and the second direction (X-axis direction). The page buffer circuit area may correspond to the bit line bonding area BLBA. For example, the upper bonding metals 270c may be grouped into a plurality of bonding pad groups, and each of the bonding pad groups may include the upper bonding metals 270c arranged in a row in the first direction (Y-axis direction). According to the embodiment, the peripheral circuit area PERI may include a plurality of through wirings extending in the first direction (Y-axis direction). For example, each of the through wirings may be disposed between the adjacent bonding pad groups.

While the inventive concept has been particularly shown and described with reference to embodiments thereof, it will be understood that various changes in form and details may be made therein without departing from the spirit and scope of the following claims.

What is claimed is:

1. A memory device comprising a memory cell structure comprising a plurality of memory blocks, wherein:
the plurality of memory blocks comprise a first dummy memory block and a plurality of main memory blocks,
each of the plurality of main memory blocks comprises a first type of string group,
the first dummy memory block comprises the first type of string group and a second type of string group,
the first type of string group comprises a plurality of first vertical channels which are connected to a first string selection line and are connected to bit lines, and
the second type of string group comprises a plurality of second vertical channels which are connected to a second string selection line and are not connected to bit lines.

2. The memory device of claim 1, wherein memory cells included in the first type of string group of the first dummy memory block are configured to store data.

3. The memory device of claim 1, wherein the first type of string group of the first dummy memory block is disposed adjacent to the plurality of main memory blocks.

4. The memory device of claim 1, wherein the first dummy memory block is disposed on one side of the plurality of main memory blocks.

5. The memory device of claim 1, wherein the memory cell structure includes
a lower wiring structure including a first interlayer insulating layer on which the bit lines are disposed and a second interlayer insulating layer;
a gate stack structure disposed on the lower wiring structure and including conductive patterns and insulating patterns stacked alternately on each other;
a first vertical channel passing through the gate stack structure;
a contact electrically connecting the first vertical channel to the bit lines and disposed in the second interlayer insulating layer; and
a second vertical channel passing through the gate stack structure, and
wherein no contact is disposed between the bit lines and the second vertical channel.

6. The memory device of claim 1, wherein the memory cell structure includes
a lower wiring structure including a first interlayer insulating layer on which the bit lines are disposed, a second interlayer insulating layer and a third interlayer insulating layer;
a gate stack structure disposed on the lower wiring structure and including conductive patterns and insulating patterns stacked alternately on each other;
a first vertical channel passing through the gate stack structure;
a first contact electrically connecting the bit lines to a second contact and disposed in the second interlayer insulating layer;
the second contact electrically connecting the first contact to the first vertical channel, and disposed in the third interlayer insulating layer; and
a second vertical channel passing through the gate stack structure, and
wherein no contact is disposed between the bit lines and the second vertical channel.

7. The memory device of claim 1, wherein the memory cell structure includes
a lower wiring structure including a first interlayer insulating layer on which the bit lines are disposed, a second interlayer insulating layer, and a third interlayer insulating layer;
a gate stack structure disposed on the lower wiring structure and including conductive patterns and insulating patterns stacked alternately on each other;
a first vertical channel passing through the gate stack structure;
a first contact electrically connecting the bit lines to a second contact and disposed in the second interlayer insulating layer;
the second contact electrically connecting the first contact to the first vertical channel, and disposed in the third interlayer insulating layer;
a second vertical channel passing through the gate stack structure; and
a third contact connected to the bit lines and disposed in the second interlayer insulating layer, and
wherein no contact is disposed between the third contact and the second vertical channel.

8. The memory device of claim 1, wherein the memory cell structure further includes:
a lower wiring structure including a first interlayer insulating layer on which the bit lines are disposed, a second interlayer insulating layer and a third interlayer insulating layer;
a gate stack structure disposed on the lower wiring structure and including conductive patterns and insulating patterns stacked alternately on each other;
a first vertical channel passing through the gate stack structure;
a first contact electrically connecting the bit lines to a second contact and disposed in the second interlayer insulating layer;
the second contact electrically connecting the first contact to the first vertical channel, and disposed in the third interlayer insulating layer;
a second vertical channel penetrating the gate stack structure; and
a third contact connected to the second vertical channel and disposed in the third interlayer insulating layer, and
wherein no contact is disposed between the third contact and the bit lines.

9. The memory device of claim 1, further comprising: a row decoder connected to the plurality of memory blocks through word lines, string selection lines, and ground selection lines,
wherein the row decoder is configured to perform a pre-program operation of applying a pre-program voltage to the first dummy memory block and to perform an erase operation of applying an erase voltage to the first dummy memory block.

10. The memory device of claim 9, wherein, to perform the pre-program operation, the row decoder is configured to:
apply the pre-program voltage to the word lines connected to the second type of string group of the first dummy memory block,
apply a pass voltage to the ground selection lines connected to the second type of string group of the first dummy memory block, and
apply a ground voltage to a common source line connected to the second type of string group of the first dummy memory block.

11. A memory device comprising a memory cell structure comprising a plurality of memory blocks, wherein:
the plurality of memory blocks comprise a first dummy memory block, a plurality of main memory blocks, and a second dummy memory block,
the first dummy memory block is disposed on a first side of the plurality of main memory blocks, and the second dummy memory block is disposed on a second side of the plurality of main memory blocks facing the first side in a first direction,
the first dummy memory block comprises a first type of string group and a second type of string group,
the second dummy memory block includes the first type of string group and the second type of string group,
each of the plurality of main memory blocks comprises the first type of string group,
the first type of string group comprises a plurality of first vertical channels which are connected to a first string selection line and are connected to bit lines, and
the second type of string group comprises a plurality of second vertical channels which are connected to a second string selection line and are not connected to bit lines.

12. The memory device of claim 11, wherein
memory cells included in the first type of string group of the first dummy memory block are configured to store data, and
memory cells included in the first type of string group of the second dummy memory block are configured to store data.

13. The memory device of claim 11, wherein
the first type of string group of the first dummy memory block is disposed adjacent to the plurality of main memory blocks, and
the first type of string group of the second dummy memory block is disposed adjacent to the plurality of main memory blocks.

14. The memory device of claim 11, wherein the memory cell structure includes
a lower wiring structure including a first interlayer insulating layer on which the bit lines are disposed, and a second interlayer insulating layer;
a gate stack structure disposed on the lower wiring structure and including conductive patterns and insulating patterns alternately stacked on each other;
a first vertical channel passing through the gate stack structure;
a contact electrically connecting the first vertical channel to the bit lines and disposed in the second interlayer insulating layer; and
a second vertical channel passing through the gate stack structure, and wherein
no contact is disposed between the bit lines and the second vertical channel.

15. The memory device of claim 11, wherein the memory cell structure further includes
a lower wiring structure including a first interlayer insulating layer on which the bit lines are disposed, a second interlayer insulating layer and a third interlayer insulating layer,
a gate stack structure disposed on the lower wiring structure and including conductive patterns and insulating patterns alternately stacked on each other;
a first channel vertical passing through the gate stack structure;
a first contact electrically connecting the bit lines to a second contact and disposed in the second interlayer insulating layer;
the second contact electrically connecting the first contact to a first vertical channel, and disposed in the third interlayer insulating layer;
a second vertical channel passing through the gate stack structure; and
a third contact connected to the bit lines and disposed in the second interlayer insulating layer, and wherein
no contact is disposed between the third contact and the second vertical channel.

16. The memory device of claim 11, wherein the memory cell structure further includes
a lower wiring structure including a first interlayer insulating layer on which the bit lines are disposed, a second interlayer insulating layer and a third interlayer insulating layer;
a gate stack structure disposed on the lower wiring structure and including conductive patterns and insulating patterns alternately stacked on each other;
a first vertical channel passing through the gate stack structure;
a first contact electrically connecting the bit lines to a second contact and disposed in the second interlayer insulating layer;
the second contact electrically connecting the first contact to the first vertical channel, and disposed in the third interlayer insulating layer;
a second vertical channel passing through the gate stack structure; and
a third contact connected to the bit lines and disposed in the third interlayer insulating layer, and wherein
no contact is disposed between the third contact and the bit lines.

17. The memory device of claim 11, further comprising a row decoder connected to the plurality memory blocks through word lines, string selection lines, and ground selection lines,
wherein, to perform a pre-program operation, the row decoder is configured to:
apply a pre-program voltage to the word lines connected to the second type of string group,
apply a pass voltage to the ground selection lines connected to the second type of string group, and
apply a ground voltage to a common source line connected to the second type of string group.

18. A memory device comprising a memory cell structure comprising a plurality of memory blocks, wherein:
the plurality of memory blocks comprise a first dummy memory block and a plurality of main memory blocks,
each of the plurality of main memory blocks comprises a plurality of first vertical channels connected to bit lines, and the first dummy memory block comprises: a plurality of first vertical channels which are connected to bit lines; and a plurality of second vertical channels which are not connected to the bit lines, and
data is stored in memory cells included in each of the plurality of first vertical channels of the first dummy memory block.

19. The memory device of claim 18, wherein the first vertical channels of the first dummy memory block are adjacent to the plurality of main memory blocks.

20. The memory device of claim 18, further comprising a row decoder connected to the plurality memory blocks through word lines, string selection lines, and ground selection lines,
wherein, to perform a pre-program operation, the row decoder is configured to:
apply a pre-program voltage to the word lines connected to the plurality of second vertical channels of the first dummy memory block,
apply a pass voltage to the ground selection lines connected to the plurality of second vertical channels of the first dummy memory block, and
apply a ground voltage to a common source line connected to the plurality of second vertical channels of the first dummy memory block.
